(19) United States
(12) Patent Application Publication
(10) Pub. No.: US 2024/0192596 A1
(43) Pub. Date: Jun. 13, 2024

(54) CHEMICALLY AMPLIFIED RESIST COMPOSITION AND PATTERNING PROCESS

(71) Applicant: Shin-Etsu Chemical Co., Ltd., Tokyo (JP)

(72) Inventors: Masahiro Fukushima, Joetsu-shi (JP); Jun Hatakeyama, Joetsu-shi (JP); Naoki Ishibashi, Joetsu-shi (JP)

(73) Assignee: Shin-Etsu Chemical Co., Ltd., Tokyo (JP)

(21) Appl. No.: 18/376,499

(22) Filed: Oct. 4, 2023

(30) Foreign Application Priority Data
Oct. 19, 2022 (JP) 2022-167620

(51) Int. Cl. G03F 7/039; C08F 212/14; C08F 220/18; C08F 220/22; C08F 220/28; C08F 220/36; G03F 7/038

(52) U.S. Cl. CPC G03F 7/0392; C08F 212/24; C08F 220/1806; C08F 220/1811; C08F 220/1812; C08F 220/1818; C08F 220/22; C08F 220/281; C08F 220/365; G03F 7/0382

(57) ABSTRACT

A chemically amplified resist composition is provided comprising (A) a polymer adapted to increase its solubility in an aqueous alkaline under the action of an acid, the polymer comprising repeat units, represented by the formula (A1), and repeat units, represented by the formula (B1), and lacking repeat units adapted to generate an acid upon exposure, and (B) a photoacid generator represented by the formula (PAG-a) or (PAG-b) which generates an acid under the action of KrF excimer laser, ArF excimer laser, electron beams or extreme ultraviolet radiation.

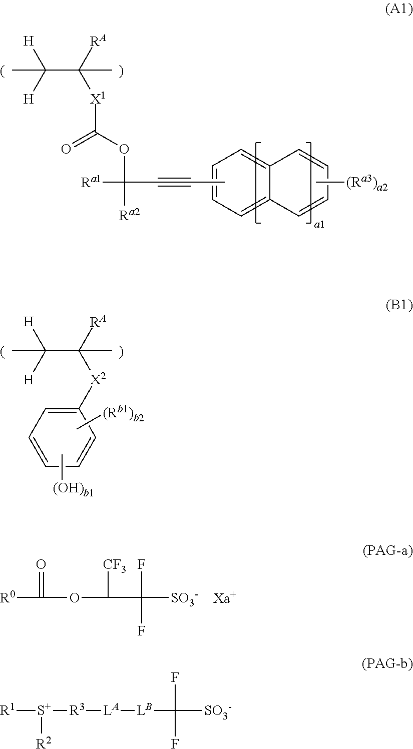

### CROSS-REFERENCE TO RELATED APPLICATIONS

This non-provisional application claims priority under 35 U.S.C. § 119(a) on Patent Application No. 2022-167620 filed in Japan on Oct. 19, 2022, the entire contents of which are hereby incorporated by reference.

### TECHNICAL FIELD

This invention relates to a chemically amplified resist composition and a pattern forming process.

### BACKGROUND ART

The currently increasing integration density of integrated circuits requires pattern formation to a smaller feature size. In the lithography process of forming patterns with a feature size of 0.2 μm or less, chemically amplified resist compositions utilizing acid as a catalyst are mostly used. As the energy source for exposure, high-energy radiation such as UV, deep UV or EB is used. The EB lithography utilized as the ultrafine processing technology is indispensable for the processing of photomask blanks to produce photomasks for use in semiconductor device fabrication.

Polymers containing abundant aromatic skeletons with acidic side chains, for example, polyhydroxystyrene are useful as the resist composition material for KrF lithography using KrF excimer laser, but not used as the resist composition material for ArF lithography using ArF excimer laser because of substantial absorption of light near to wavelength 200 nm. The above polymers are yet important, because of high etching resistance, as the resist materials for the EB lithography and EUV lithography which are promising for forming patterns of smaller size than the processing limit of ArF excimer laser.

In positive tone resist compositions for the EB lithography and resist compositions for the EUV lithography, a base polymer having on a phenol side chain an acidic functional group masked with an acid-decomposable protective group (acid labile group) is often used in combination with a photoacid generator. Under the catalysis of an acid generated from the photoacid generator upon exposure to high-energy radiation, the protective group is deprotected so that the polymer may become solubilized in alkaline developer. Tertiary alkyl, tert-butoxycarbonyl, and acetal groups are mainly used as the acid-decomposable protective group. On use of acetal and similar protective groups requiring relatively small activation energy for deprotection, one advantage is that a resist film having a high sensitivity is obtained. Unless the diffusion of the generated acid is fully suppressed, however, deprotection reaction can take place even in the unexposed region of the resist film. There arise problems like degradation of edge roughness (LWR) of line patterns and a loss of dimensional uniformity (CDU) of hole patterns.

For the control of resist sensitivity and pattern profile, various improvements are made through a choice and combination of components in a resist composition and selection of processing conditions. One of such improvements addresses the diffusion of acid that has a significant impact on the resolution of chemically amplified resist compositions. Enormous studies are made on acid diffusion that largely affects sensitivity and resolution.

For the purpose of enhancing the sensitivity of resist compositions, Patent Documents 1 to 11 disclose attempts to introduce a multiple bond or aromatic ring into an acid labile group on a base polymer. By introducing such substituent groups, the resist performance is improved to some extent, but not to a satisfactory extent (Patent Documents 1 to 11).

### CITATION LIST

Patent Document 1: JP-A 2011-191262
Patent Document 2: JP-A 2013-53196
Patent Document 3: JP-A 2018-92159
Patent Document 4: JP-A 2008-268741
Patent Document 5: JP-A 2019-120759
Patent Document 6: JP-A 2020-085917
Patent Document 7: JP 6782569
Patent Document 8: JP-A 2019-214554
Patent Document 9: JP-A 2021-50307
Patent Document 10: JP-A 2022-100187
Patent Document 11: JP-A 2022-100188

### SUMMARY OF THE INVENTION

While many chemically amplified resist compositions utilizing acid as a catalyst are known, there is the desire for a resist composition exhibiting a higher sensitivity and contrast, improved LWR of lines or the CDU of holes, and excellent etch resistance after formation of patterns.

An object of the invention is to provide a chemically amplified resist composition and a pattern forming process using the resist composition, the resist composition exhibiting a high sensitivity and contrast, improved LWR of lines and CDU of holes, and excellent etch resistance after formation of patterns, when processed in photolithography, especially photolithography using EB, or EUV having a wavelength of 13.5 nm.

The inventors have found that a chemically amplified resist composition obtained using a polymer comprising repeat units having an acid labile group containing an aromatic triple bond and repeat units having a phenolic hydroxy group, and a photoacid generator having a specific structure exhibits a high sensitivity and contrast, improved LWR of lines and CDU of holes, and excellent etch resistance after formation of patterns.

In one aspect, the invention provides a chemically amplified resist composition comprising
(A) a polymer adapted to increase its solubility in an aqueous alkaline under the action of an acid, the polymer comprising repeat units, represented by the formula (A1), and repeat units, represented by the formula (B1), and lacking repeat units adapted to generate an acid upon exposure, and
(B) a photoacid generator represented by the formula (PAG-a) or (PAG-b) which generates an acid under the action of KrF excimer laser, ArF excimer laser, electron beams or extreme ultraviolet radiation.

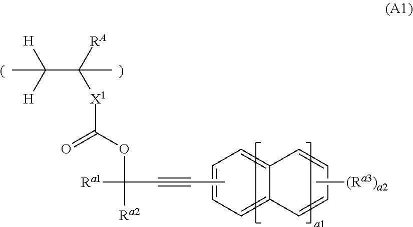

In formula (A1), a1 is 0 or 1, a2 is an integer of 0 to 3,
R^{A} is hydrogen, fluorine, methyl, or trifluoromethyl,
X¹ is a single bond, a phenylene group, a naphthylene group or *—C(═O)—O—X¹¹—, X¹¹ is a C₁-C₁₀ saturated hydrocarbylene group which may contain a hydroxy moiety, ether bond, ester bond, sulfide bond, sulfonamide bond, lactone ring or sultone ring, or a phenylene or naphthylene group, the asterisk (*) designates a point of attachment to the carbon atom in the backbone.
R^{a1} and R^{a2} are each independently hydrogen, or a C₁-C₂₀ hydrocarbyl group which may contain a heteroatom, excluding that R^{a1} and R^{a2} are hydrogen at the same time, R^{a1} and R^{a2} may bond together to form a ring with the carbon atom to which they are attached,
R^{a3} is a C₁-C₂₀ hydrocarbyl group which may contain a halogen atom or a heteroatom, and a plurality of R^{a3} moieties may bond together to form a ring with the carbon atom to which they are attached when a2≥2.

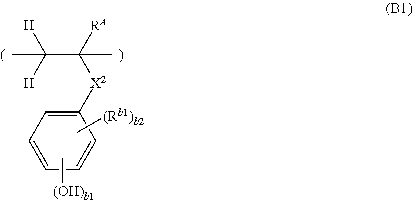

In formula (B1), b1 is an integer of 1 to 4 and b2 is an integer of 0 to 3, the sum of b1+b2 is from 1 to 5,
R^{A} is hydrogen, fluorine, methyl, or trifluoromethyl,
X² is a single bond or *—C(═O)—O—, the asterisk (*) designates a point of attachment to the carbon atom in the backbone,
R^{b1} is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, and a plurality of R^{b1} moieties may bond together to form a ring with the carbon atom to which they are attached when b2≥2.

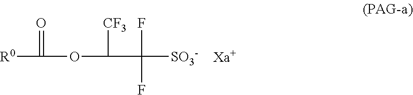

In formula (PAG-a), R⁰ is hydrogen or a C₁-C₅₀ hydrocarbyl group, some or all of the hydrogen atoms of the hydrocarbyl group may be substituted by halogen atoms, and some constituent —CH₂— of the hydrocarbyl group may be substituted by —O— or —C(═O)—, and

Xa⁺ is an organic cation.

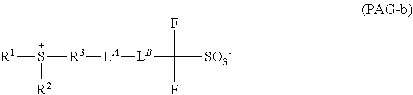

R¹ and R² are each independently a C₁-C₂₀ hydrocarbyl group which may contain a heteroatom, R¹ and R² may bond together to form a ring with the sulfur atom to which they are attached,
R³ is a C₁-C₂₀ hydrocarbylene group which may contain a heteroatom,
L^{A} is a divalent linking group, and
L^{B} is a single bond, or a C₁-C₂₀ hydrocarbylene group which may contain a heteroatom.

In a preferred embodiment, Xa⁺ is an onium cation represented by the formula (Xa-1) or (Xa-2).

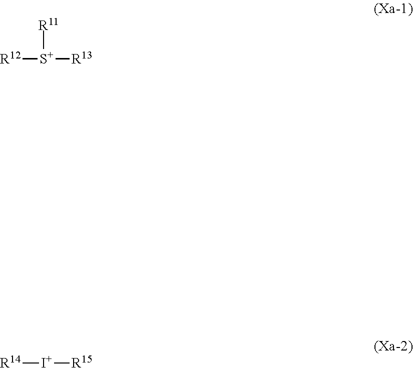

In formulae (Xa-1) and (Xa-2), R¹¹ to R¹⁵ are each independently a C₁-C₃₀ hydrocarbyl group which may contain a heteroatom, and R¹ and R¹² may bond together to form a ring with the sulfur atom to which they are attached.

In a preferred embodiment, the polymer further comprises repeat units represented by the formula (a1) or (a2).

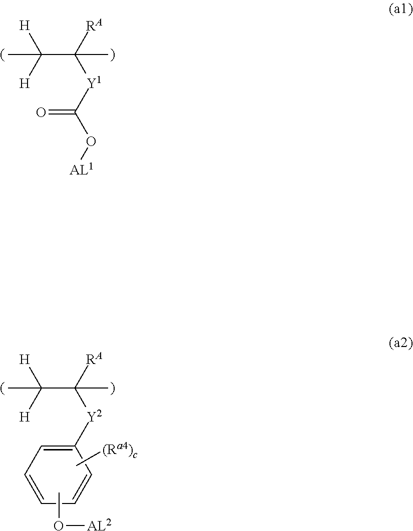

In formulae (a1) and (a2), R^{A} is hydrogen, fluorine, methyl group, or trifluoromethyl,
Y¹ is a single bond, a phenylene group, a naphthylene group or *—C(═O)—O—Y¹¹—, Y¹¹ is a C₁-C₁₀ saturated hydrocarbylene group which may contain a hydroxy moiety, ether bond, ester bond or lactone ring, or a phenylene or naphthylene group,
Y² is a single bond or *—C(═O)—O—,
the asterisk (*) designates a point of attachment to the carbon atom in the backbone,
AL¹ and AL² are each independently an acid labile group having no triple bond,
R¹¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R moieties may bond together to form a ring with the carbon atom to which they are attached when c≥2, and
c is an integer of0 to 4.

In a preferred embodiment, the polymer further comprises repeat units represented by the formula (C1).

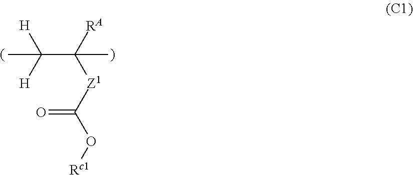

In formula (C1), R^{A} is hydrogen, fluorine, methyl group, or trifluoromethyl,
Z¹ is a single bond, a phenylene group, a naphthylene group or *—C(═O)—O—Z¹¹—, Z¹¹ is a C₁-C₁₀ saturated hydrocarbylene group which may contain a hydroxy moiety, ether bond, ester bond or lactone ring, or a phenylene or naphthylene group, the asterisk (*) designates a point of attachment to the carbon atom in the backbone,
R^{c1} is hydrogen, or a C₁-C₂₀ group containing at least one structure selected from a hydroxy moiety other than a phenolic hydroxy moiety, a cyano moiety, a carbonyl moiety, a carboxy moiety, an ether bond, an ester bond, a sulfonic ester bond, a sulfonic amide bond, a carbonate bond, a lactone ring, a sultone ring, a sulfur atom and carboxylic anhydride (—C(═O)—O—C(═O)—).

In a preferred embodiment, the chemically amplified resist composition further comprises an organic solvent.

In a preferred embodiment, the chemically amplified resist composition further comprises a quencher.

In a preferred embodiment, the chemically amplified resist composition further comprises a surfactant.

In another aspect, the invention provides a process for forming a pattern comprising the steps of applying the chemically amplified resist composition defined herein to a substrate to form a resist film thereon, exposing the resist film to KrF excimer laser, ArF excimer laser, electron beams or EUV having a wavelength of 3 to 15 nm, and developing the exposed resist film in a developer.

### Advantageous Effects of the Invention

By using a polymer comprising repeat units having an acid labile group containing an aromatic triple bond and repeat units having a phenolic hydroxy group, and a photoacid generator having a specific structure, a chemically amplified resist composition exhibiting a high sensitivity and contrast, improved LWR of lines and CDU of holes and excellent etch resistance after formation of patterns can be produced.

### DETAILED DESCRIPTION OF THE INVENTION

Chemically Amplified Resist Composition

One embodiment of the invention is a chemically amplified resist composition comprising (A) a polymer adapted to increase solubility in an aqueous alkaline under the action of an acid, the polymer lacking repeat units adapted to generate an acid upon exposure, and comprising repeat units having an acid labile group containing an aromatic triple bond and repeat units a phenolic hydroxy group, and (B) a photoacid generator having a specific structure.

(A) Polymer

Preferably, the repeat units having an acid labile group containing an aromatic triple bond in the polymer as component (A), which are also referred to as repeat units A, hereinafter, are represented by the formula (A1).

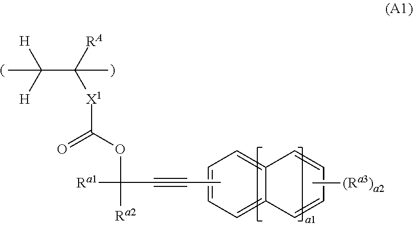

In formula (A1), a1 is 0 or 1. The polymer has a benzene ring when a1 is 0, and a naphthalene ring when a1 is 1, and a1 is preferably 0 from the aspect of solvent solubility, a2 is an integer of 0 to 3,

In formula (A1), R^{A} is hydrogen, fluorine, methyl, or trifluoromethyl.

In formula (A1), X¹ is a single bond, a phenylene group, a naphthylene group or *—C(═O)—O—X¹¹—, X¹¹ is a C₁-C₁₀ saturated hydrocarbylene group which may contain a hydroxy moiety, ether bond, ester bond, sulfide bond, sulfonamide bond, lactone ring or sultone ring, or a phenylene or naphthylene group, the asterisk (*) designates a point of attachment to the carbon atom in the backbone.

The saturated hydrocarbylene group X¹¹ may be straight, branched or cyclic. Examples thereof include C₁-C₁₀ alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, and decane-1,10-diyl; C₃-C₁₀ cycloalkanediyl groups such as cyclopropanediyl, cyclobutane-1,1-diyl, cyclopentanediyl, and cyclohexanediyl; C₄-C₁₀ polycyclic saturated hydrocarbylene groups such as adamantanediyl and norbornanediyl; and divalent groups obtained by combining the foregoing.

Examples of the structure having formula (A1) wherein X¹ is a variant are shown below, but not limited thereto. Herein R^{A} is as defined herein. The broken line designates a point of attachment to the carbon atom to which R^{a1} and R^{a2} in formula (A1) are attached.

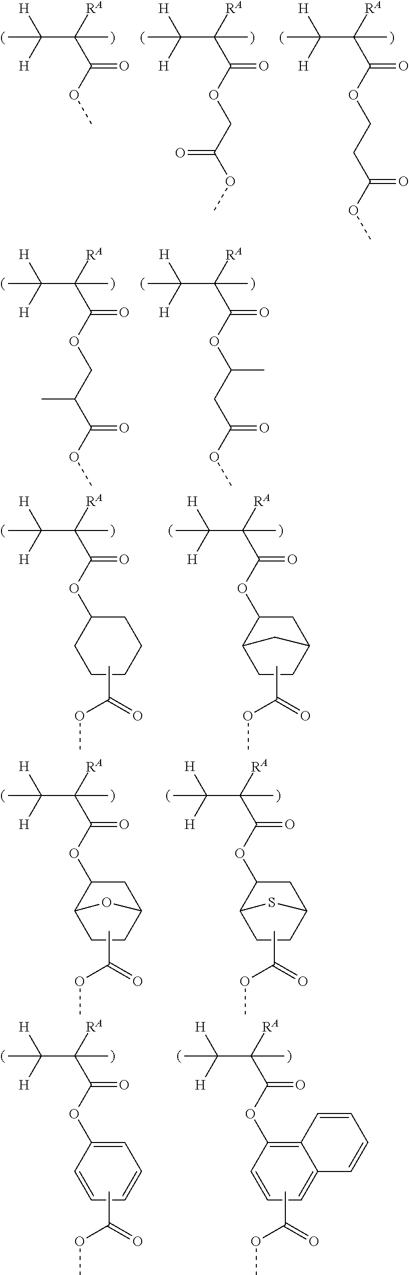

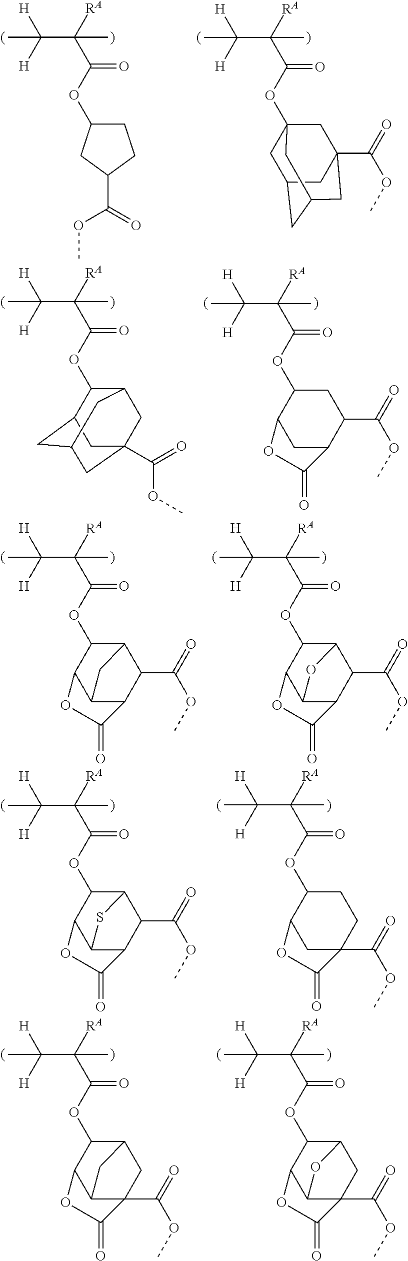

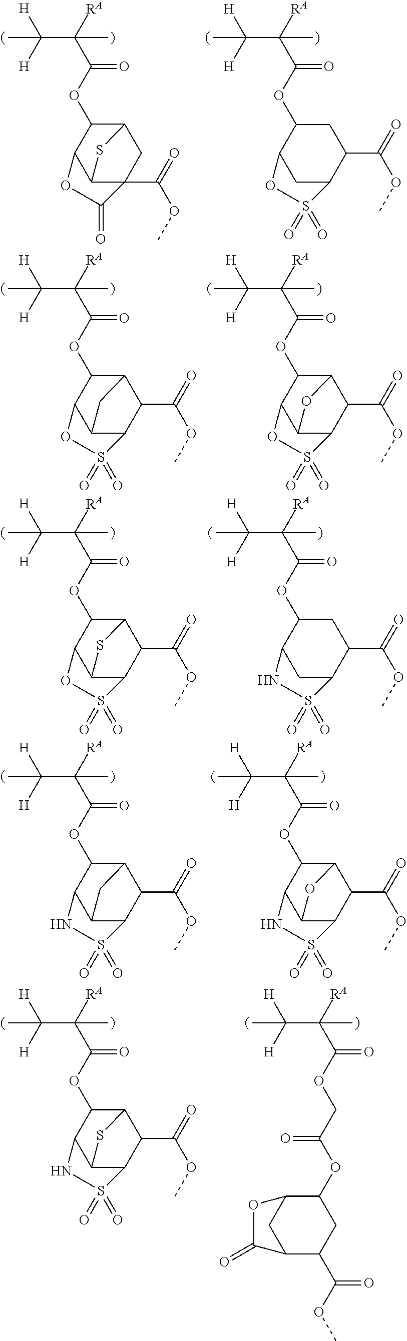

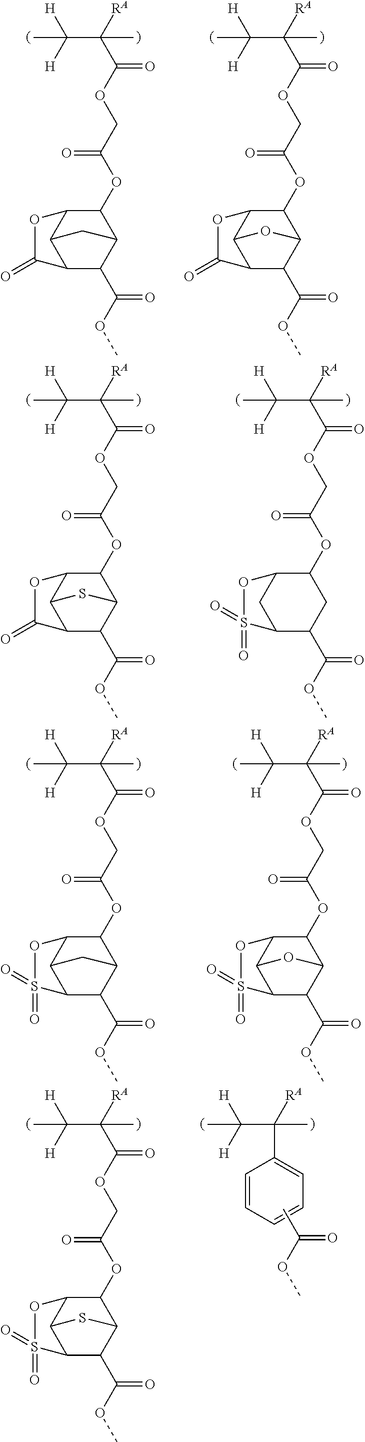

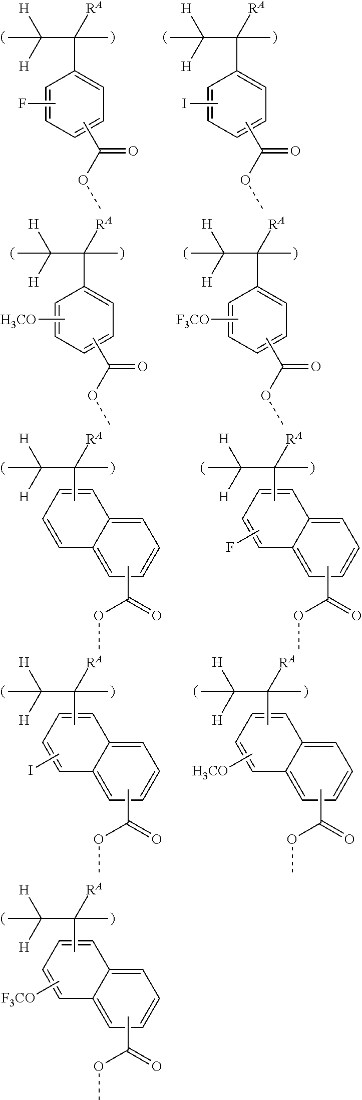

In formula (A1). R^{a1} and R^{a2} are each independently hydrogen, or a C₁-C₂₀ hydrocarbyl group which may contain a heteroatom, excluding that R^{a1} and R^{a2} are hydrogen at the same time. R^{a1} and R^{a2} may bond together to form a ring with the carbon atom to which they are attached. Examples of the ring include cyclopropane, cyclobutane, cyclopentane, cyclohexane, and adamantane rings. Inter alia, cyclopentane and cyclohexane rings are preferred.

In formula (A1), R¹ is a halogen atom, or a C₁-C₂₀ hydrocarbyl group which may contain a heteroatom. A plurality of R¹ moieties may bond together to form a ring with the carbon atom to which they are attached when a2≥2.

The hydrocarbyl groups R^{a1}, R^{a2} and R¹ may be saturated or unsaturated and straight, branched or cyclic. Examples thereof include C₁-C₂₀ alkyl groups such as methyl, ethyl, n-propyl, isopropyl, n-butyl, isobutyl, sec-butyl and tert-butyl groups; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl and adamantyl groups; C₂-C₂₀ alkenyl groups such as vinyl, allyl, propenyl, butenyl and hexenyl groups; C₃-C₂₀ cyclic unsaturated hydrocarbyl groups such as a cyclohexenyl group: C₂-C₂₀ aryl groups such as phenyl and naphthyl groups; C₇-C₂₀ aralkyl groups such as benzyl, 1-phenylethyl and 2-phenylethyl groups; and combinations thereof. Inter alia, aryl groups are preferred. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a cyano group, a fluorine atom, a chlorine atom, a bromine atom, an iodine atom, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

Examples of repeat unit A are shown below, but not limited thereto. Herein, R^{A} is as defined above.

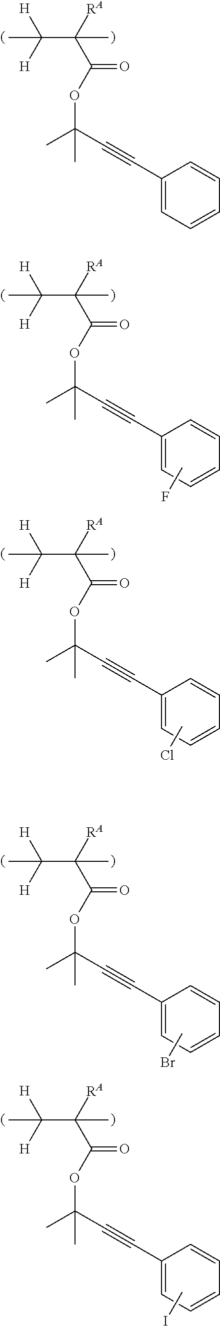

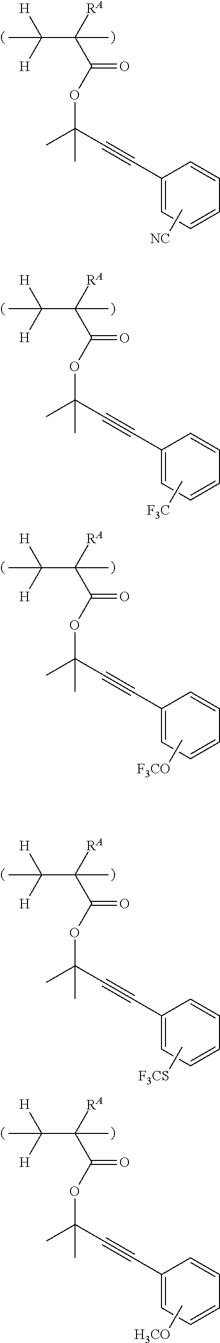

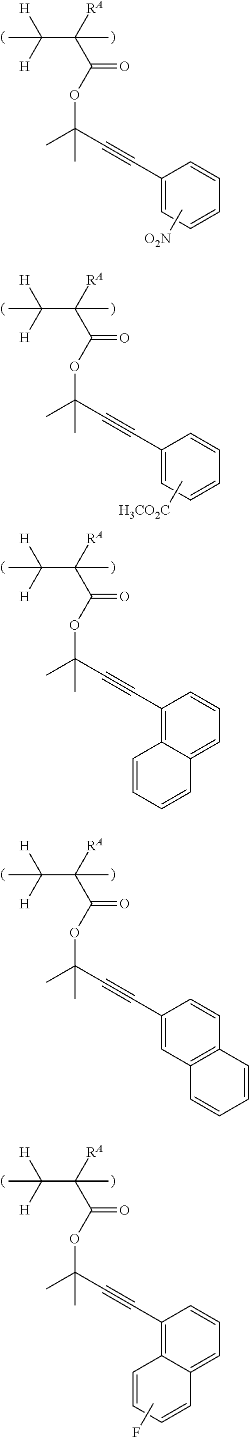

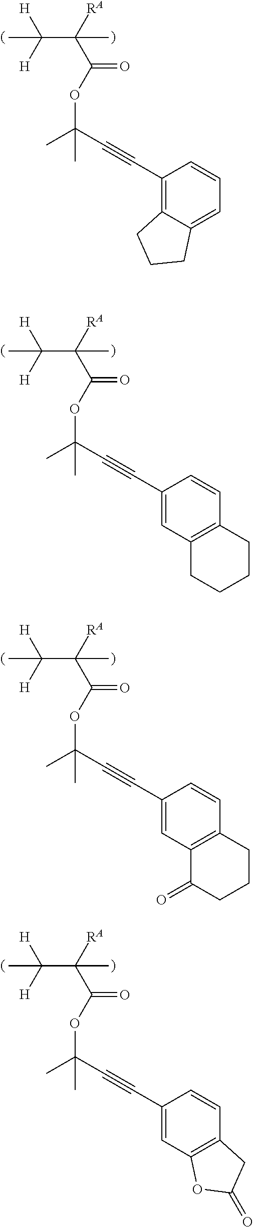

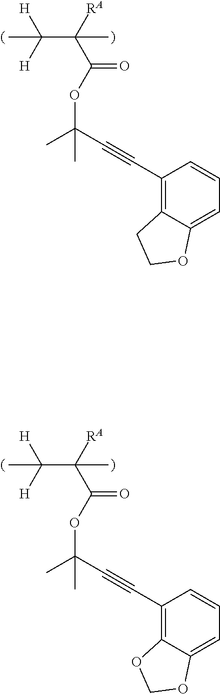

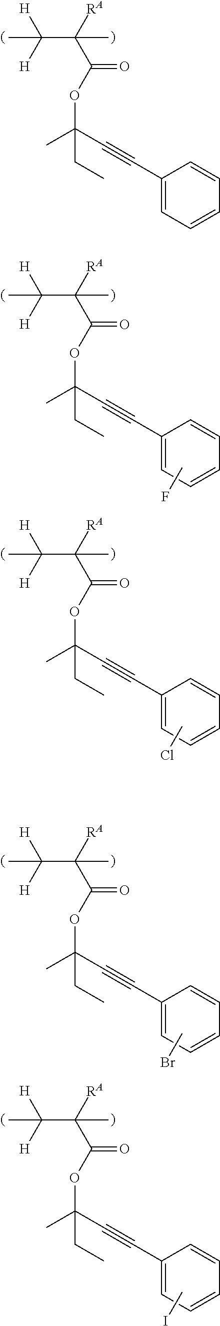

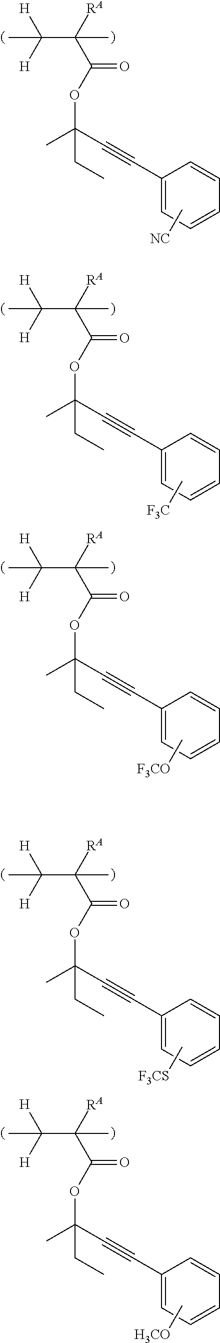

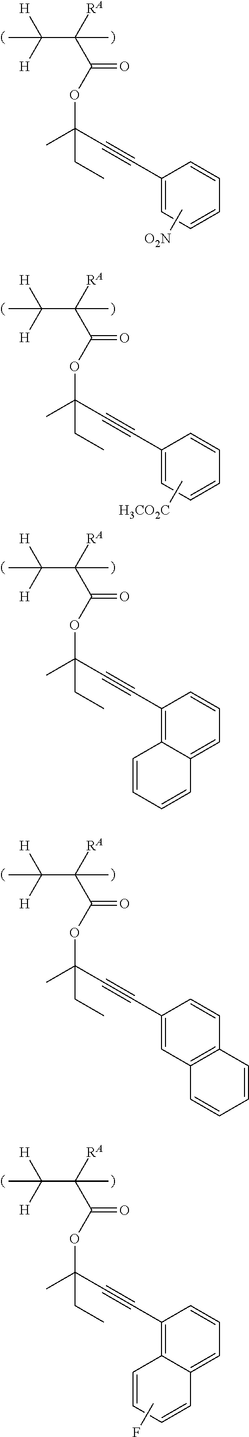

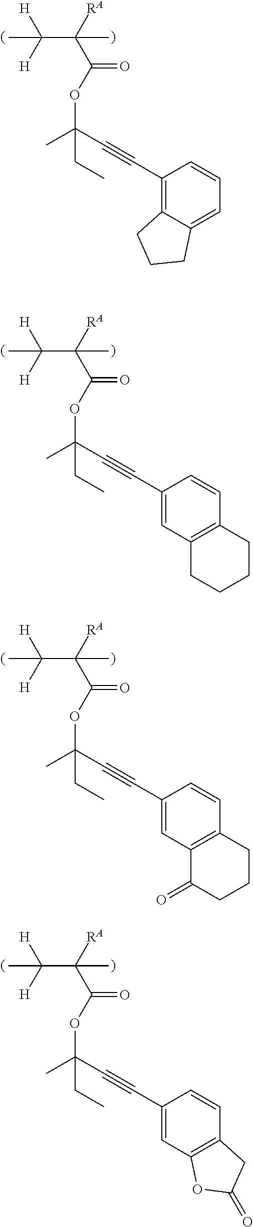

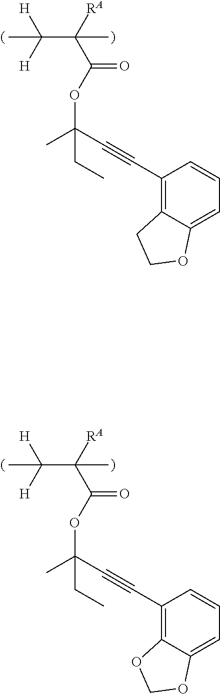

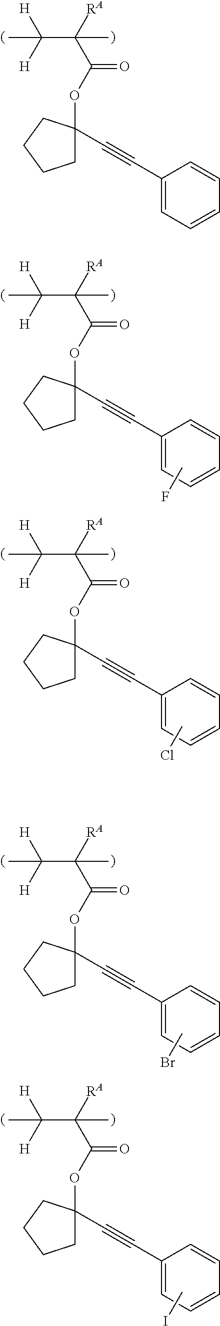

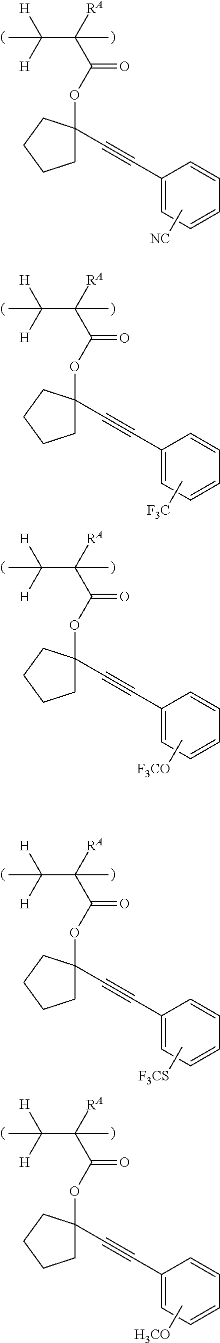

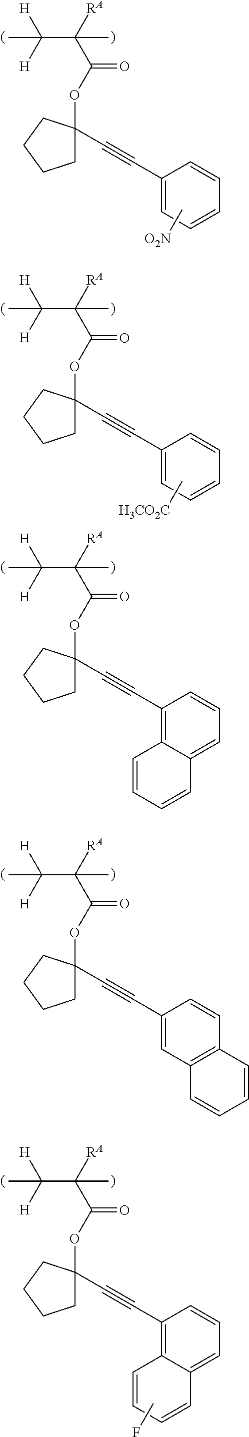

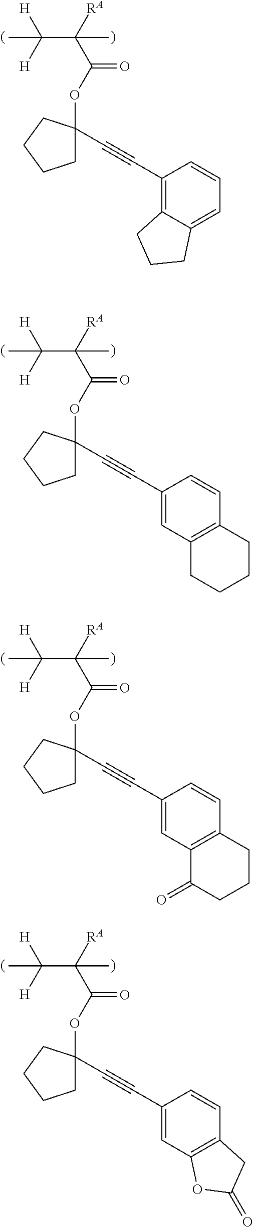

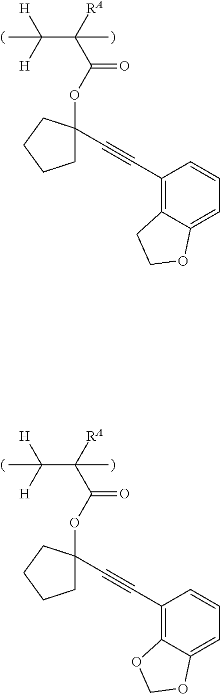

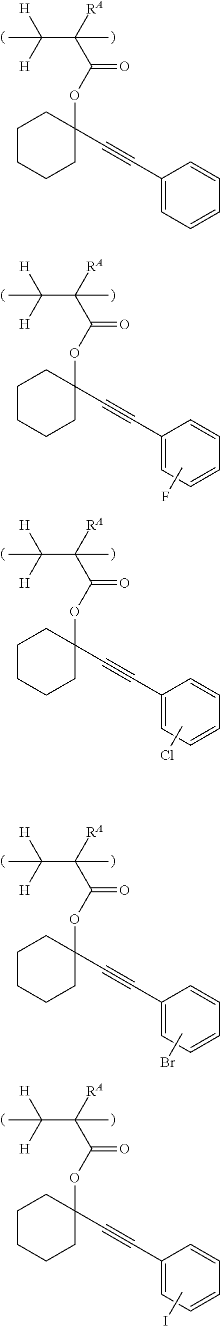

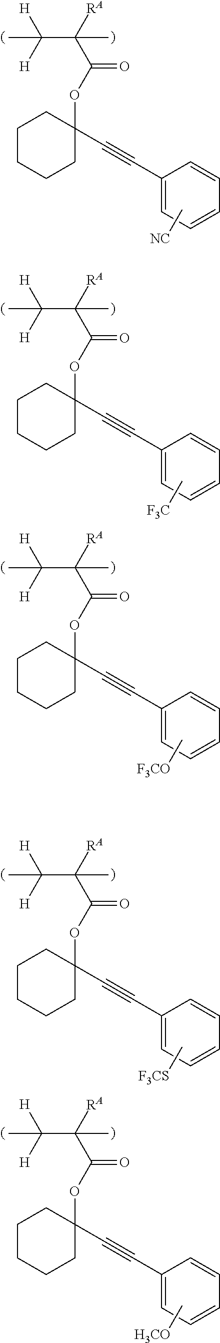

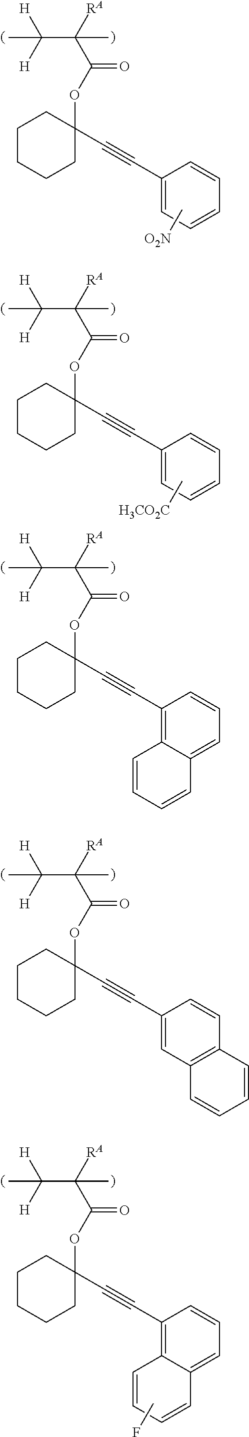

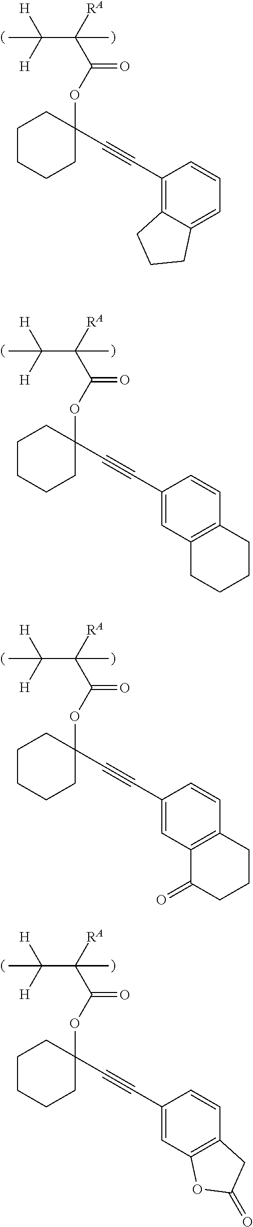

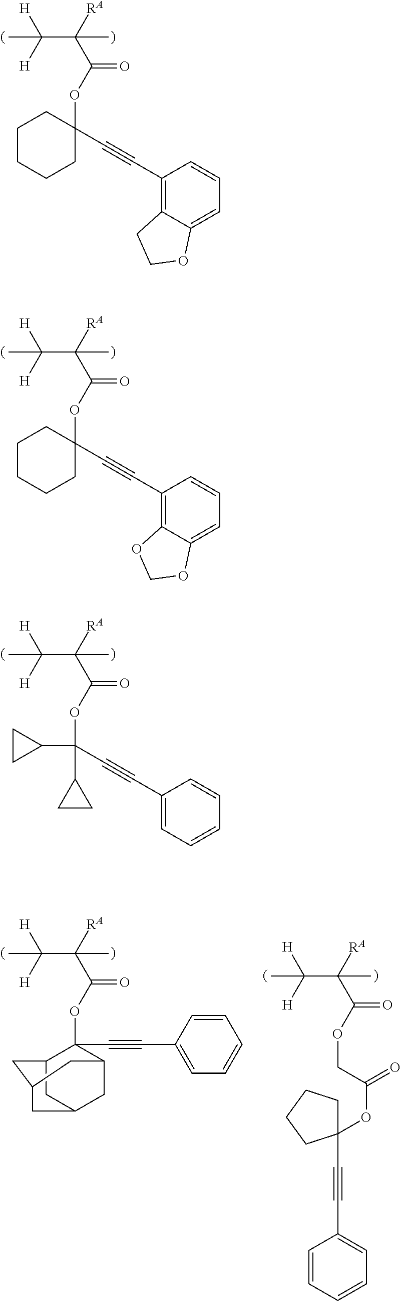

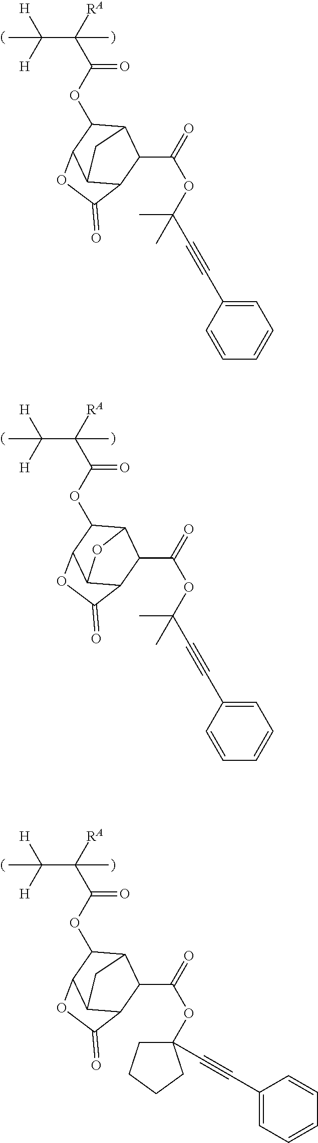

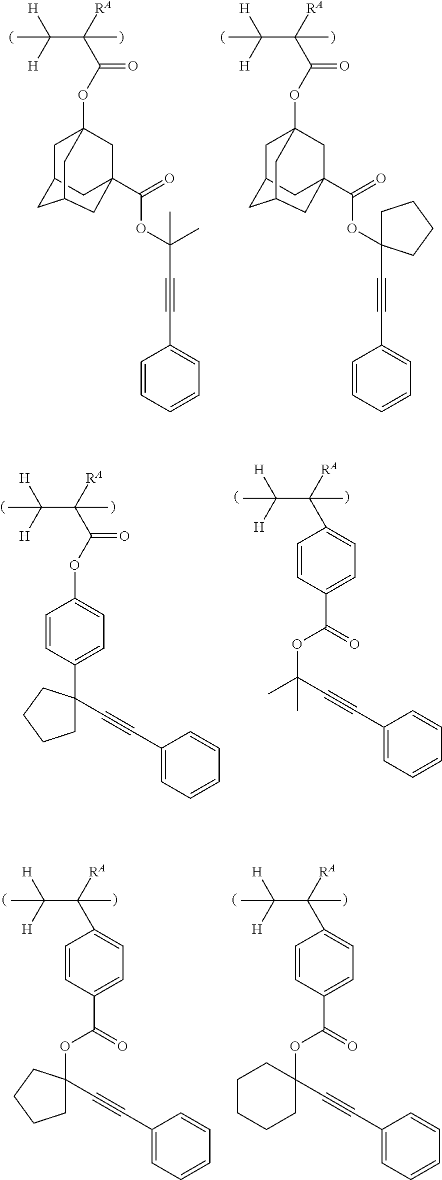

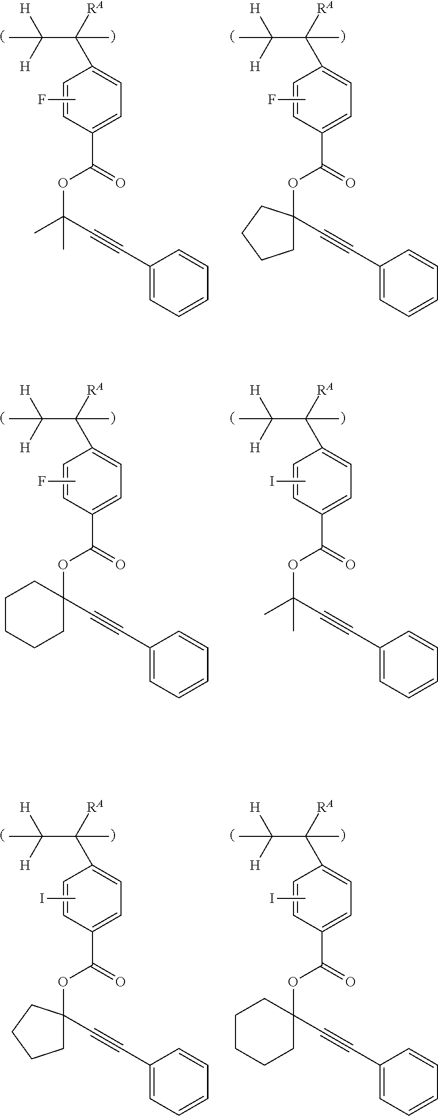

Preferably, the repeat units having a phenolic hydroxy group in the polymer as component (A), which are also referred to as repeat units B, hereinafter, are represented by the formula (B1).

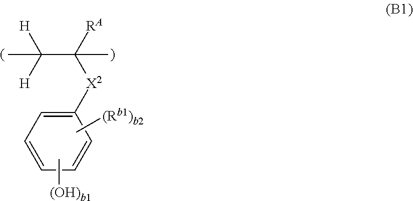

In formula (B1), b1 is an integer of 1 to 4 and b2 is an integer of 0 to 3, the sum of b1+b2 is from 1 to 5.

In formula (B1), R^{A} is hydrogen, fluorine, methyl group, or trifluoromethyl.

In formula (B1), X² is a single bond or *—C(═O)—O—, the asterisk (*) designates a point of attachment to the carbon atom in the backbone,

In formula (B1), R¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom. A plurality of Re moieties may bond together to form a ring with the carbon atom to which they are attached when b2≥2.

The hydrocarbyl group and hydrocarbyl moiety of the hydrocarbyloxy, hydrocarbylcarbonyl, hydrocarbylcarbonyloxy and hydrocarbyloxycarbonyl groups, represented by R^{b1}, may be saturated or unsaturated and straight, branched or cyclic. Examples thereof are as exemplified above for R^{a1}, R^{a2} and R^{a3} in formula (A1).

Examples of repeat unit B are shown below, but not limited thereto. Herein, R^{A} is as defined above.

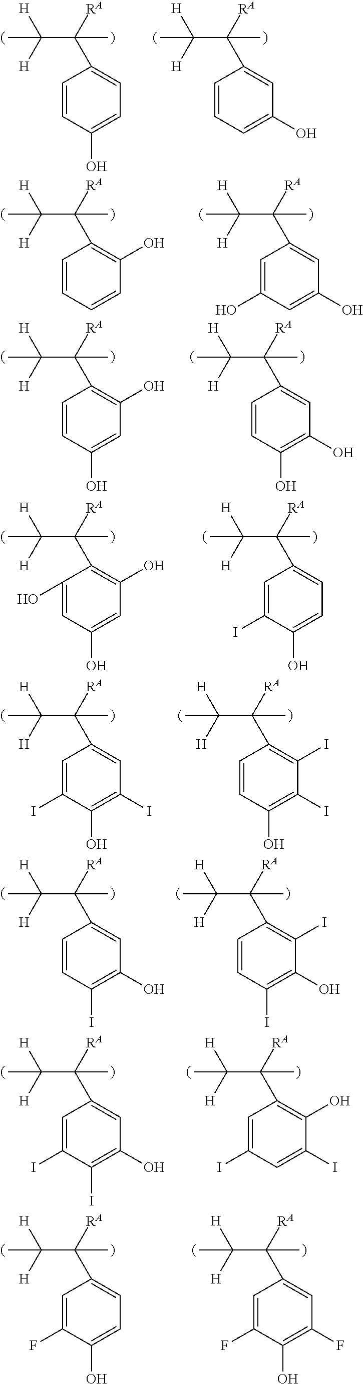

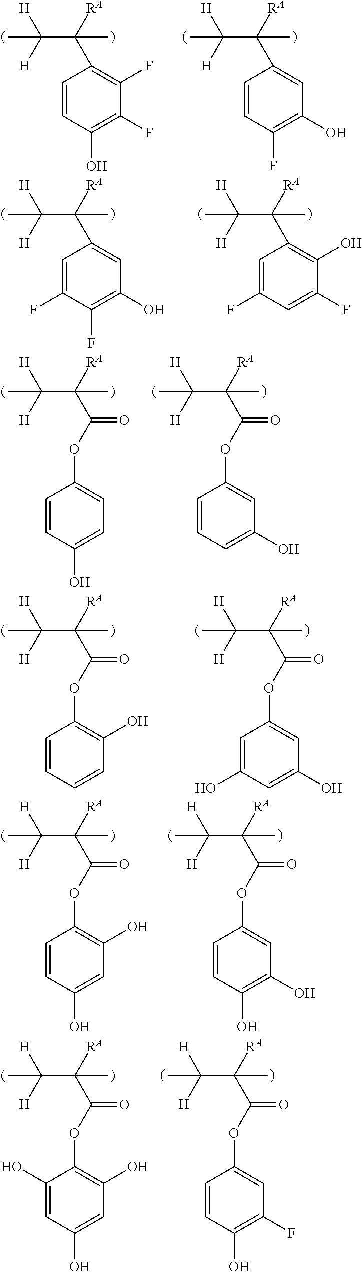

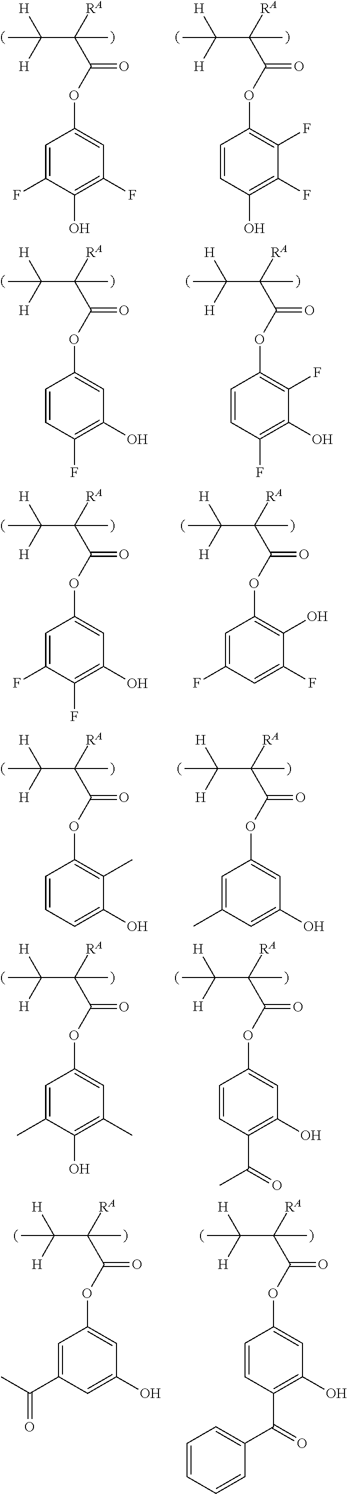

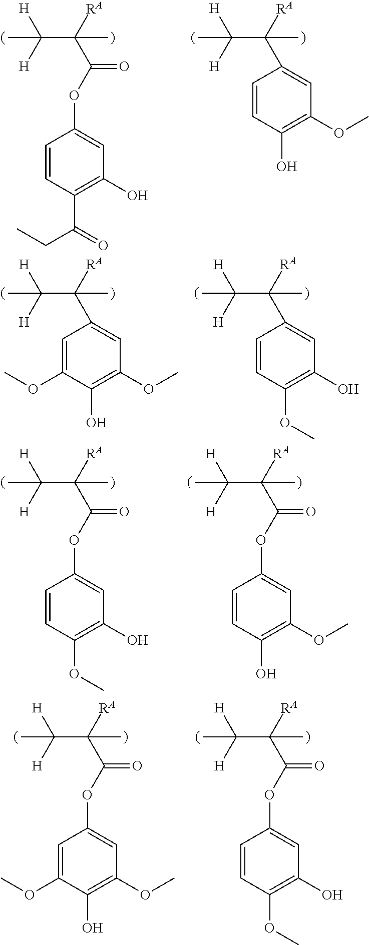

The inventive polymer is characterized by comprising repeat units A having an acid labile group containing an aromatic triple bond, and repeat units B. Upon exposure, repeat units B generate secondary electrons, which are conducted to the cation of the photoacid generator whereby the sulfonium or iodonium cation is decomposed to generate the corresponding acid. The generated acid acts on the acid labile group bound to the polymer backbone, so that the deprotection reaction of the exposed region proceeds. The repeat unit A forms a stable conjugated enyne after the elimination reaction, but since an aromatic ring is bound to the tip of the triple bond, the conjugation is extended, so that the acid elimination reaction is promoted. As a result, the resist film exhibits a high dissolution contrast in developer and is improved in sensitivity. The triple bond is advantageous in fine pattern formation because of the smaller excluded volume as compared to the single bond and double bond, and the terminal aromatic rings may be regularly arranged in the backbone and between backbones due to the stacking effect (π-π stacking). As a result, the glass transition temperature (Tg) of the polymer increases, and etch resistance during pattern formation can be improved. The conjugated triple bond and the aromatic ring have a high electron density, and a pseudo δ polarity, and may electrostatically repel hydroxide ions in the alkaline developer. As a result, in the unexposed region, swelling in the alkaline developer hardly occurs, and pattern collapse is suppressed. JP-A 2021-50307 discloses a polymer comprising repeat units that generate an acid upon exposure, in addition to repeat units having an acid labile group containing a triple bond and repeat units having a phenolic hydroxy group. However, introduction of the additional units may lead to pattern collapse resistance and deterioration of etch resistance because the degree of ionicity of the polymer increases, so that the alkaline developer is easily drawn into the unexposed region, and the stacking effect in the backbone and between backbones is impaired. The resist composition obtained using the inventive polymer exhibits a high sensitivity and dissolution contrast, improved CDU of hole patterns and LWR of line patterns, and excellent resistance to pattern collapse and etch resistance, and is suitable for fine pattern formation.

The polymer as component (A) may further comprise repeat units represented by the formula (a1), which are also referred to repeat units a1, hereinafter, and/or repeat units having the formula (a2), which also referred to as repeat units a2, hereinafter.

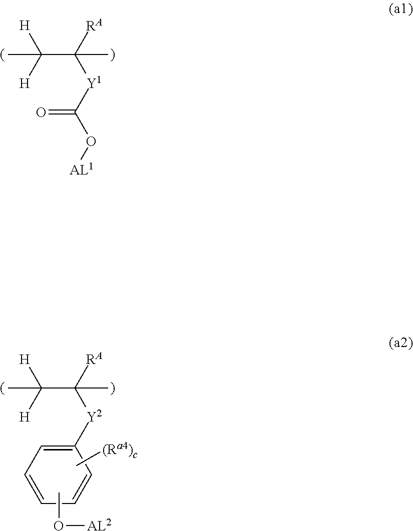

In formulae (a1) and (a2), R^{A} is hydrogen, fluorine, methyl, or trifluoromethyl. Y¹ is a single bond, a phenylene group, a naphthylene group or *—C(═O)—O—Y¹¹, Y¹¹ is a C₁-C₁₀ saturated hydrocarbylene group which may contain a hydroxy moiety, ether bond, ester bond or lactone ring, or a phenylene or naphthylene group, Y² is a single bond or *—C(═O)—O—, the asterisk (*) designates a point of attachment to the carbon atom in the backbone, AL¹ and AL² are each independently an acid labile group having no triple bond, R¹ is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R¹¹ moieties may bond together to form a ring with the carbon atom to which they are attached when c≥2, and c is an integer of 0 to 4.

Examples of the acid labile group having no triple bond represented by AL¹ and AL² in formulae (a1) and (a2) are as shown in JP-A 2013-80033 and JP-A 2013-83821, but not limited thereto.

Typical of the acid labile group are groups of the following formulae (AL-1) to (AL-3).

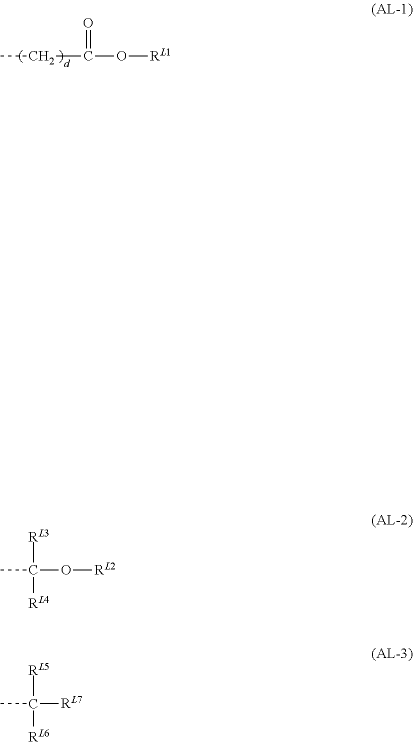

Herein the broken line denotes a valence bond.

In formulae (AL-1) and (AL-2), R^{L1} and R^{L2} are each independently a C₁-C₄₀ hydrocarbyl group, and may contain a heteroatom such as an oxygen atom, a sulfur atom, a nitrogen atom or a fluorine atom. The saturated hydrocarbyl group may be straight, branched or cyclic. The saturated hydrocarbyl group is preferably a C₁-C₂₀ hydrocarbyl group.

In formula (AL-1), d is an integer of 0 to 10, preferably an integer of 1 to 5.

In formulae (AL-2), R^{L3} and R^{L4} are each independently a hydrogen atom, a C₁-C₂₀ saturated hydrocarbyl group, and may contain a heteroatom such as an oxygen atom, a sulfur atom, a nitrogen atom or a fluorine atom. The hydrocarbyl group may be straight, branched or cyclic. Any two of R^{L2}, R^{L3} and R^{L4} may bond together to form a C₃-C₂₀ ring with a carbon atom to which they are attached, or a carbon atom or an oxygen atom. The ring is preferably a C₄-C₁₆ ring particularly preferably in an alicyclic form.

In formula (AL-3), R^{L5}, R^{L6} and R^{L7} are each independently a C₁-C₂₀ saturated hydrocarbyl group, and may contain a heteroatom such as an oxygen atom, a sulfur atom, a nitrogen atom or a fluorine atom. The hydrocarbyl group may be straight, branched or cyclic. Any two of R^{L5}, R^{L6} and R^{L7} may bond together to form a C₃-C₂₀ ring with a carbon atom to which they are attached. The ring is preferably a C₄-C₁₆ ring particularly preferably in an alicyclic form.

Examples of repeat unit a1 are shown below, but not limited thereto. Herein, R^{A} and AL¹ are as defined above.

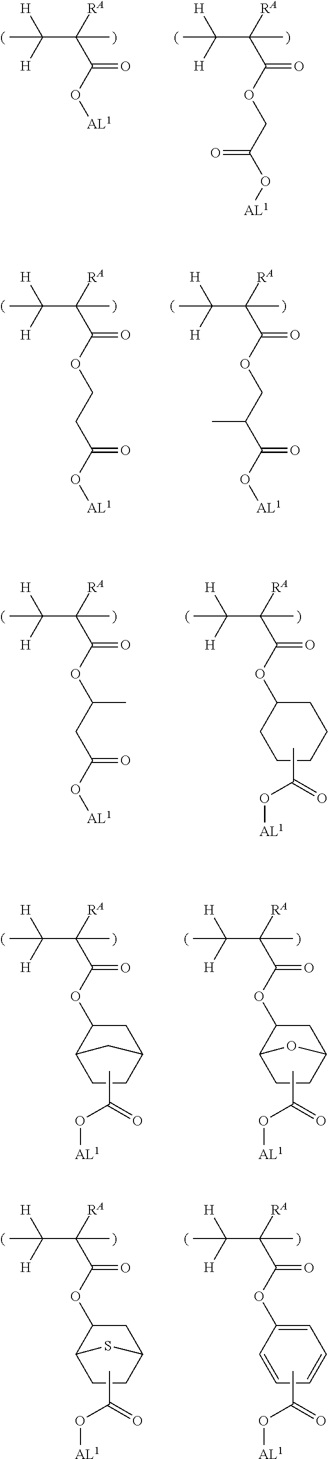

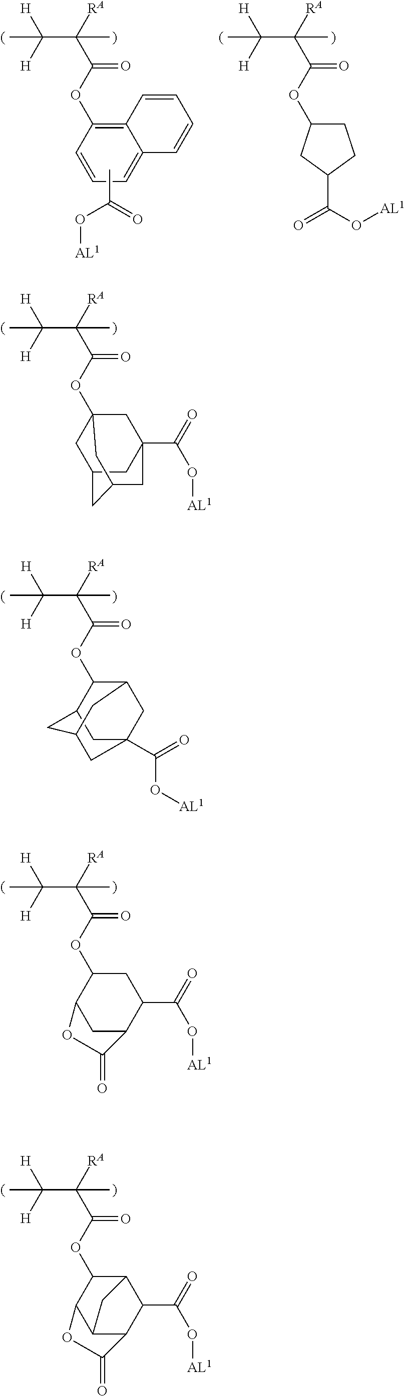

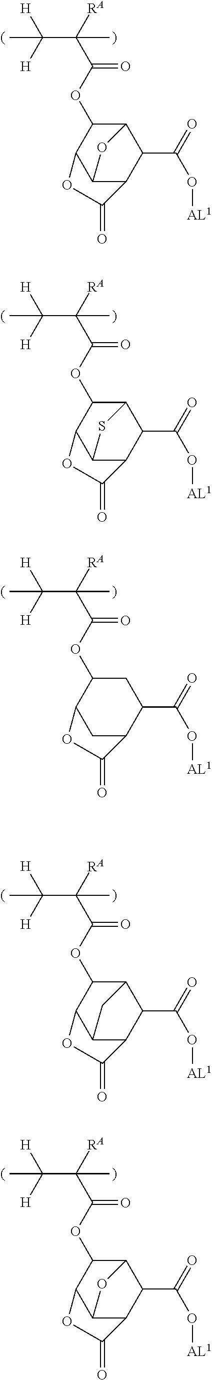

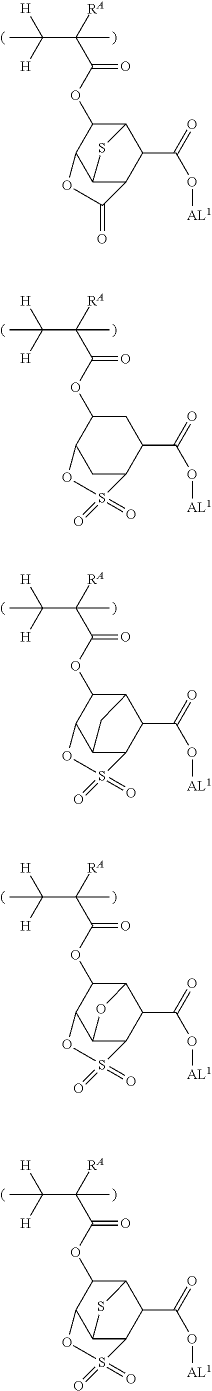

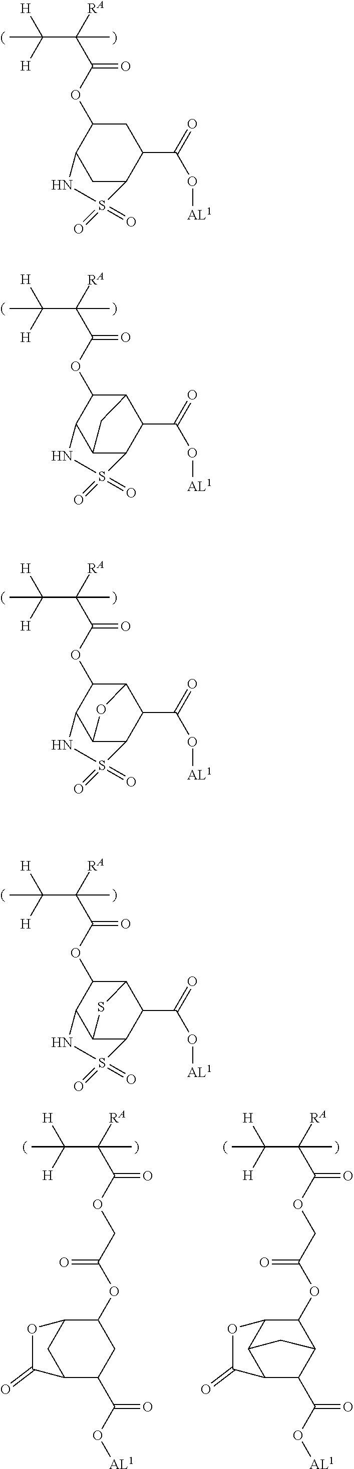

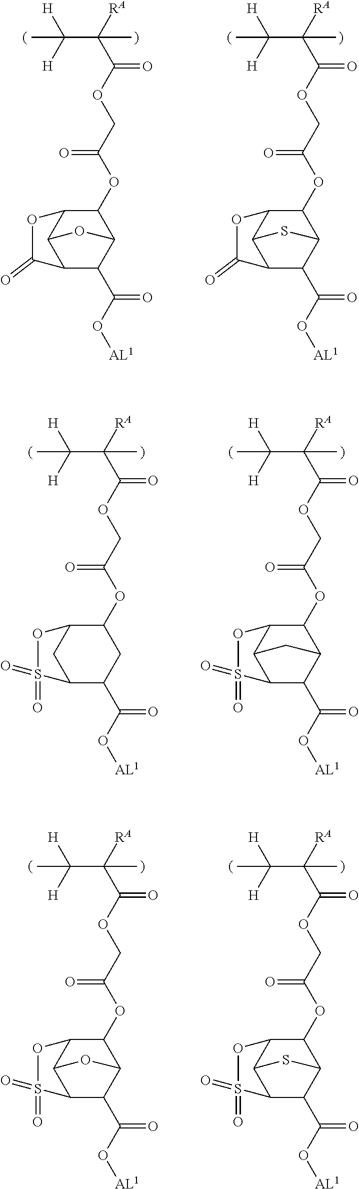

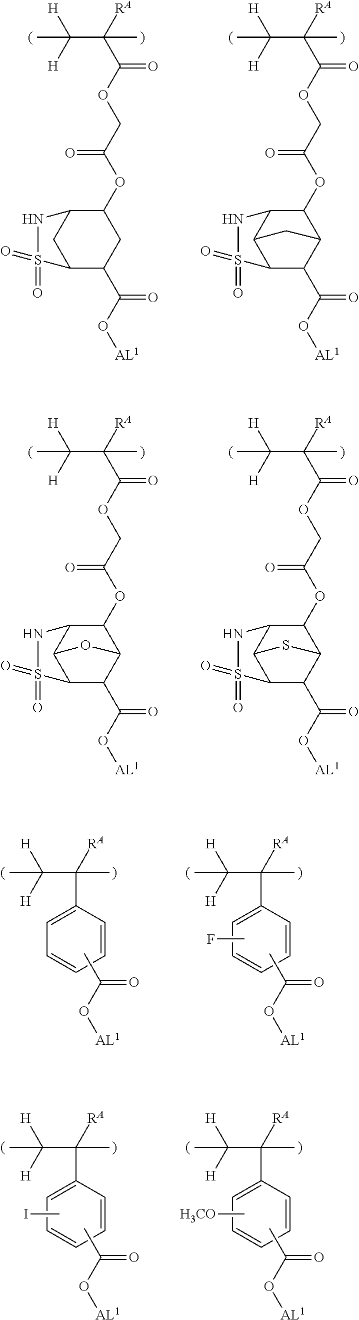

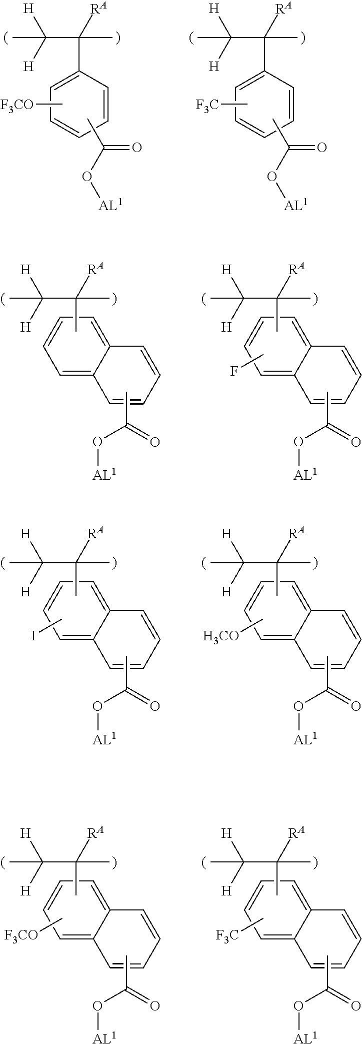

Examples of repeat unit a2 are shown below, but not limited thereto. Herein, R^{A} and AL² are as defined above.

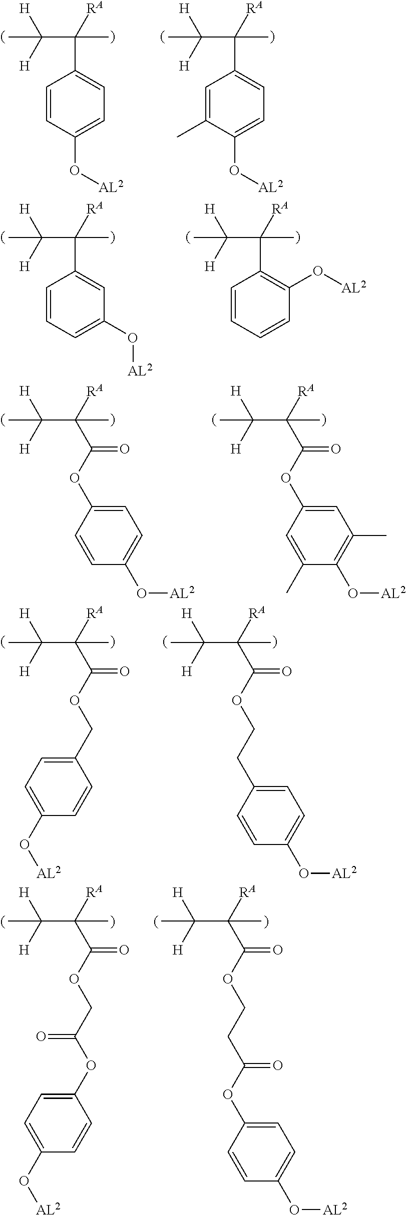

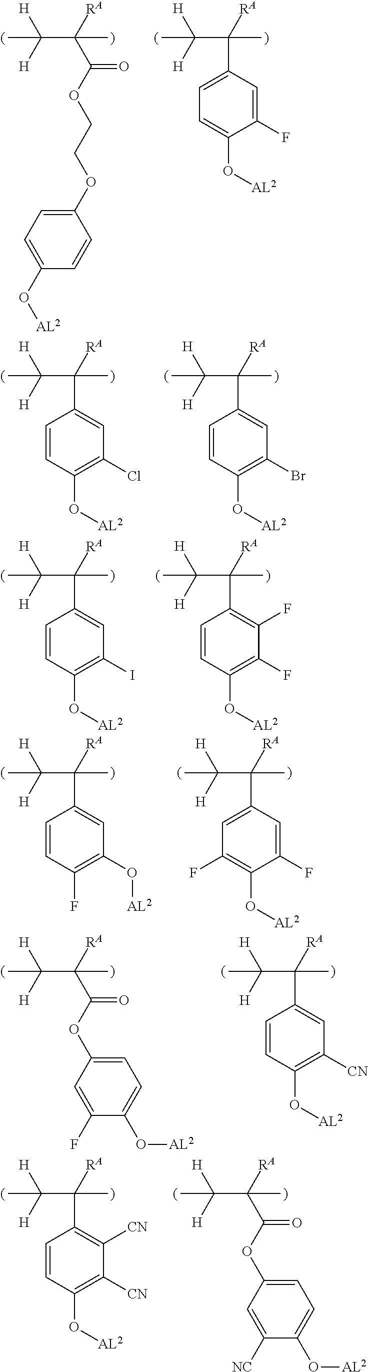

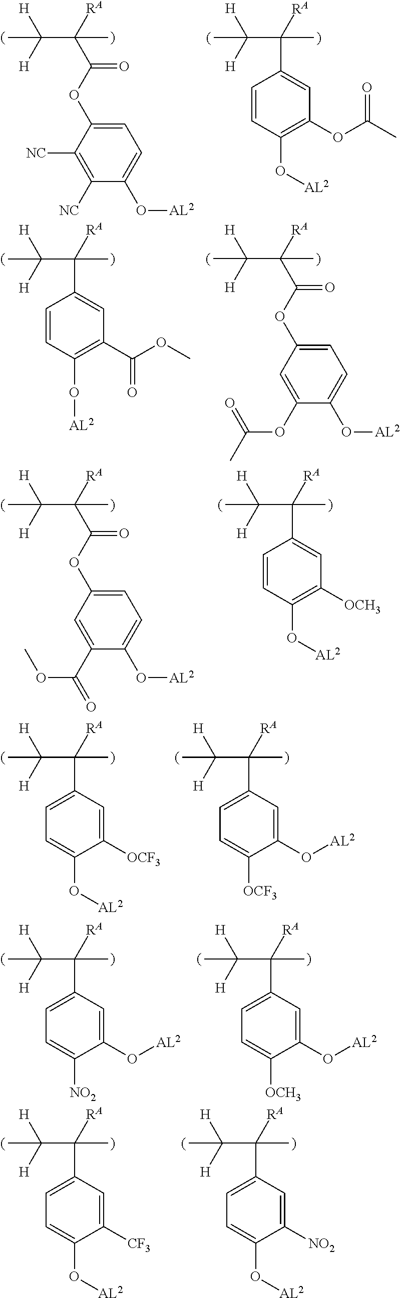

The polymer as component (A) may further comprise repeat units represented by the formula (C1), which are also referred to as repeat units C.

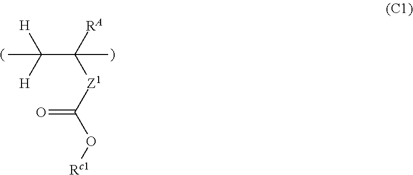

In formula (C1), R^{A} is hydrogen, fluorine, methyl group, or trifluoromethyl. Z¹ is a single bond, a phenylene group, a naphthylene group or *—C(═O)—O—Z¹¹—, Z¹¹ is a C₁-C₁₀ saturated hydrocarbylene group which may contain a hydroxy moiety, ether bond, ester bond or lactone ring, or a phenylene or naphthylene group, the asterisk (*) designates a point of attachment to the carbon atom in the backbone, R^{c1} is hydrogen, or a C₁-C₂₀ group containing at least one structure selected from a hydroxy moiety other than a phenolic hydroxy moiety, a cyano moiety, a carbonyl moiety, a carboxy moiety, an ether bond, an ester bond, a sulfonic ester bond, a sulfonic amide bond, a carbonate bond, a lactone ring, a sultone ring, a sulfur atom and carboxylic anhydride (—C(═O)—O—C(═O)—).

Examples of repeat unit C are shown below, but not limited thereto. Herein, R^{A} is as defined above.

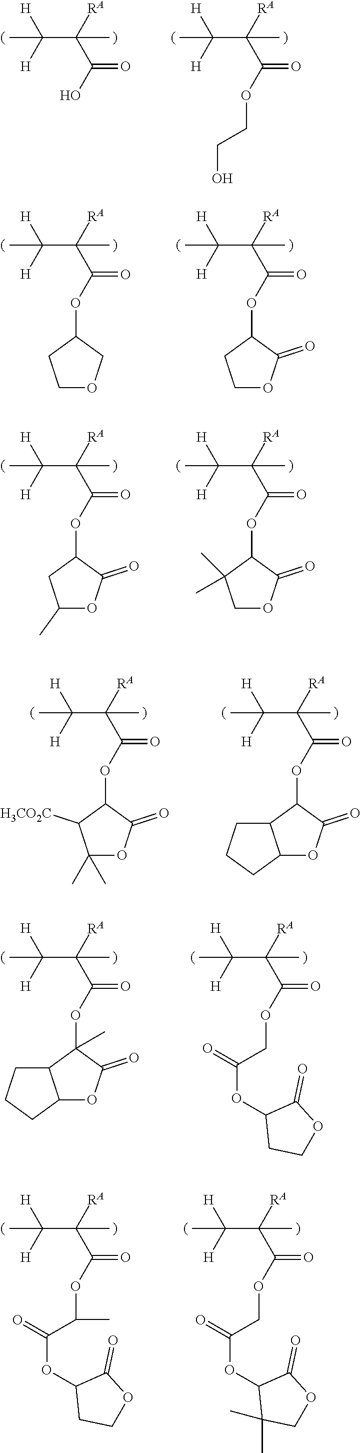

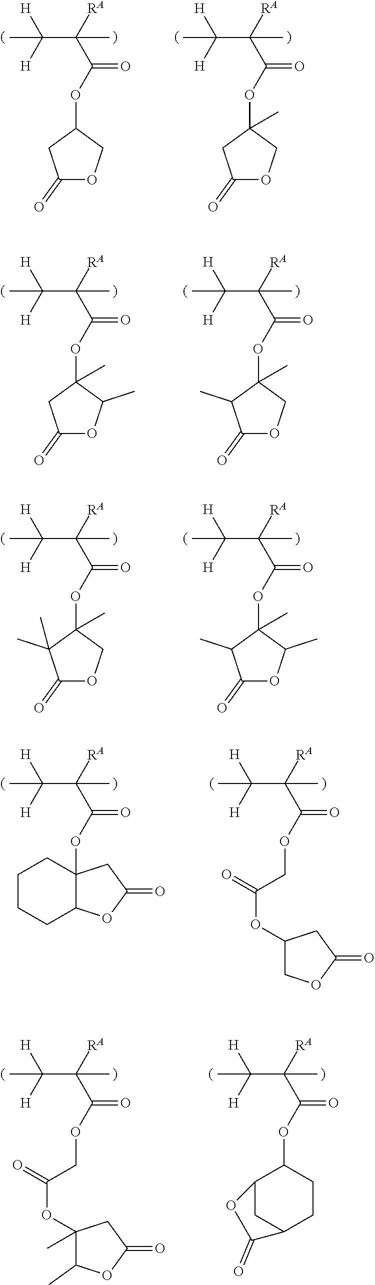

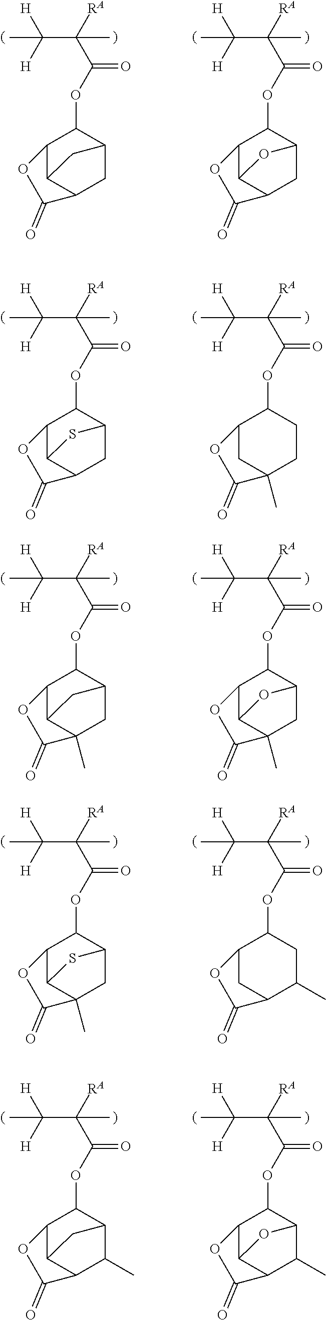

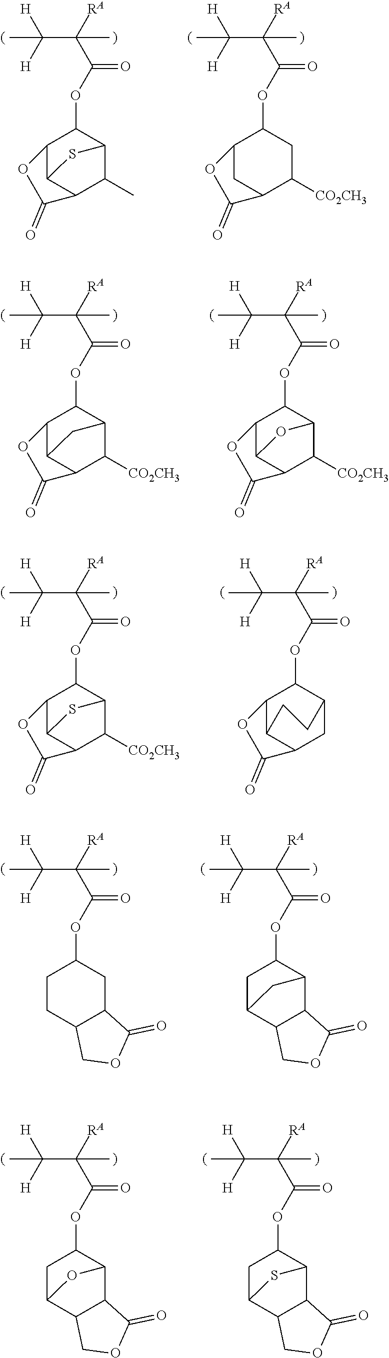

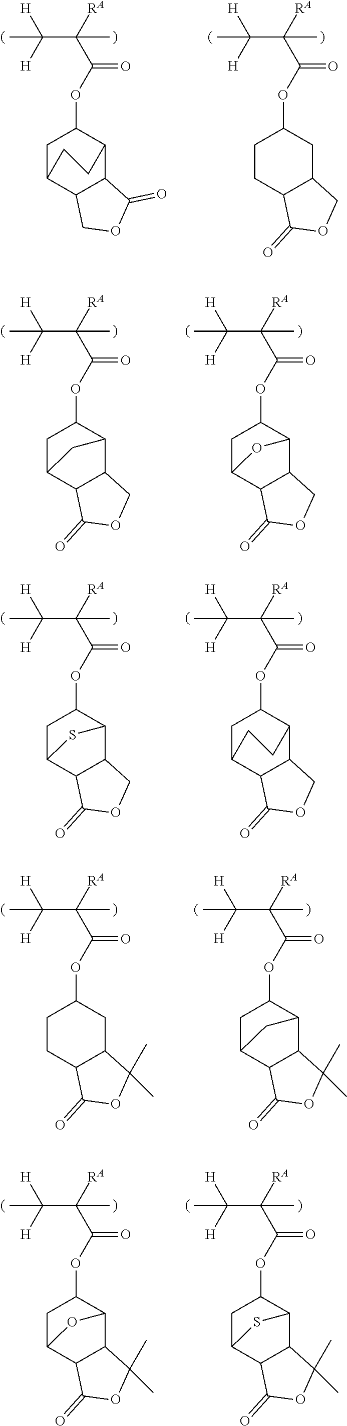

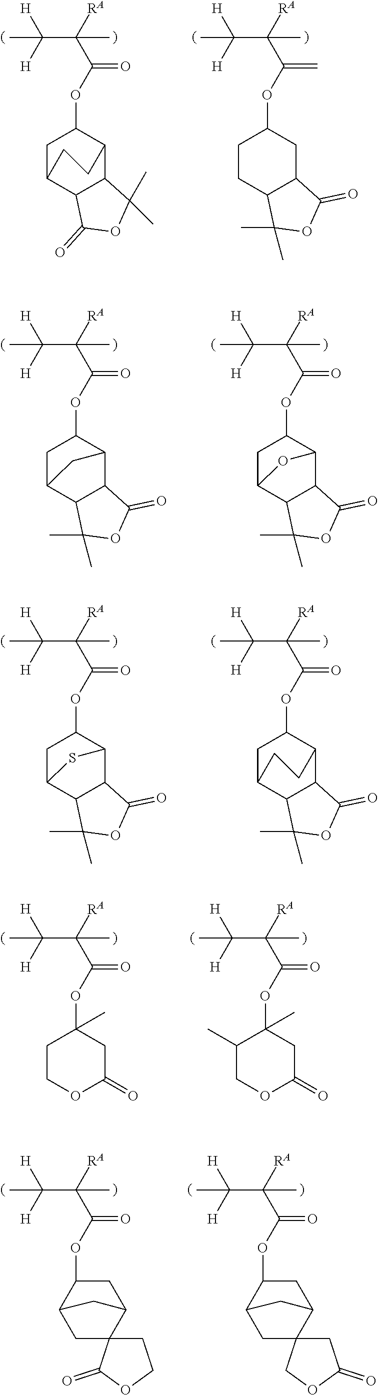

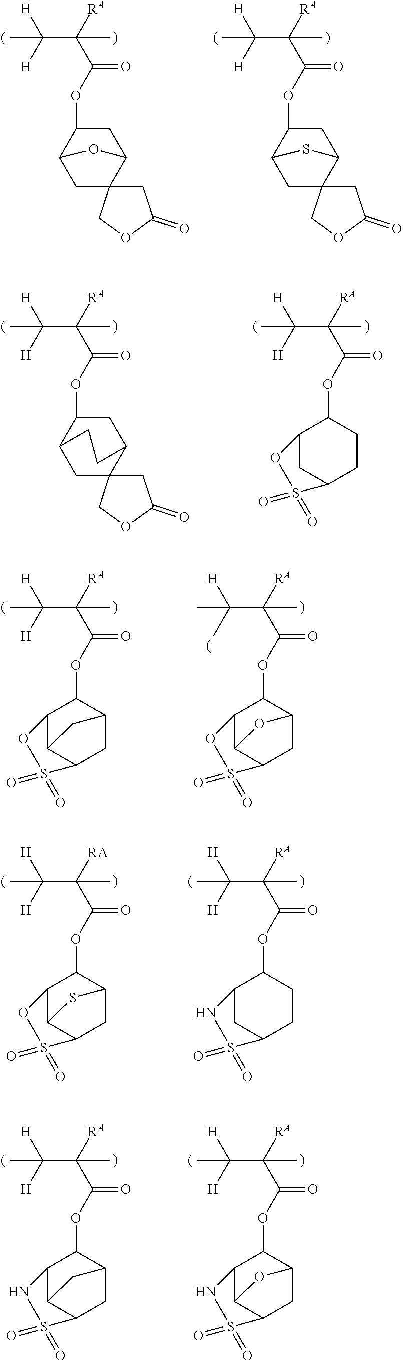

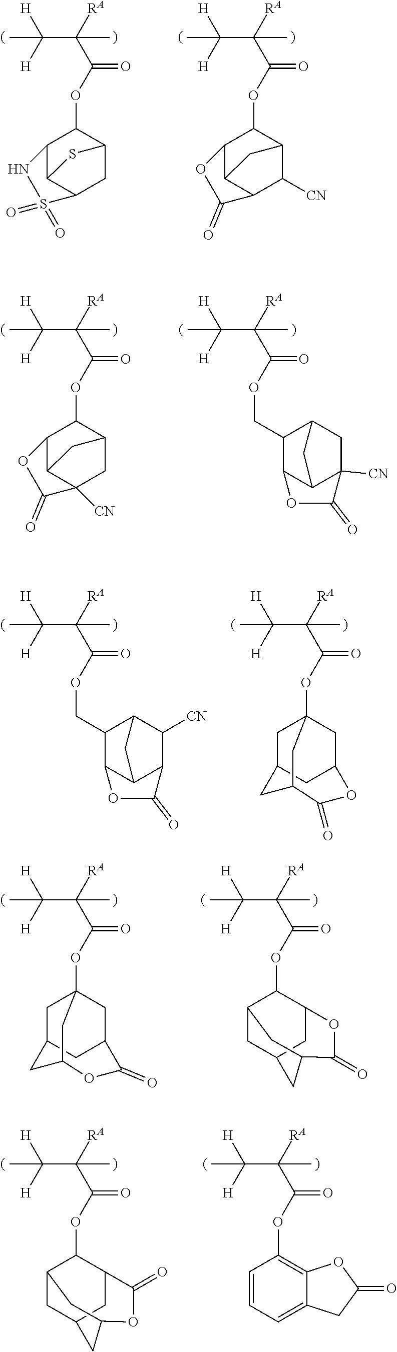

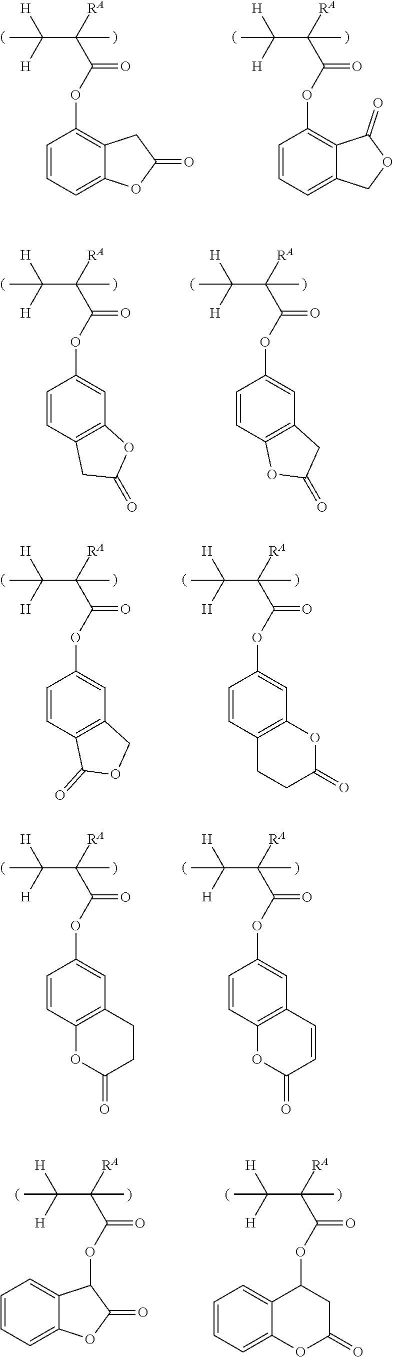

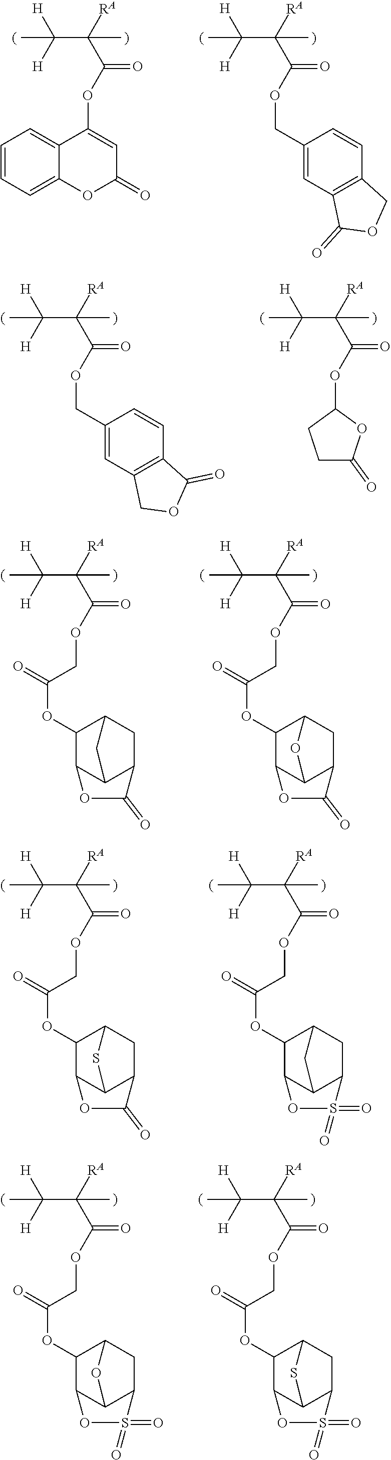

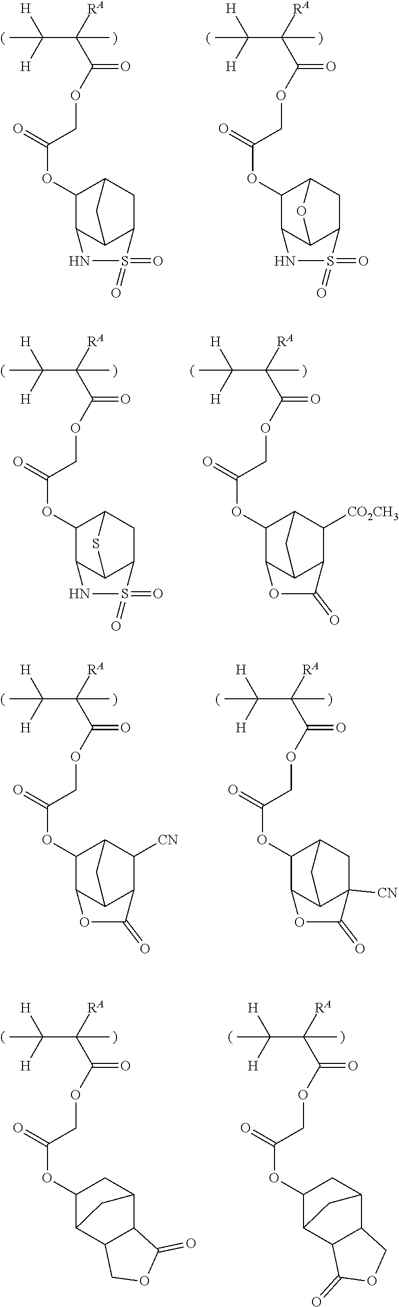

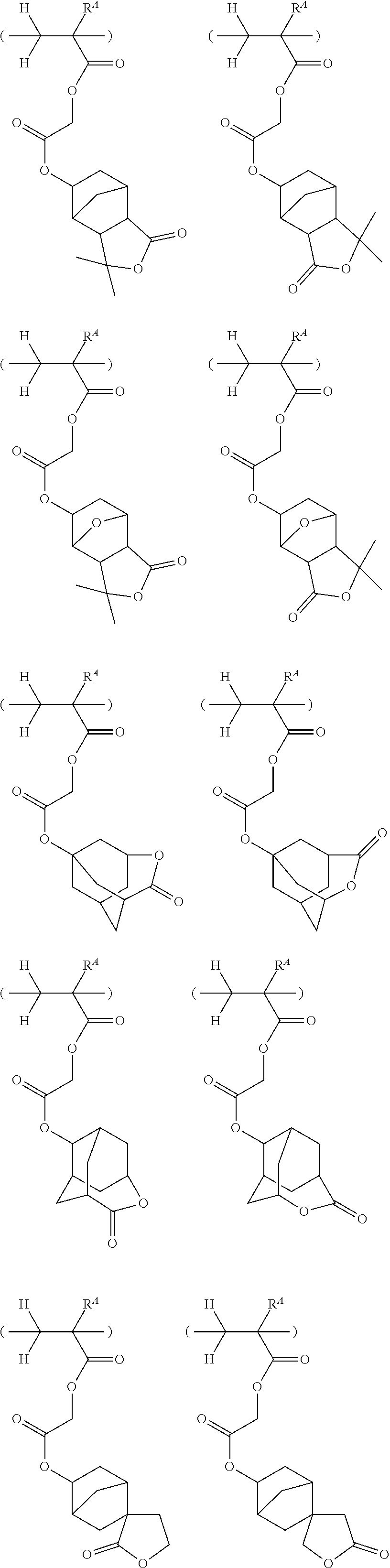

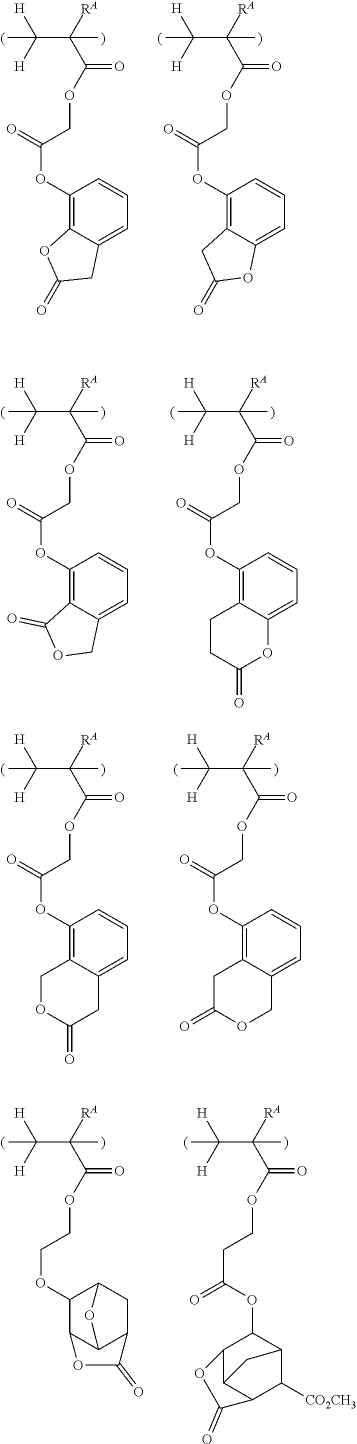

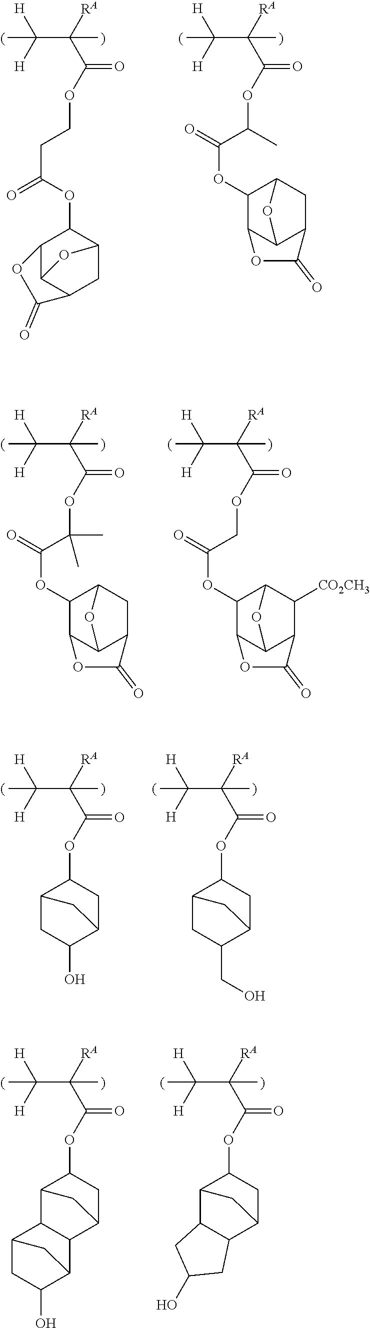

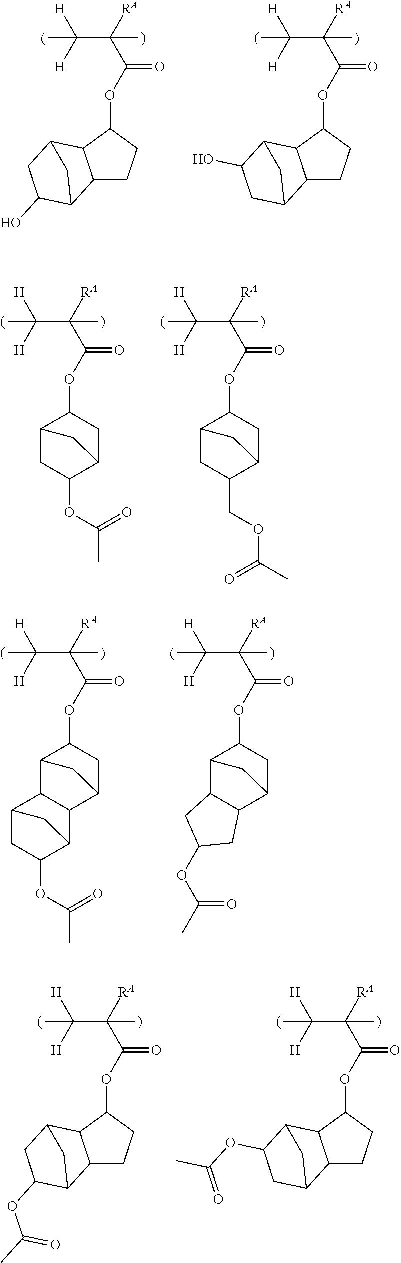

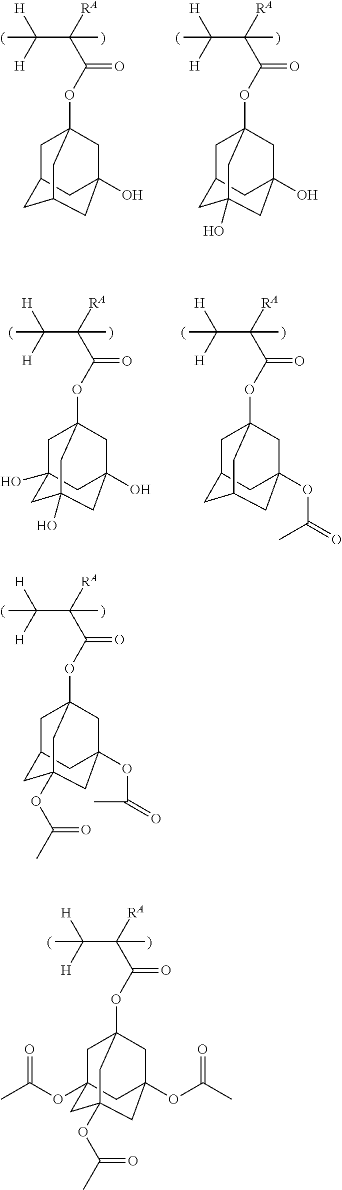

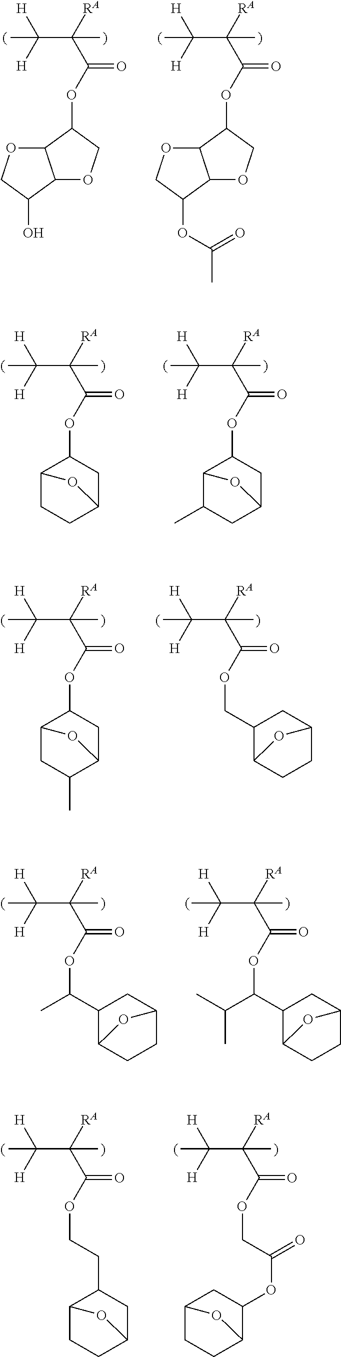

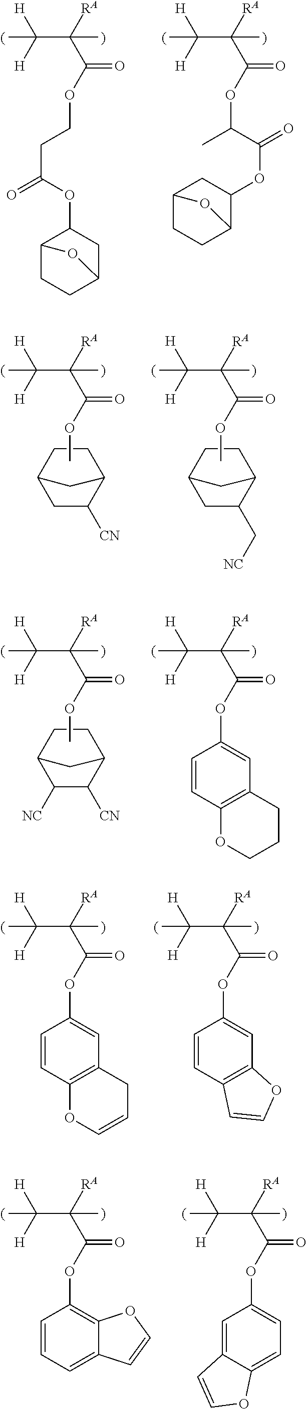

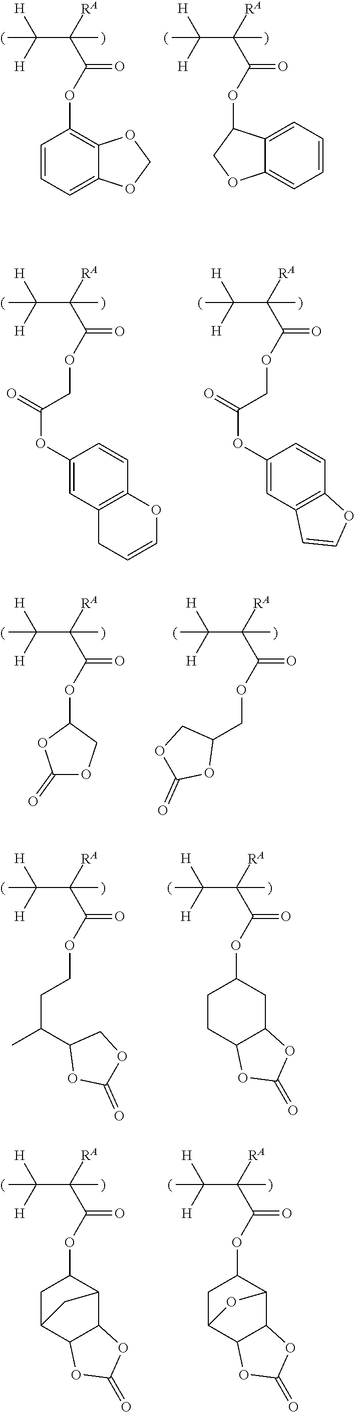

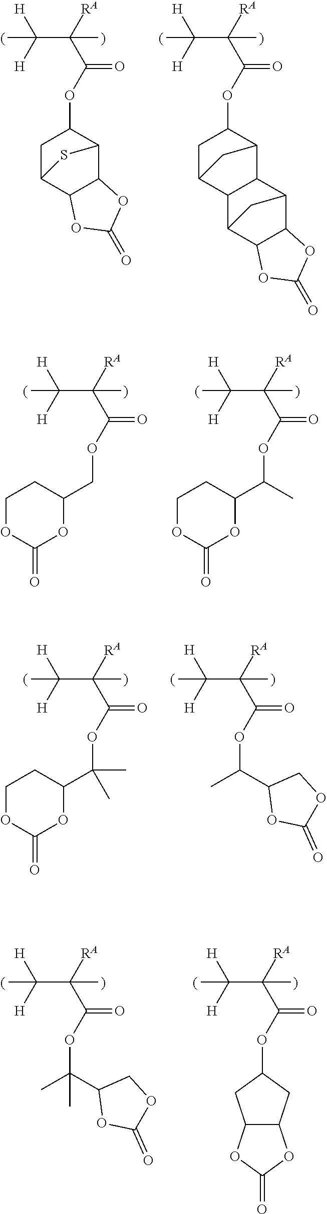

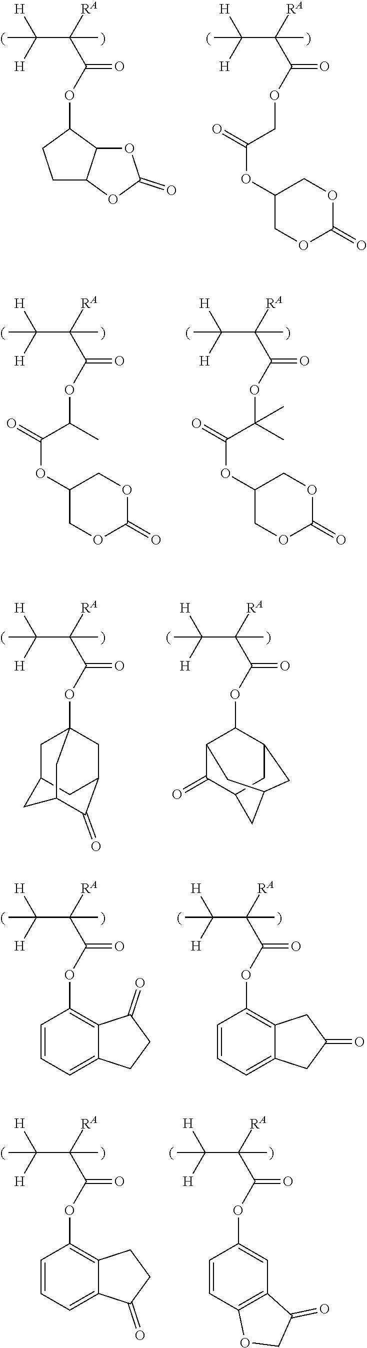

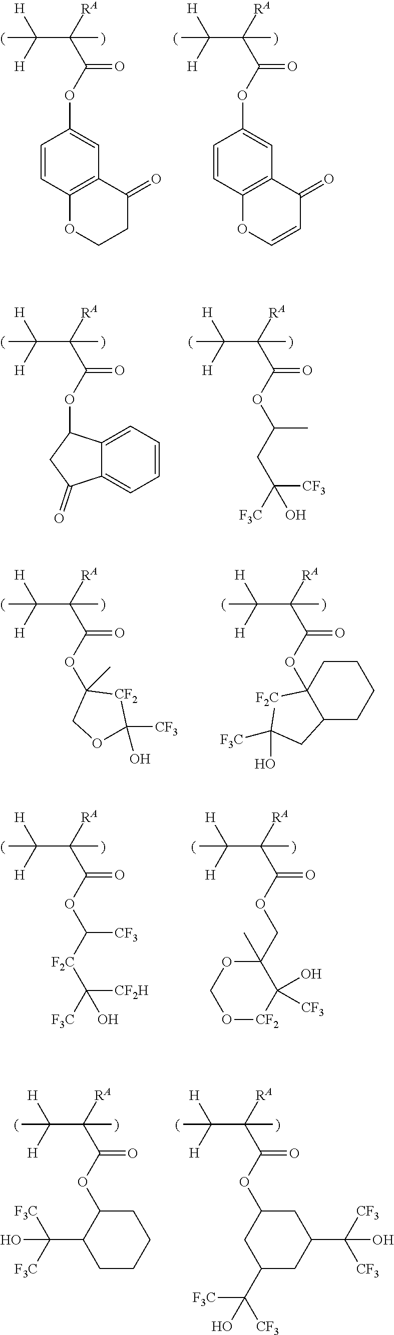

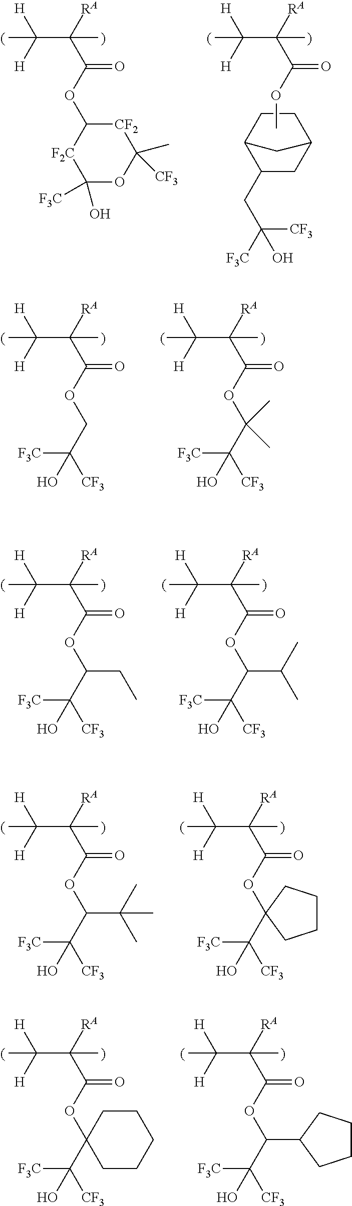

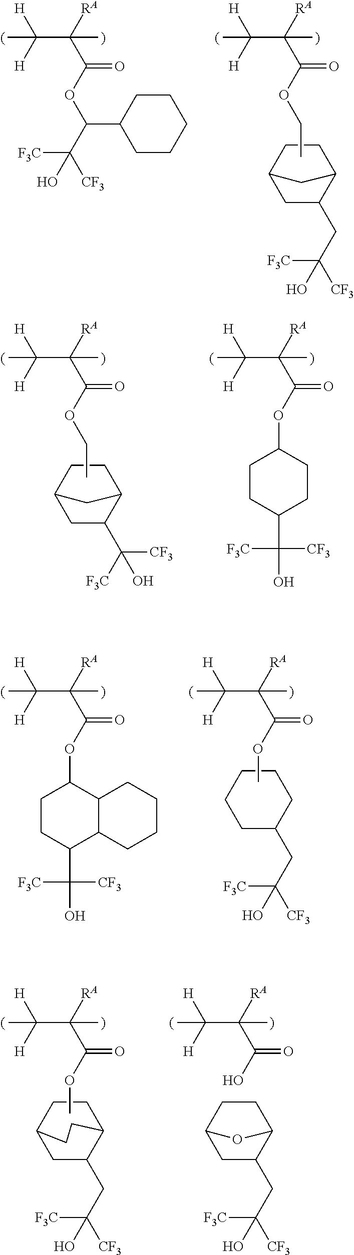

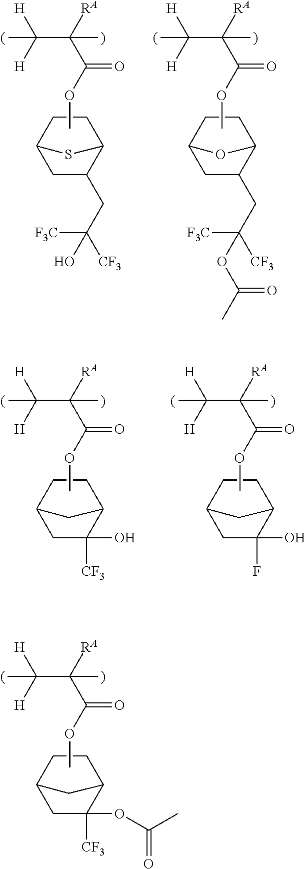

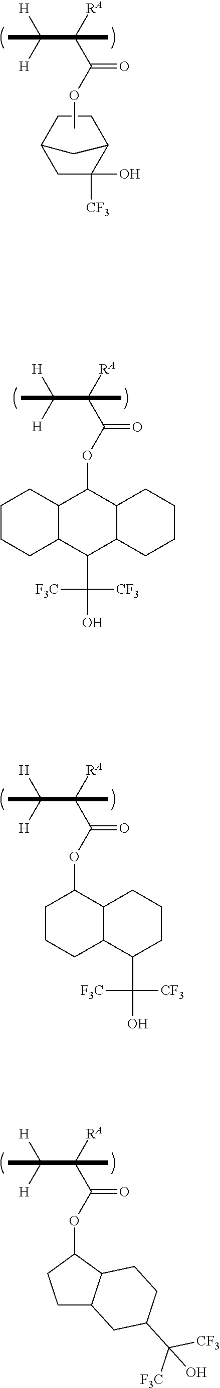

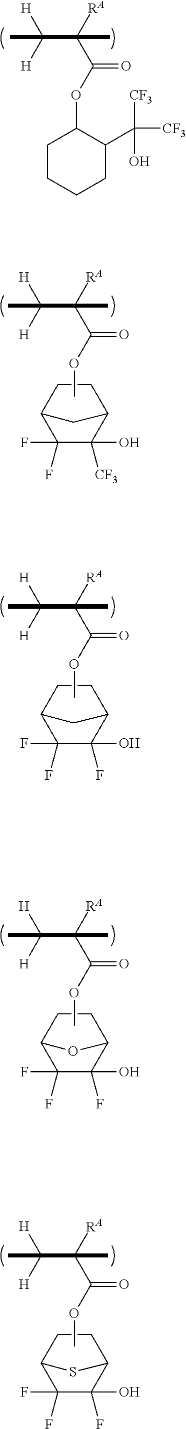

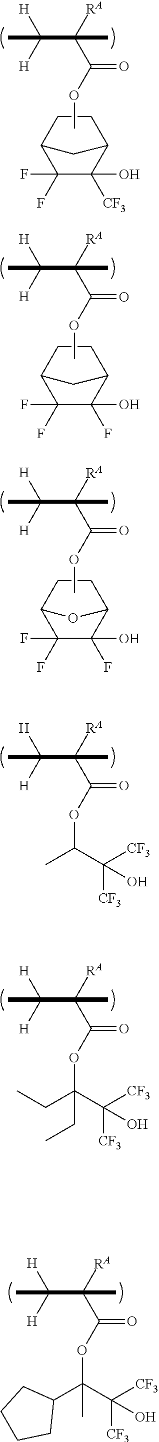

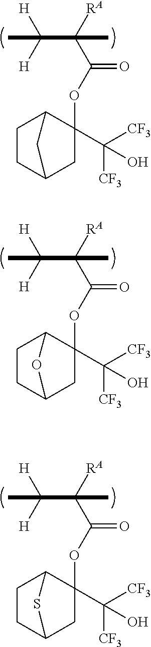

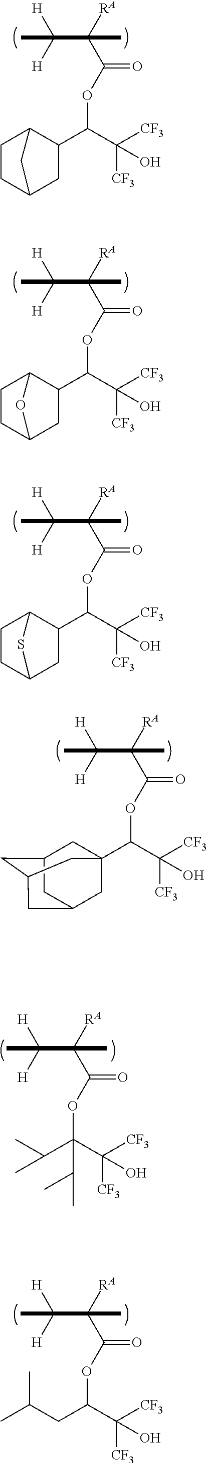

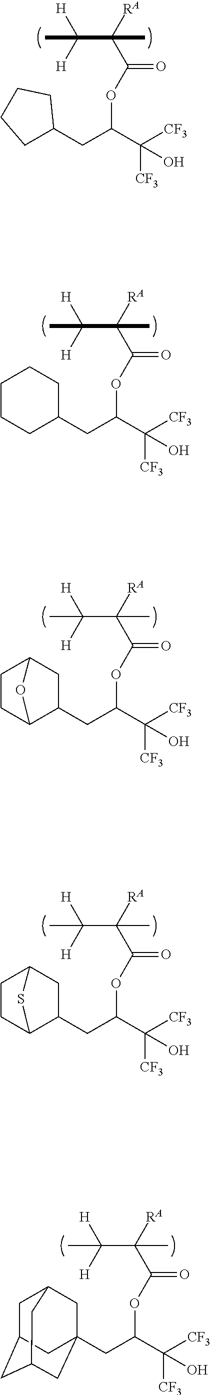

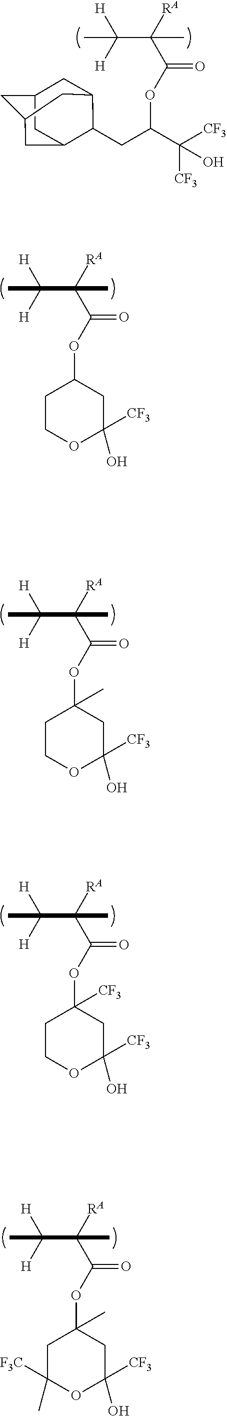

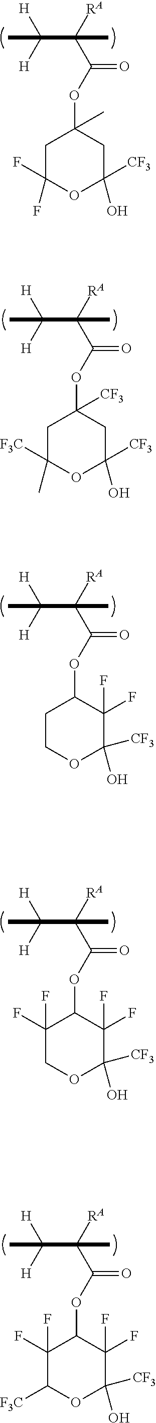

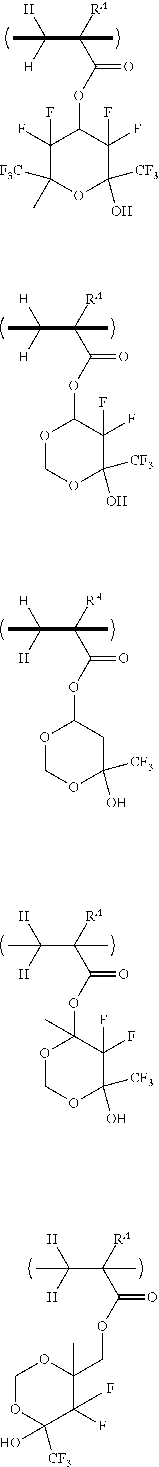

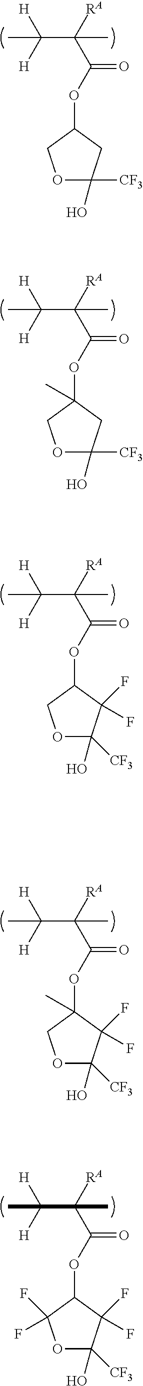

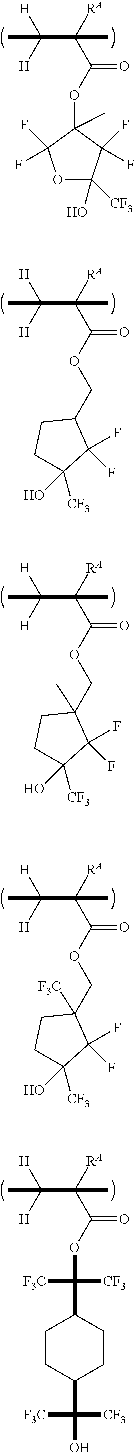

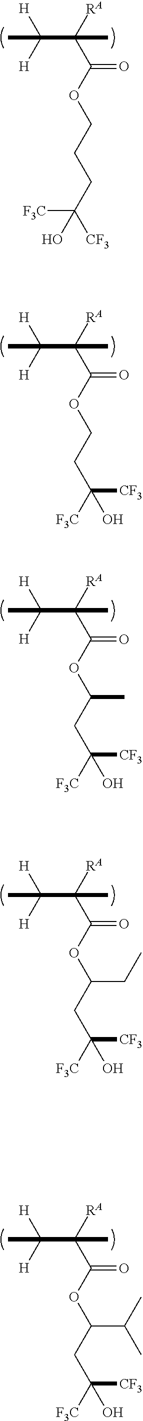

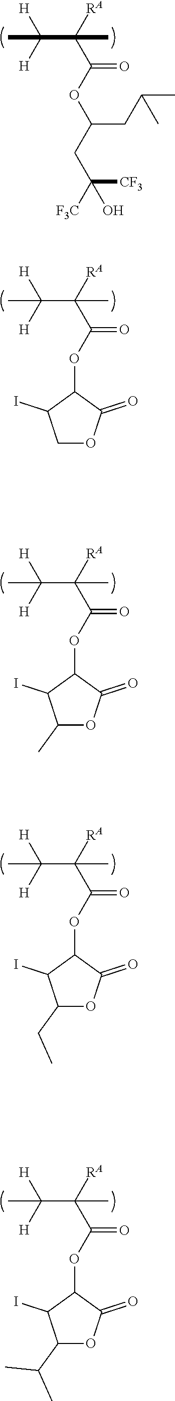

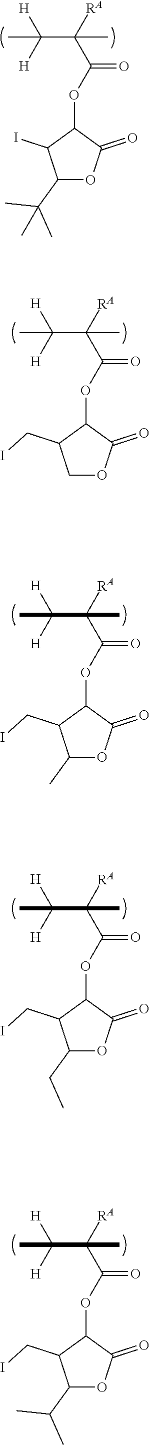

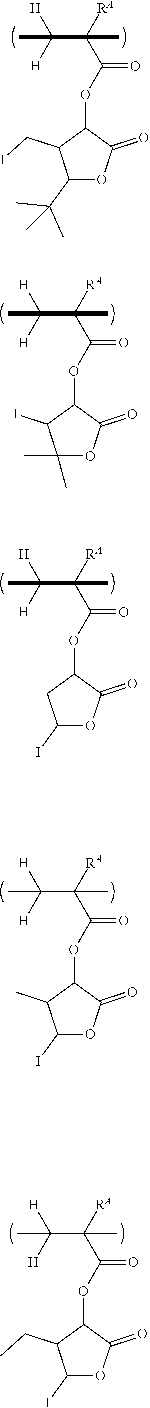

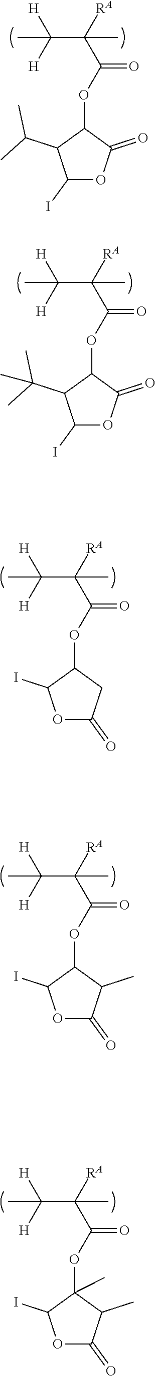

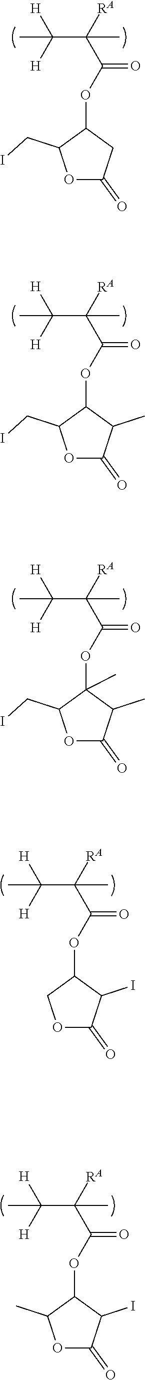

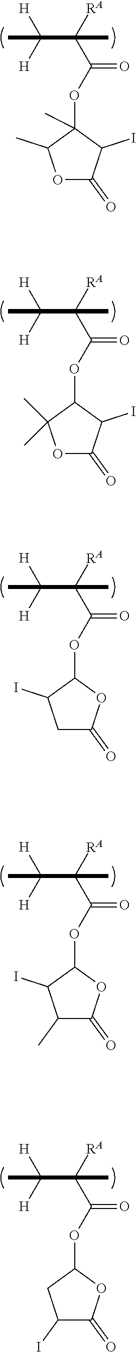

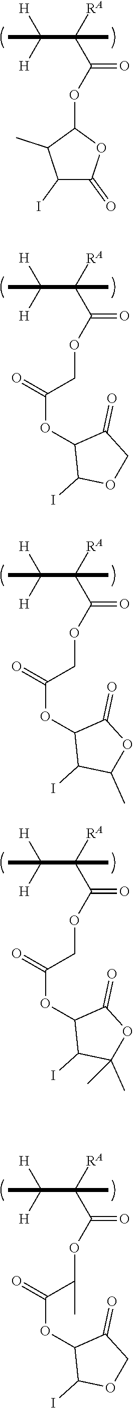

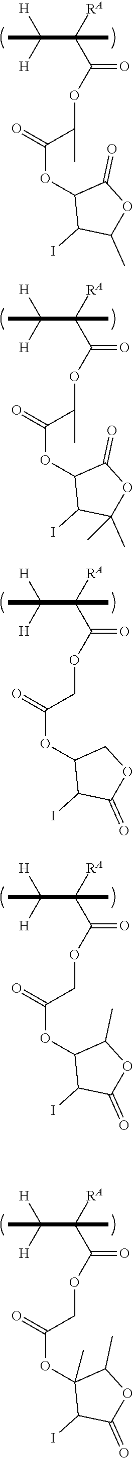

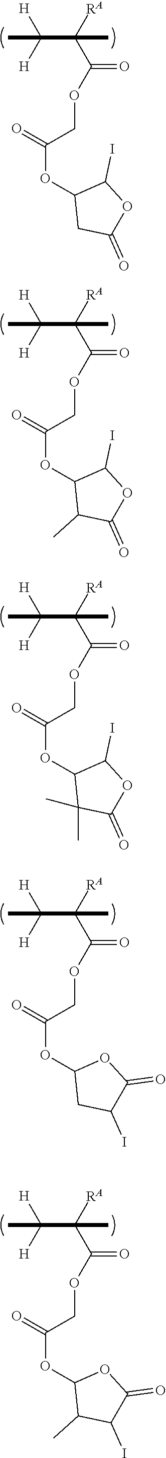

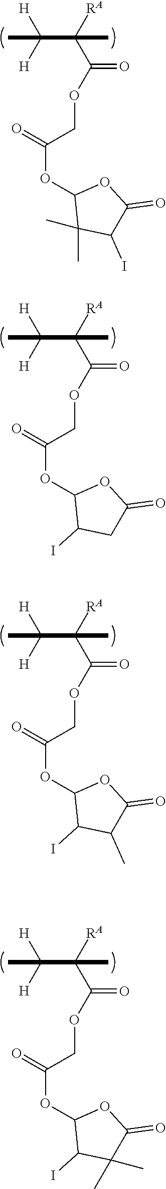

The polymer as component (A) may further comprise repeat units D derived from indene, benzofuran, benzothiophene, acenaphthylene, chromone, coumarin, and norbornadiene, or derivatives thereof. Examples of the monomer from which repeat units D are derived are shown below, but not limited thereto.

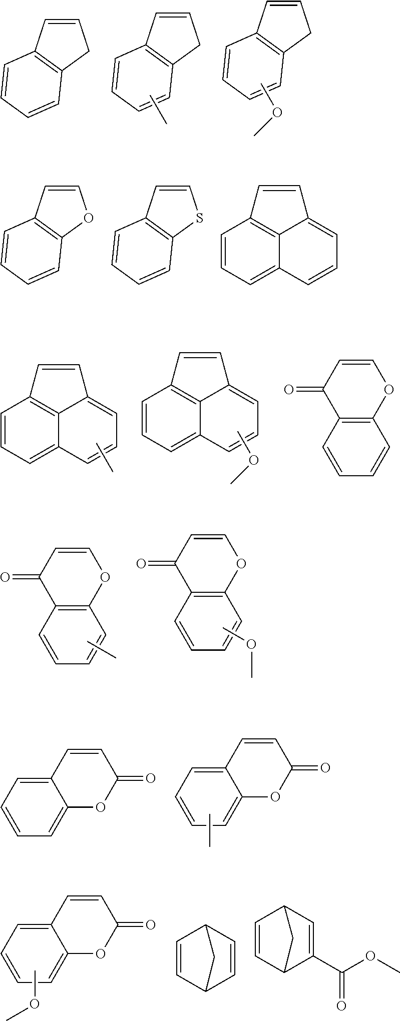

The polymer as component (A) may comprise repeat units E derived from indane, vinylpyridine or vinylcarbazole.

While the polymer comprises repeat units A, a1, a2, B, C, D, and E, a fraction of units is: preferably 0<A<1.0, 0≤a1≤0.8, 0≤a2≤0.8, 0≤a1+a2≤0.8, 0<B<1.0, 0≤C<1.0, 0≤D≤0.8 and 0≤E≤0.4;
more preferably 0.05≤A≤0.9, 0≤a1≤0.7, 0≤a2≤0.7, 0≤a1+a2≤0.7, 0.01≤B≤0.7, 0.0≤C≤0.55, 0≤D≤0.7 and 0≤E≤0.3;
even more preferably 0.1≤A≤0.8, 0≤a1≤0.6, 0≤a2≤0.6, 0≤a1+a2≤0.60, 0.05≤B≤0.6, 0≤C≤0.5, 0≤D≤0.5 and 0≤E≤0.2.

The polymer should preferably have a weight average molecular weight (Mw) in the range of 1,000 to 500.000, and more preferably 3,000 to 100,000, as measured by GPC versus polystyrene standards using tetrahydrofuran (THF) or N,N-dimethylformamide (DMF) solvent. A polymer having the range of Mw provides sufficient etching resistance and eliminates the risk of resolution lowering from a failure to establish a difference in dissolution rate before and after exposure.

Since the influence of dispersity (Mw/Mn) becomes stronger as the pattern rule becomes finer, the polymer should preferably have a narrow dispersity (Mw/Mn) of 1.0 to 2.0 in order to provide a resist composition suitable for micropatterning to a small feature size. A Mw/Mn in the range indicates smaller amounts of lower and higher molecular weight fractions and eliminates the risk of leaving foreign matter on the pattern or degrading the pattern profile after exposure and development.

Examples of the method for synthesizing the polymer include a method in which one or more monomers selected from the monomers corresponding to the foregoing repeat units are dissolved in an organic solvent, a radical polymerization initiator is added thereto, and the mixture is heated for polymerization.

Examples of the organic solvent which can be used for polymerization include toluene, benzene, tetrahydrofuran THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the initiator added is preferably 0.01 to 25 mol % based on the total of monomers. The reaction temperature is preferably 50 to 150° C., more preferably 60 to 100° C. The reaction time is preferably 2 to 24 hours, a time of 2 to 12 hours being more preferred in view of production efficiency.

The polymerization initiator may be added to the monomer solution, which is fed to the reactor. Alternatively, a solution of the polymerization initiator is prepared separately from the monomer solution, and the monomer and initiator solutions be independently fed to the reactor. Since there is a possibility that the initiator generates a radical in the standby time, by which polymerization reaction takes place to form an ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to polyhydroxystyrene or hydroxypolyvinylnaphthalene.

For alkaline hydrolysis, a base such as aqueous ammonia or triethylamine may be used. Preferably the reaction temperature is −20° C. to 100° C., more preferably 0° C. to 60° C. The reaction time is 0.2 to 100 hours, more preferably 0.5 to 20 hours.

The amounts of monomers in the monomer solution may be determined appropriate so as to provide the preferred fractions of repeat units as mentioned above.

The reaction solution resulting from polymerization reaction may be used as the final product. Alternatively, the polymer may be recovered in powder form through a purifying step such as re-precipitation step of adding the reaction solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product.

The solvents which can be used herein are described in JP-A 2008-111103, paragraphs [0144]-[0145]. Exemplary solvents include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; alcohols such as diacetone alcohol (DAA); and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign matter and gel which can cause defects are removed.

Suitable materials of which the filter is made include fluorocarbon, cellulose, nylon, polyester, and hydrocarbon base materials. Preferred for the filtration of an amplified resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 mu, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

The polymer may be a blend of two or more polymers which differ in compositional ratio, Mw or Mw/Mn.

(B) Photoacid Generator

The photoacid generator as component (B) is a compound represented by the formula (PAG-a) or (PAG-b). The photoacid generator generates an acid under the action of KrF excimer laser, ArF excimer laser, EB or EUV.

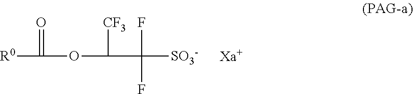

In formula (PAG-a), R⁰ is hydrogen or a C₁-C₅₀ hydrocarbyl group, some or all of the hydrogen atoms of the hydrocarbyl group may be substituted by halogen atoms, and some constituent —CH₂— of the hydrocarbyl group may be substituted by —O— or —C(═O)—. Xa⁺ is an organic cation.

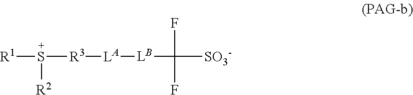

In formula (PAG-b), R¹ to R² are each independently a C₁-C₂₀ hydrocarbyl group which may contain a heteroatom. R¹ and R² may bond together to form a ring with the sulfur atom to which they are attached, R³ is a C₁-C₂₀ hydrocarbylene group which may contain a heteroatom, L^{A} is a divalent linking group, and L^{B} is a single bond, or a C₁-C₂₀ hydrocarbylene group which may contain a heteroatom.

The hydrocarbyl group R⁰ in formula (PAG-a) may be saturated or unsaturated and straight, branched or cyclic. Examples thereof include C₁-C₅₀ alkyl groups such as methyl, ethyl, n-propyl, isopropyl, n-butyl, isobutyl, sec-butyl and tert-butyl groups; C₃-C₅₀ cyclic saturated hydrocarbyl groups such as cyclopropyl, cyclopentyl, cyclohexyl, cyclopropylmethyl, 4-methylcyclohexyl, cyclohexylmethyl, norbornyl and adamantyl groups; C₂-C₅₀ alkenyl groups such as vinyl, allyl, propenyl, butenyl and hexenyl groups; C₃-C₅₀ cyclic unsaturated hydrocarbyl groups such as a cyclohexenyl group; C₆-C₅₀ aryl groups such as phenyl and naphthyl groups; C₇-C₅₀ aralkyl groups such as benzyl, 1-phenylethyl and 2-phenylethyl groups; C₂₀-C₃₈ hydrocarbyl groups having a steroid backbone, which may contain a heteroatom; and combinations thereof. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

Examples of the anion in the photoacid generator having formula (PAG-a) are shown below, but not limited thereto.

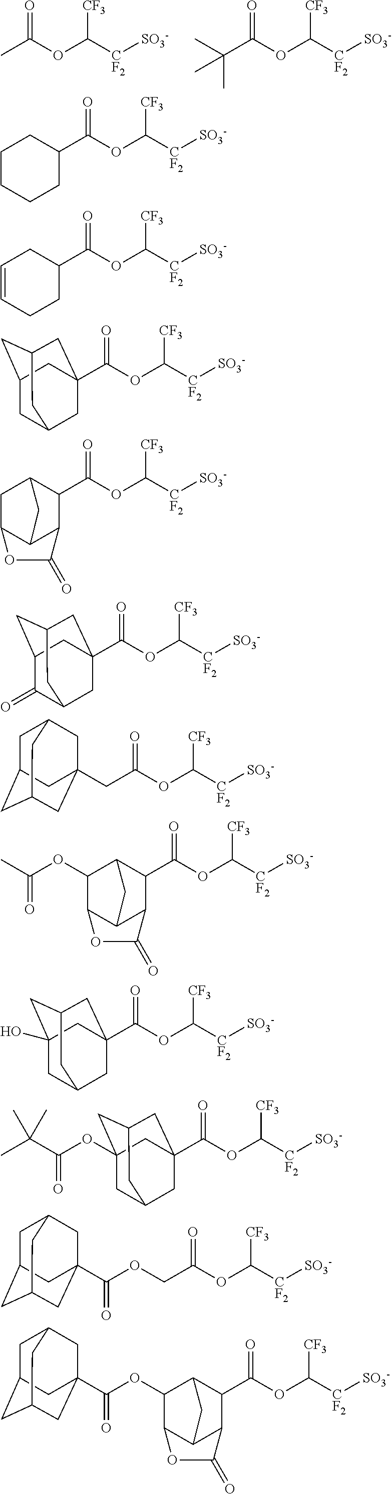

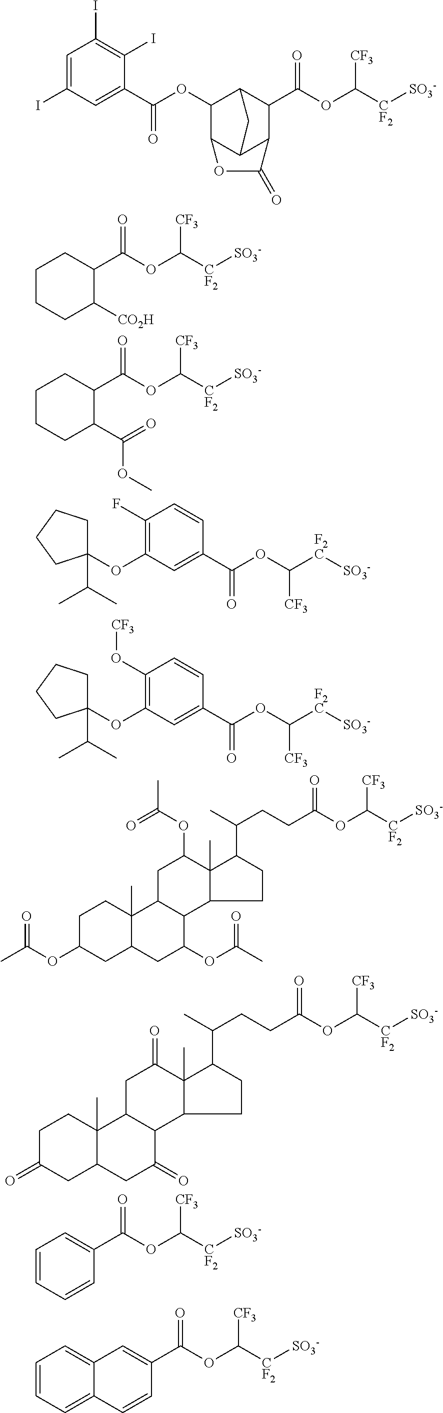

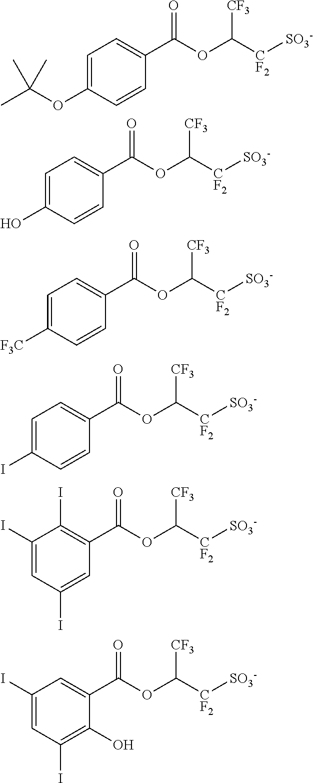

The organic cation Xa⁺ in formula (PAG-a) is preferably a sulfonium cation having the formula (Xa-1) or an iodonium cation having the formula (Xa-2).

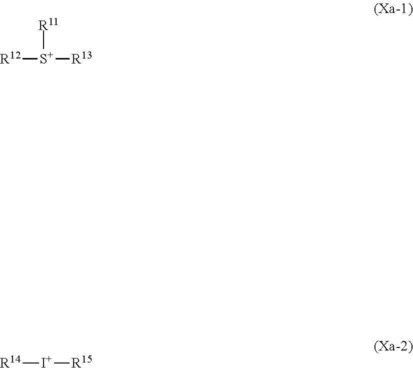

In formulae (Xa-1) and (Xa-2). R¹¹ to R¹⁵ are each independently a C₁-C₃₀ hydrocarbyl group which may contain a heteroatom. R¹¹ to R⁵ moieties may be saturated or unsaturated and straight, branched or cyclic. Examples thereof include C₁-C₃₀ alkyls such as methyl, ethyl, n-propyl, isopropyl, n-butyl, isobutyl, sec-butyl, tert-butyl, tert-pentyl, n-pentyl, n-hexyl, n-octyl, 2-ethylhexyl, n-nonyl and n-decyl groups; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2.6}] decyl, adamantyl and adamantylmethyl groups; C₆-C₃₀ aryl groups such as phenyl, naphthyl and anthracenyl groups; and combinations thereof. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, a thioether bond, an ester bond, a sulfonic ester bond, a carbonate bond, a carbamate bond, a lactone ring, a sultone ring, carboxylic anhydride (—C(═O)—O—C(═O)—), a haloalkyl group, or the like.

R¹¹ and R¹² may bond together to form a ring with the sulfur atom to which they are attached. Examples of the sulfonium cation represented by formula (Xa-1) have the following formula.

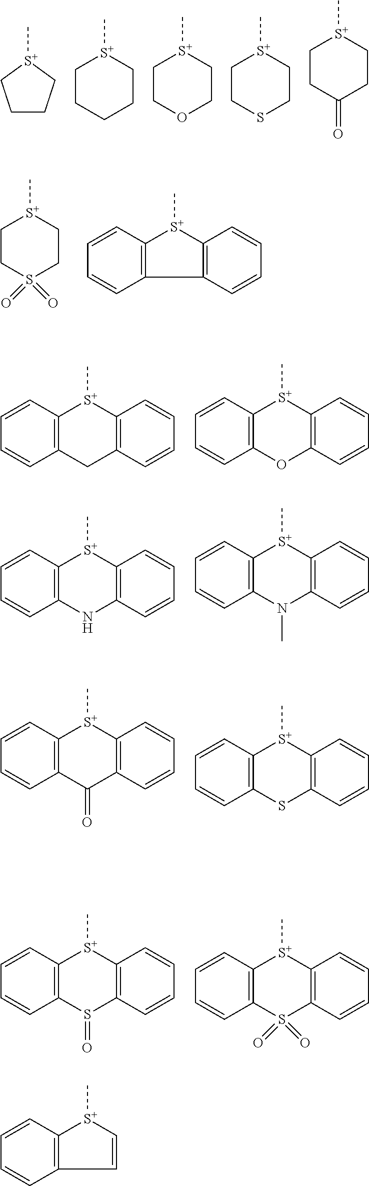

Herein the broken line denotes a valence bond.

Examples of the sulfonium cation represented by formula (Xa-1) are shown below, but not limited thereto.

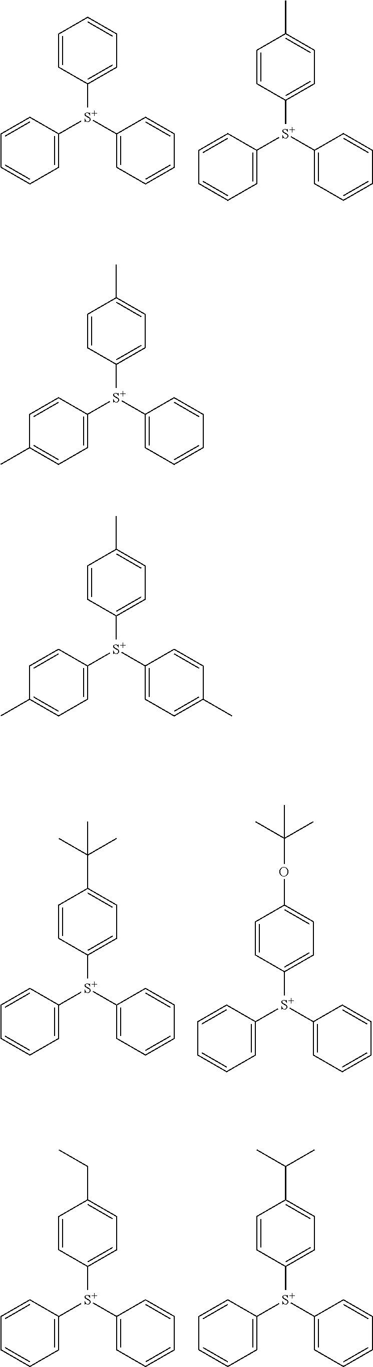

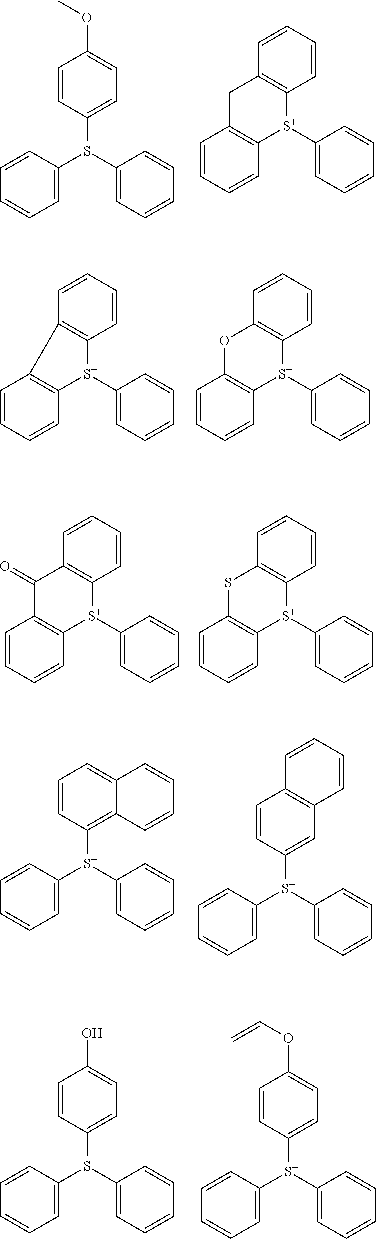

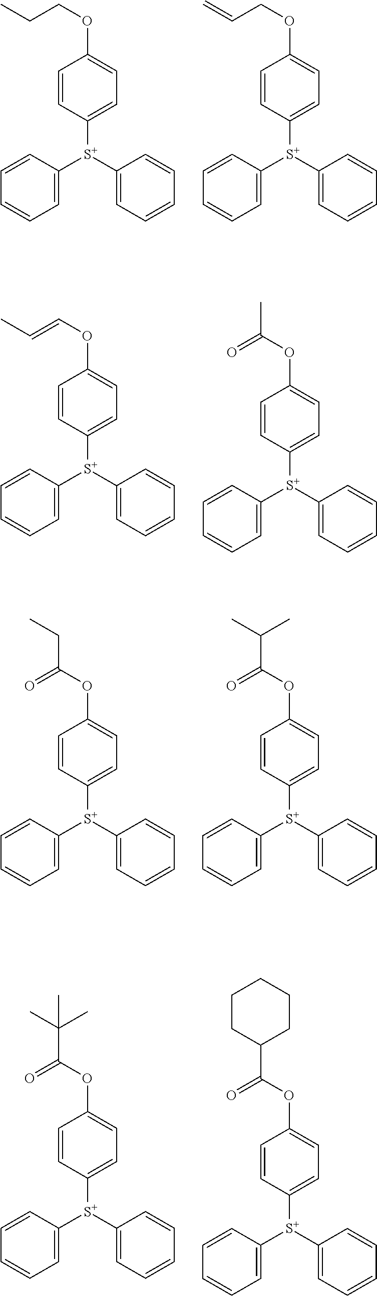

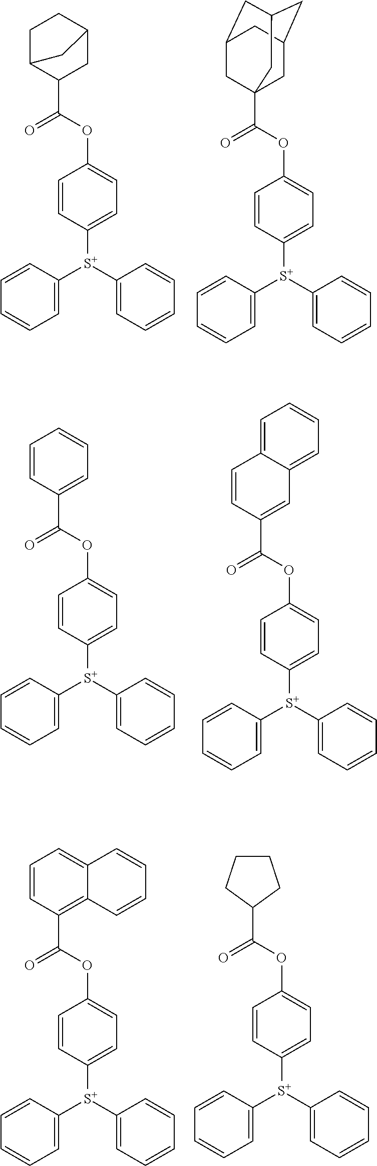 [SMILES: O=C(Oc1ccc([S+](c2ccccc2)c2ccccc2)cc1)C1CC2CCC1C2 ; O=C(Oc1ccc([S+](c2ccccc2)c2ccccc2)cc1)C12CC3CC(CC(C3)C1)C2 ; O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1 ; O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1]

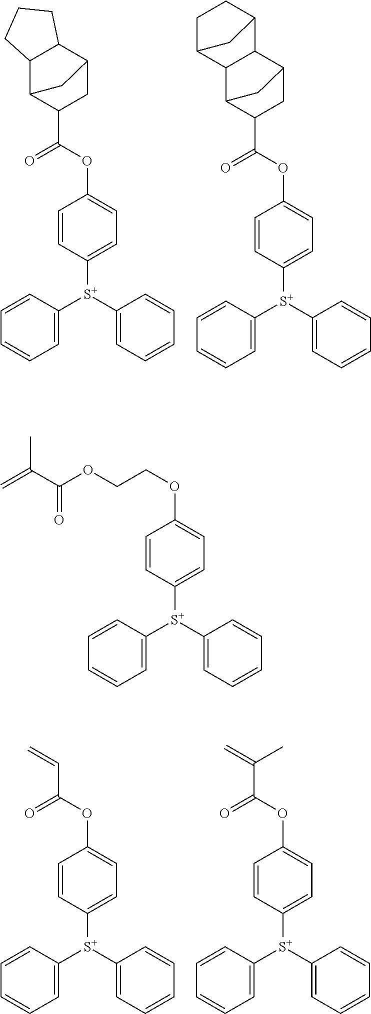 [SMILES: O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1]

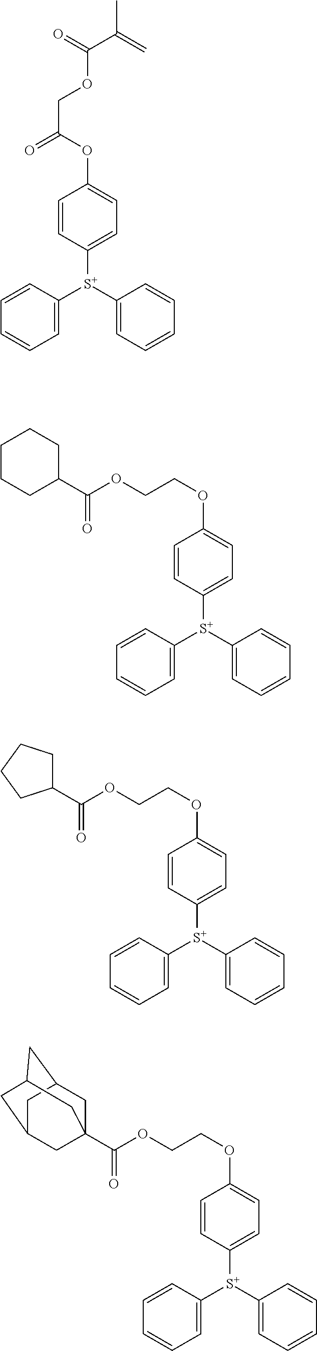 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

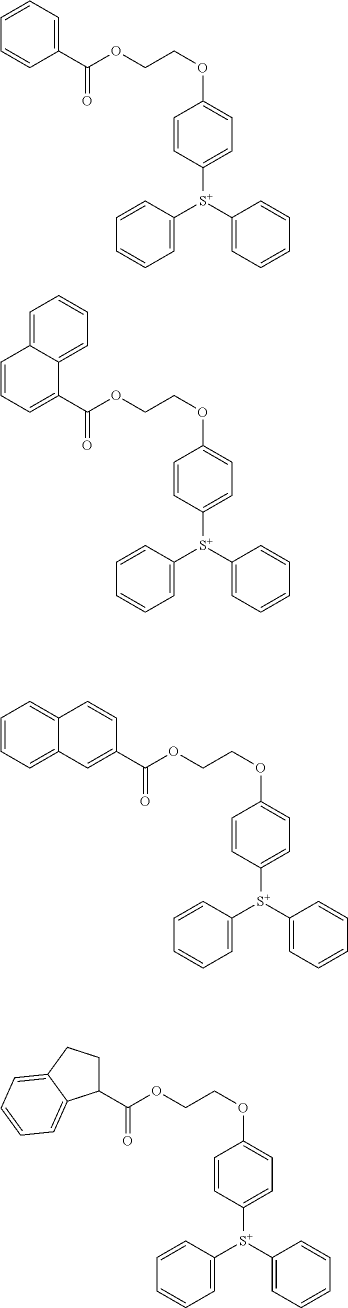 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

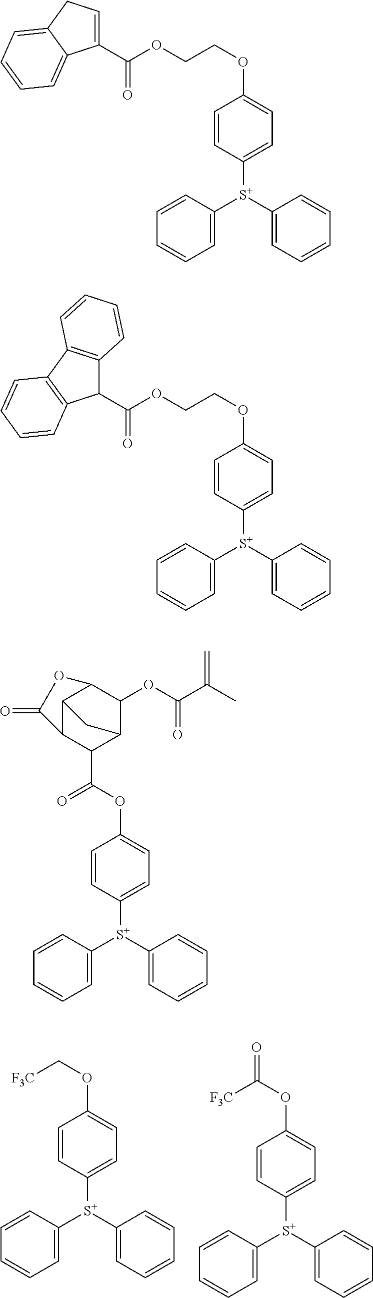 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F]

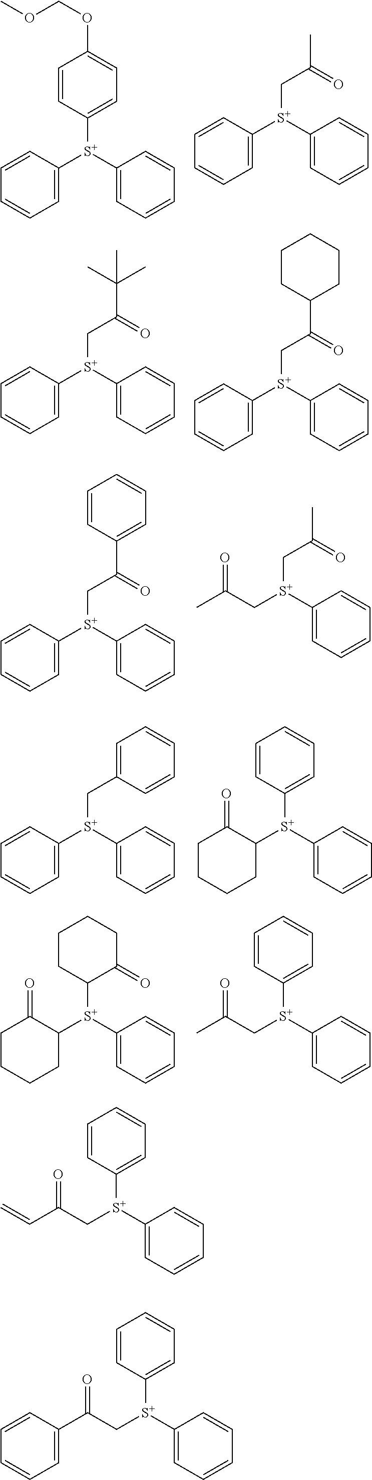

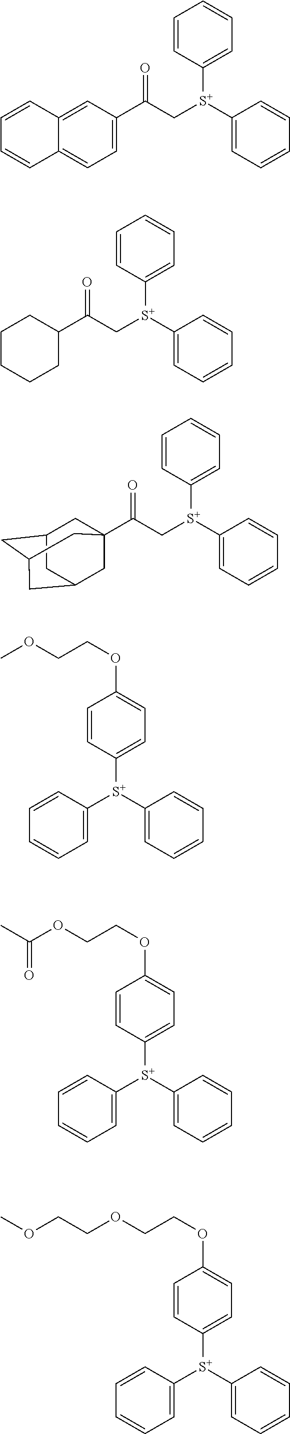 [SMILES: O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1 ; CC(=O)OCCOc1ccc([S+](c2ccccc2)c2ccccc2)cc1 ; COCCOCCOc1ccc([S+](c2ccccc2)c2ccccc2)cc1]

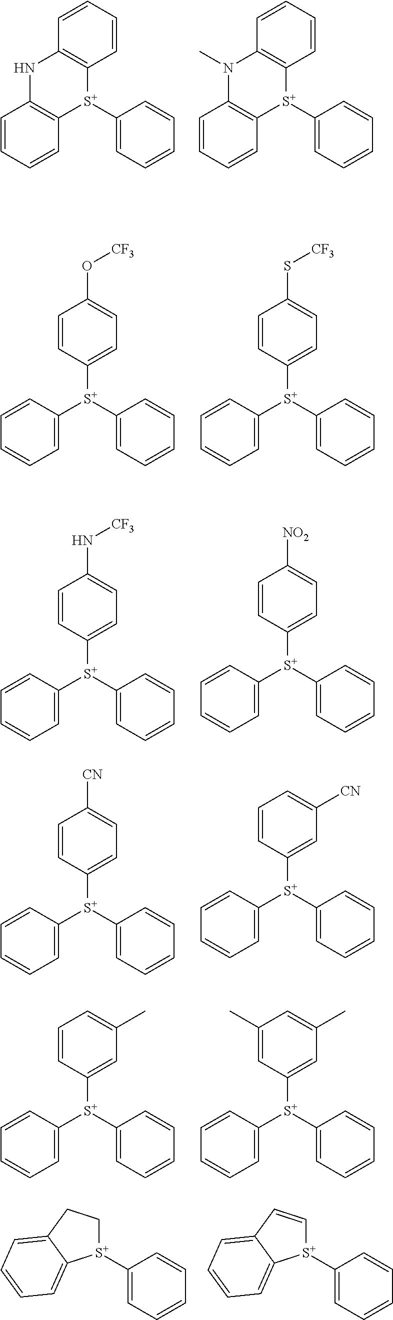

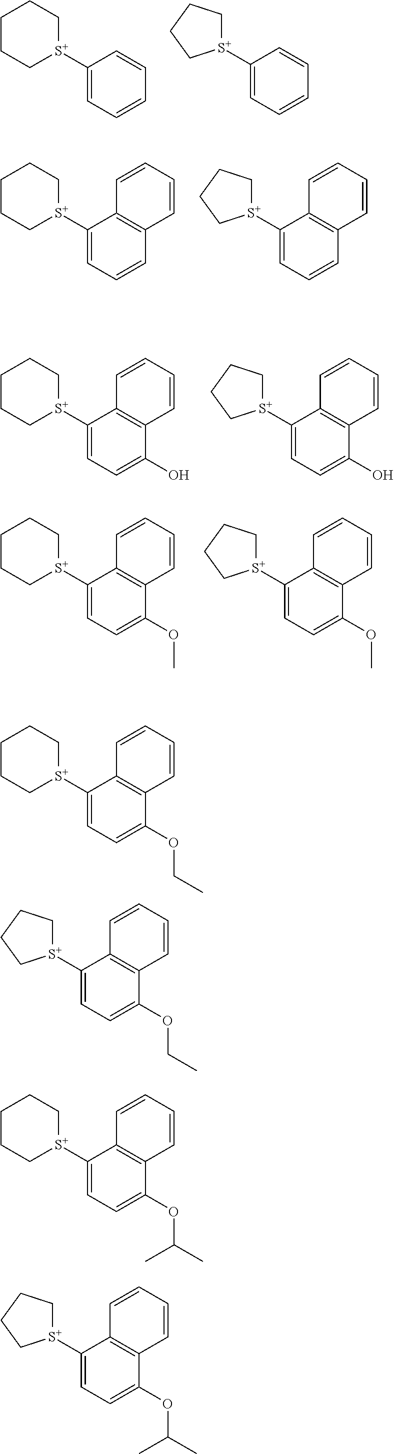

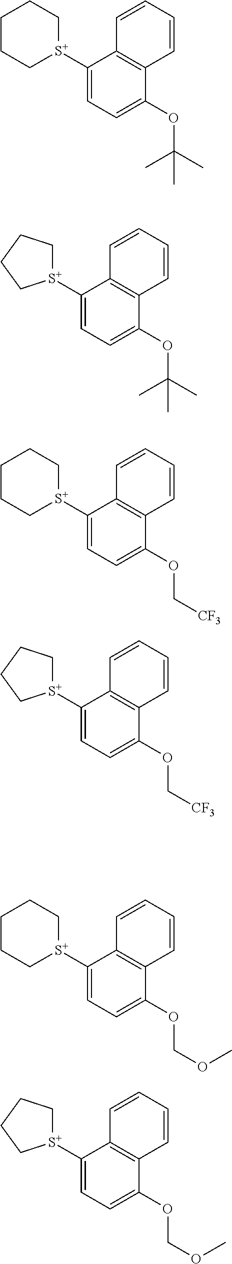 [SMILES: CC(C)(C)Oc1ccc([S+]2CCCCC2)c2ccccc12 ; CC(C)(C)Oc1ccc([S+]2CCCC2)c2ccccc12 ; FC(F)(F)COc1ccc([S+]2CCCCC2)c2ccccc12 ; FC(F)(F)COc1ccc([S+]2CCCC2)c2ccccc12 ; COCOc1ccc([S+]2CCCCC2)c2ccccc12 ; COCOc1ccc([S+]2CCCC2)c2ccccc12]

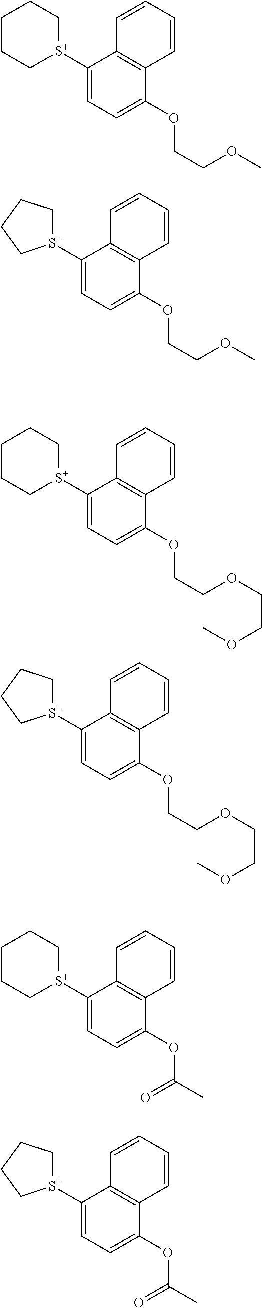 [SMILES: COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12 ; CC(=O)Oc1ccc([S+]2CCCCC2)c2ccccc12 ; CC(=O)Oc1ccc([S+]2CCCC2)c2ccccc12]

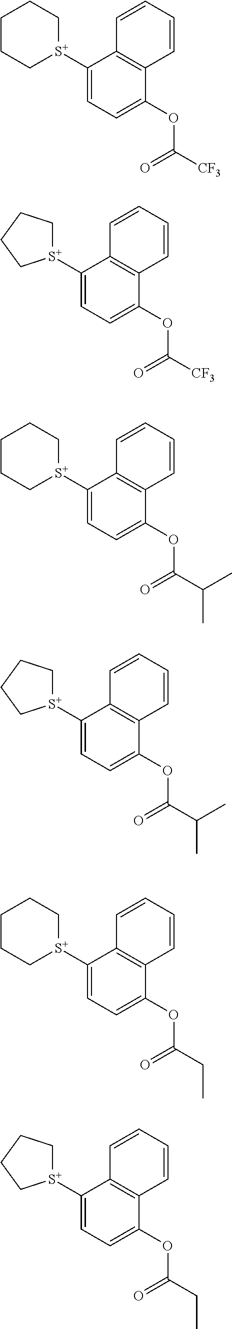 [SMILES: O=C(Oc1ccc([S+]2CCCCC2)c2ccccc12)C(F)(F)F ; O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12]

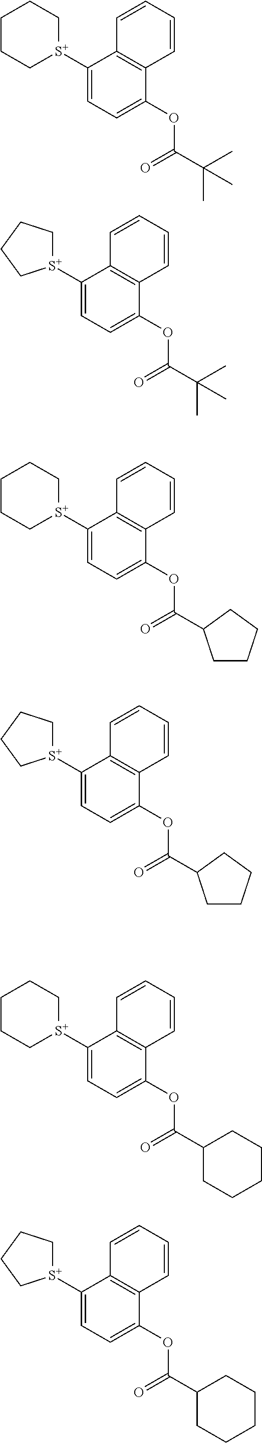 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

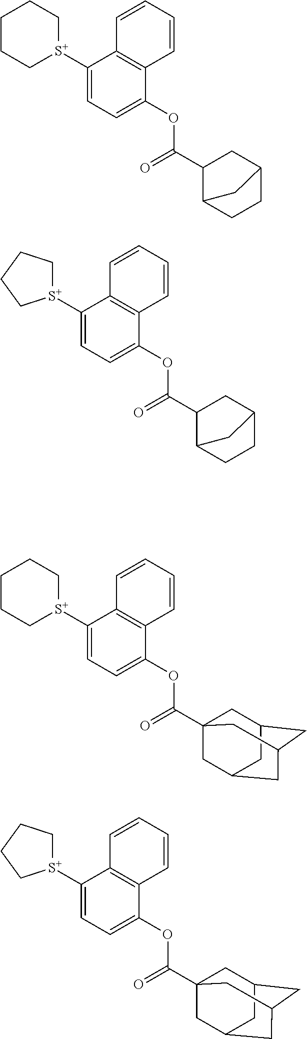 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2]

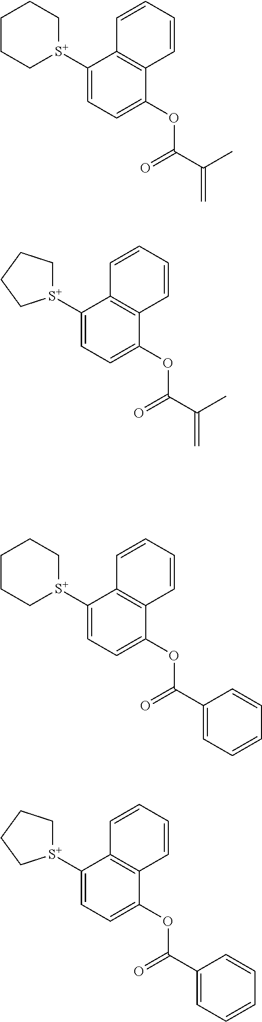 [SMILES: C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1]

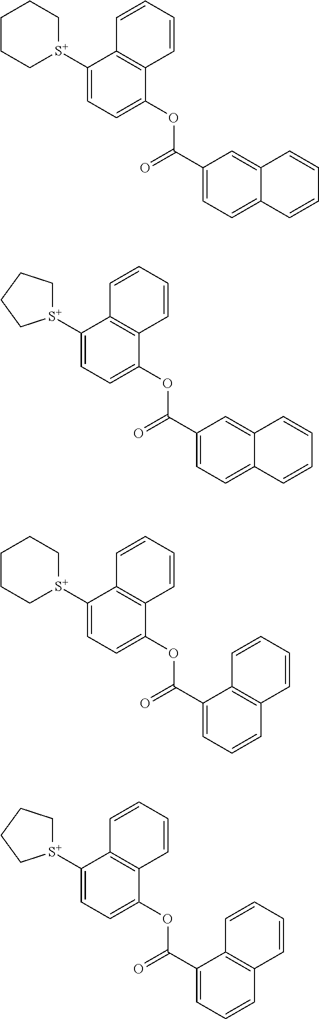 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

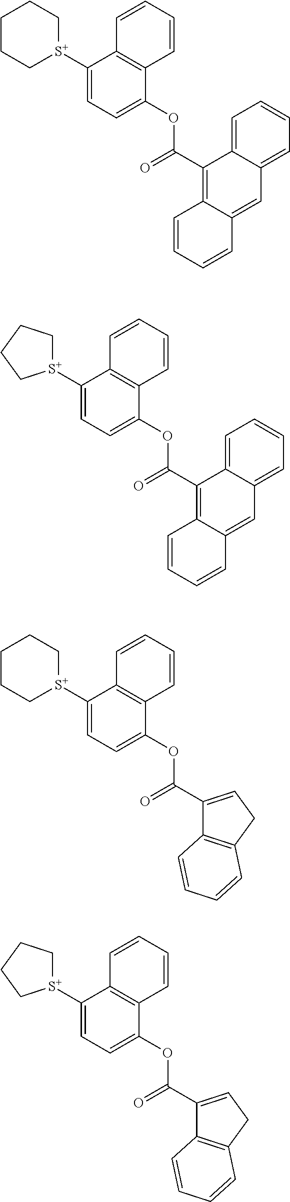 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

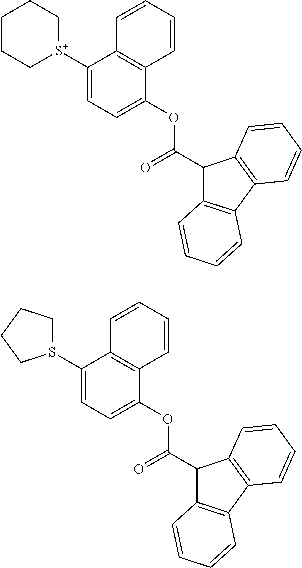 [SMILES: O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

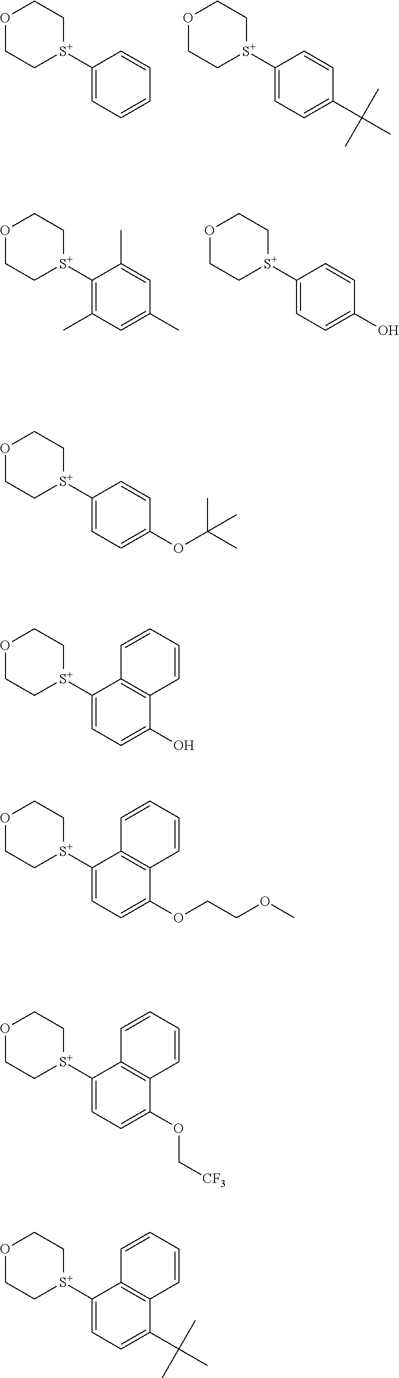

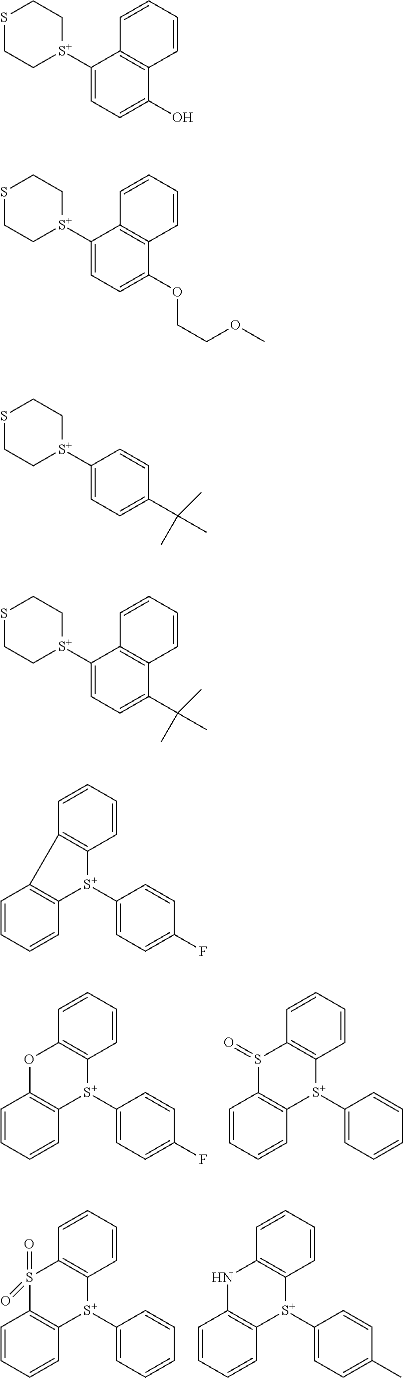

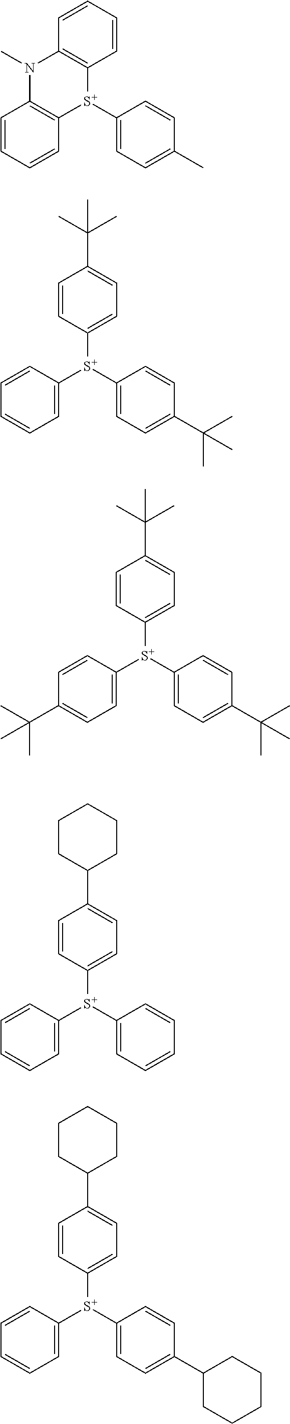

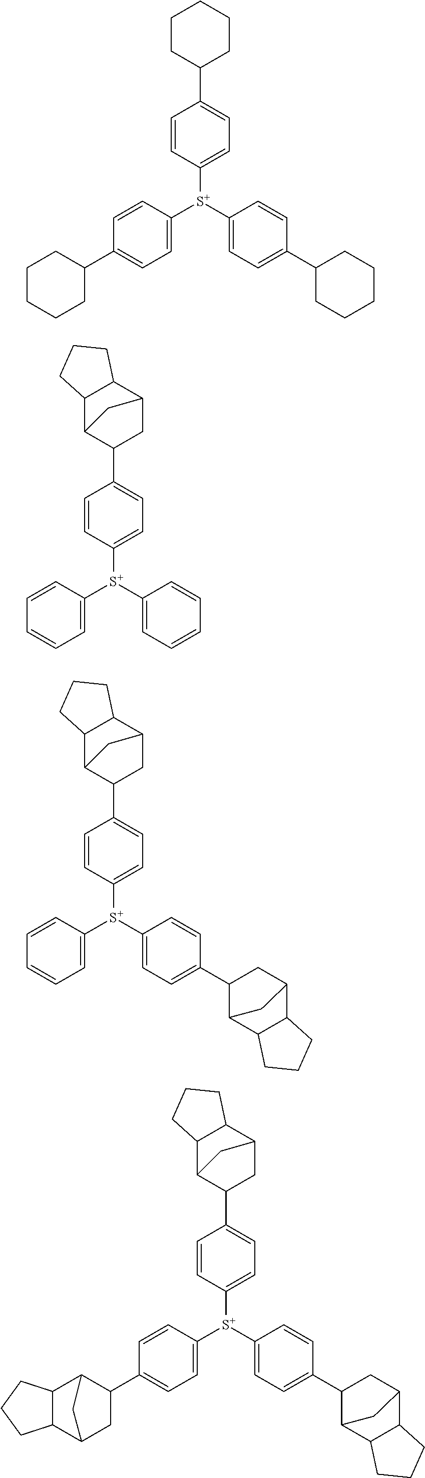 [SMILES: c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21]

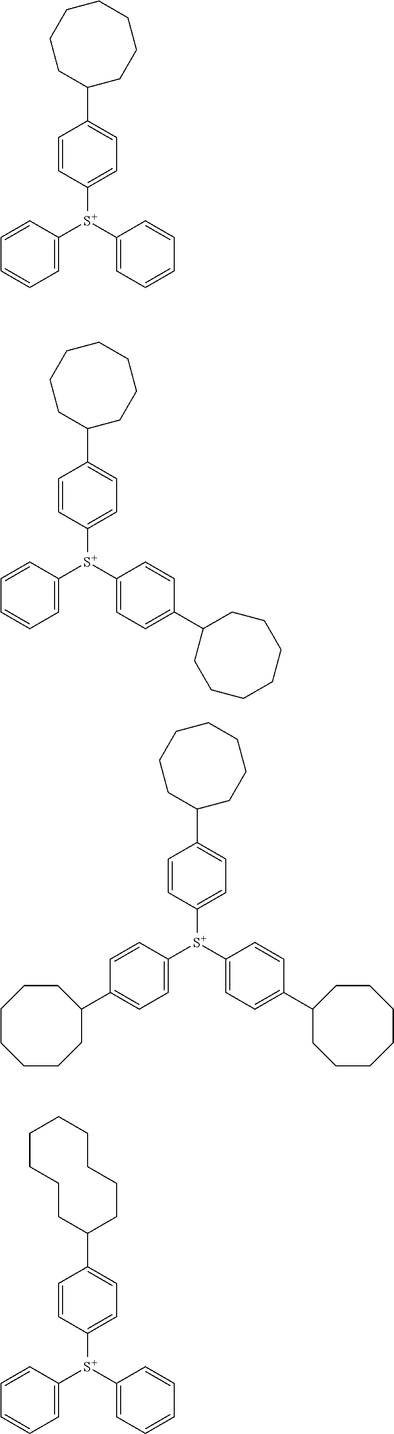 [SMILES: c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1]

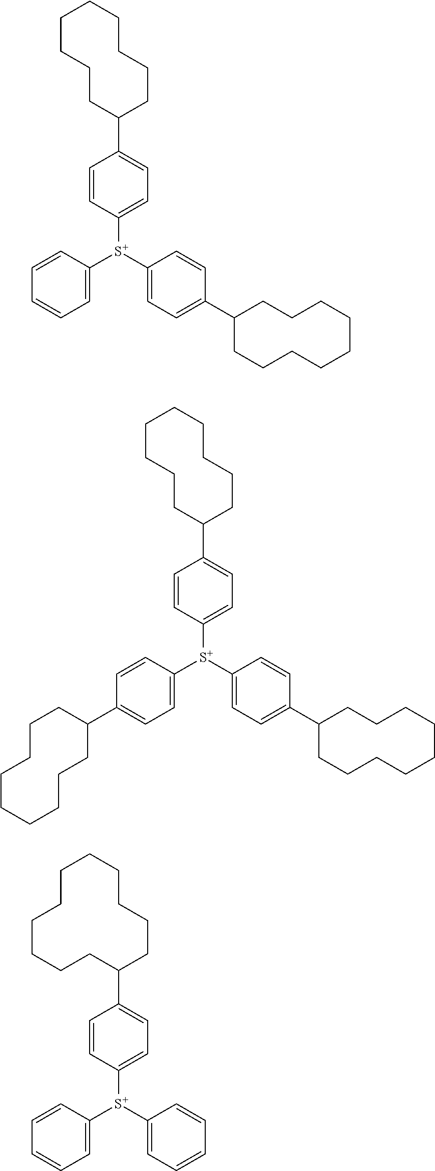 [SMILES: c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1]

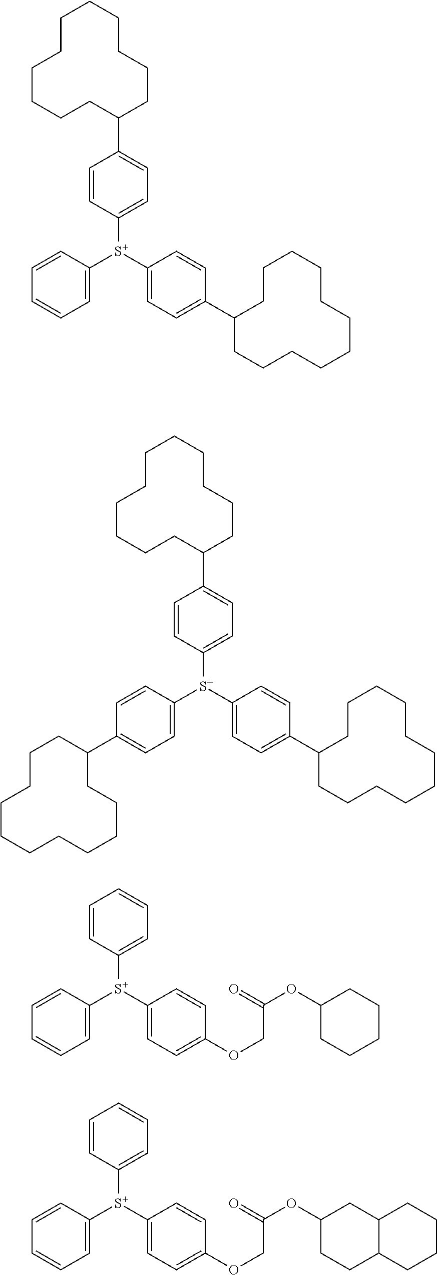 [SMILES: c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1]

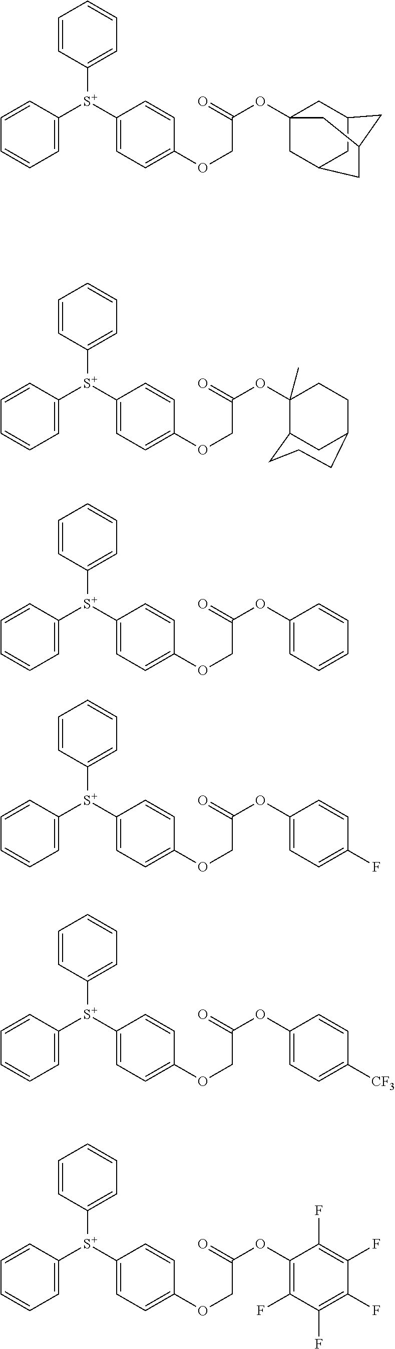 [SMILES: O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)CCC2CCCC1C2 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F]

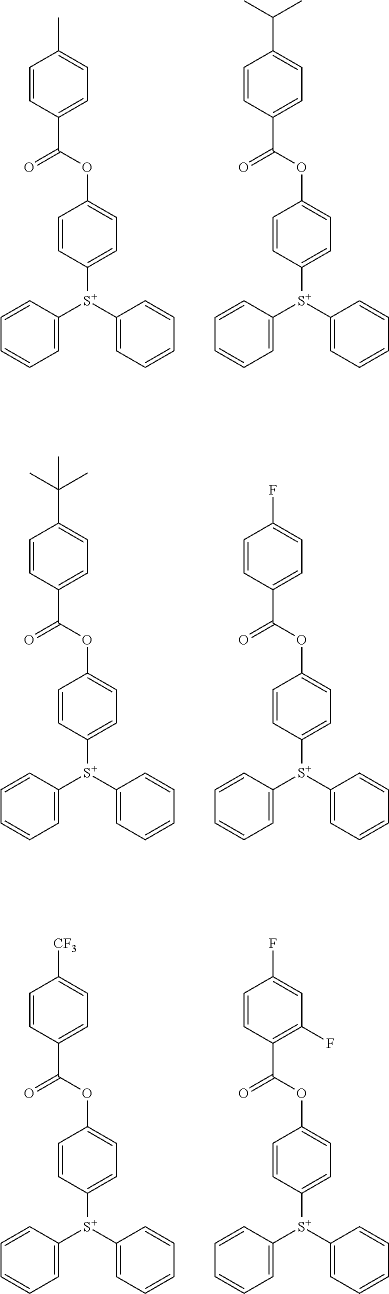 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

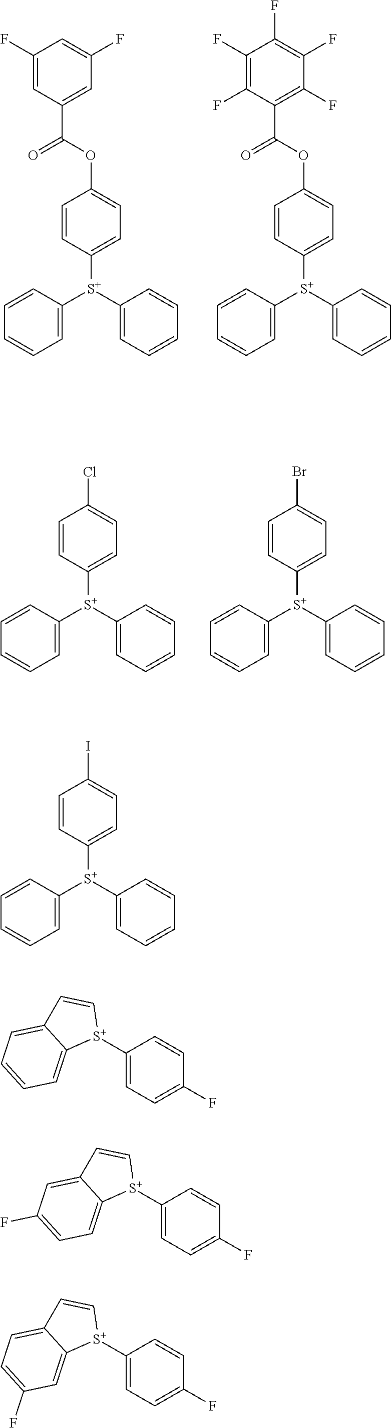

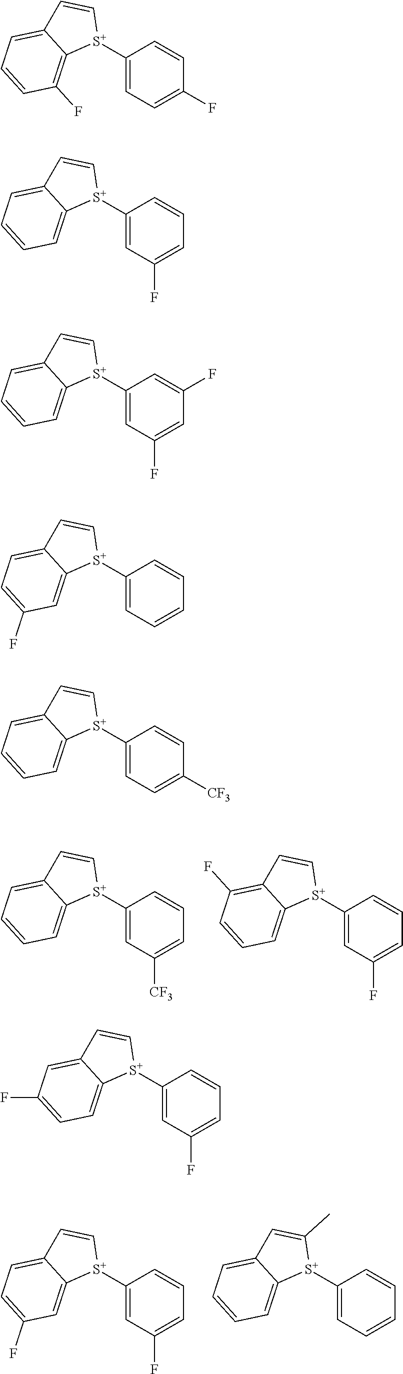

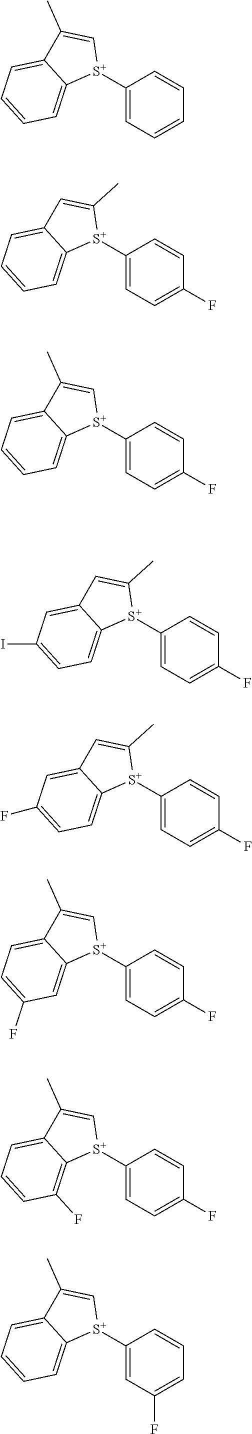

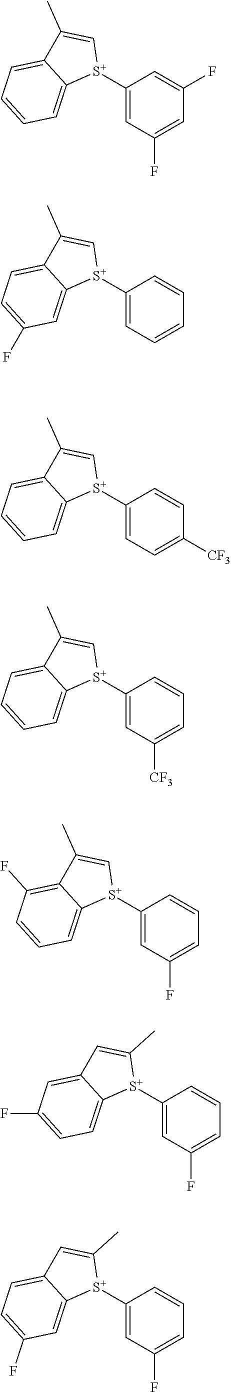

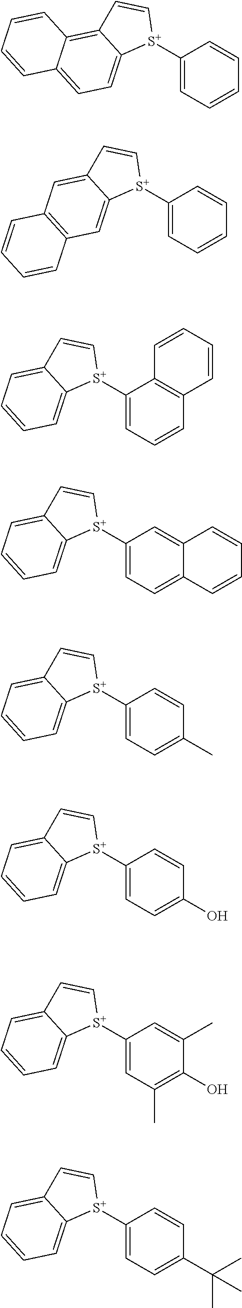

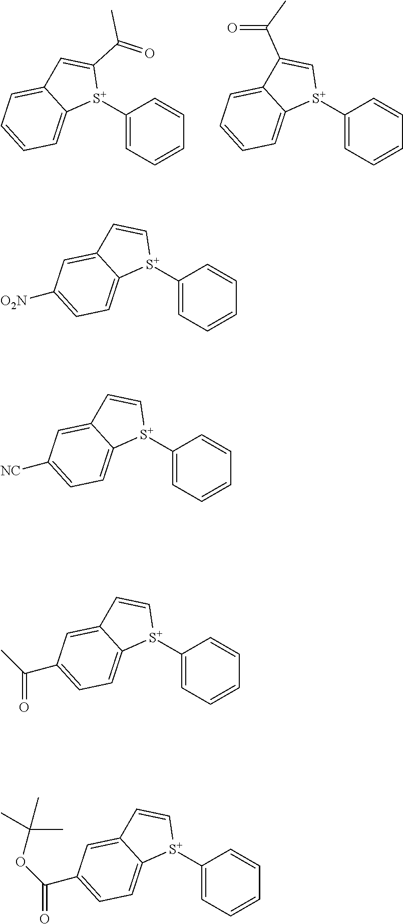 [SMILES: CC(=O)c1cc2ccccc2[s+]1-c1ccccc1 ; CC(=O)c1c[s+](-c2ccccc2)c2ccccc12 ; O=[N+]([O-])c1ccc2c(cc[s+]2-c2ccccc2)c1 ; N#Cc1ccc2c(cc[s+]2-c2ccccc2)c1 ; CC(=O)c1ccc2c(cc[s+]2-c2ccccc2)c1 ; CC(C)(C)OC(=O)c1ccc2c(cc[s+]2-c2ccccc2)c1]

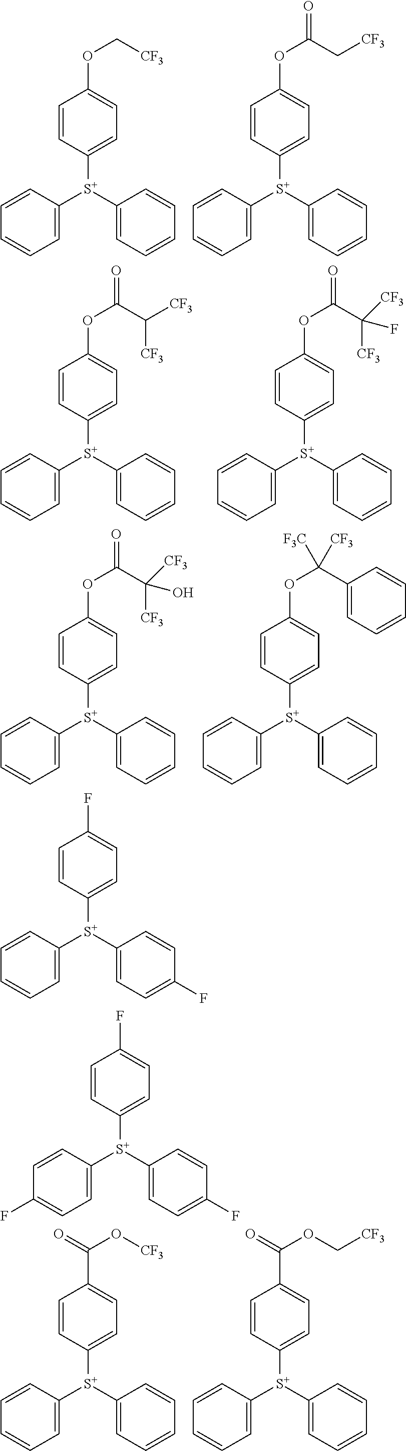

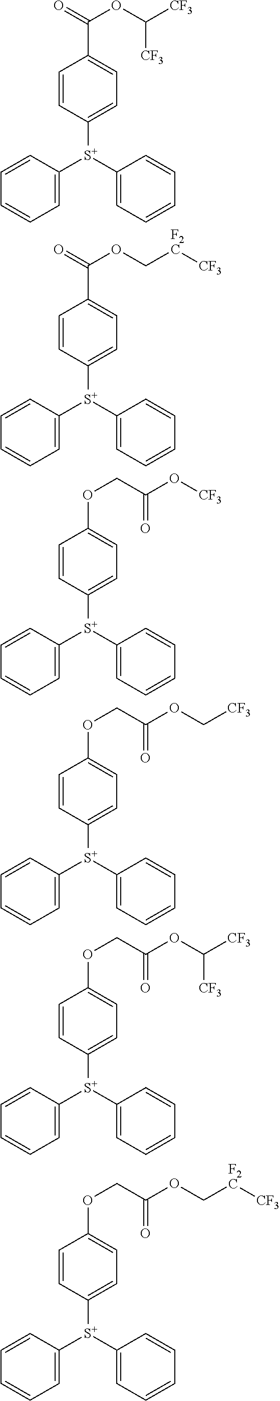 [SMILES: O=C(OC(C(F)(F)F)C(F)(F)F)c1ccc([S+](c2ccccc2)c2ccccc2)cc1 ; O=C(OCC(F)(F)C(F)(F)F)c1ccc([S+](c2ccccc2)c2ccccc2)cc1 ; O=C(COc1ccc([S+](c2ccccc2)c2ccccc2)cc1)OC(F)(F)F ; O=C(COc1ccc([S+](c2ccccc2)c2ccccc2)cc1)OCC(F)(F)F ; O=C(COc1ccc([S+](c2ccccc2)c2ccccc2)cc1)OC(C(F)(F)F)C(F)(F)F ; O=C(COc1ccc([S+](c2ccccc2)c2ccccc2)cc1)OCC(F)(F)C(F)(F)F]

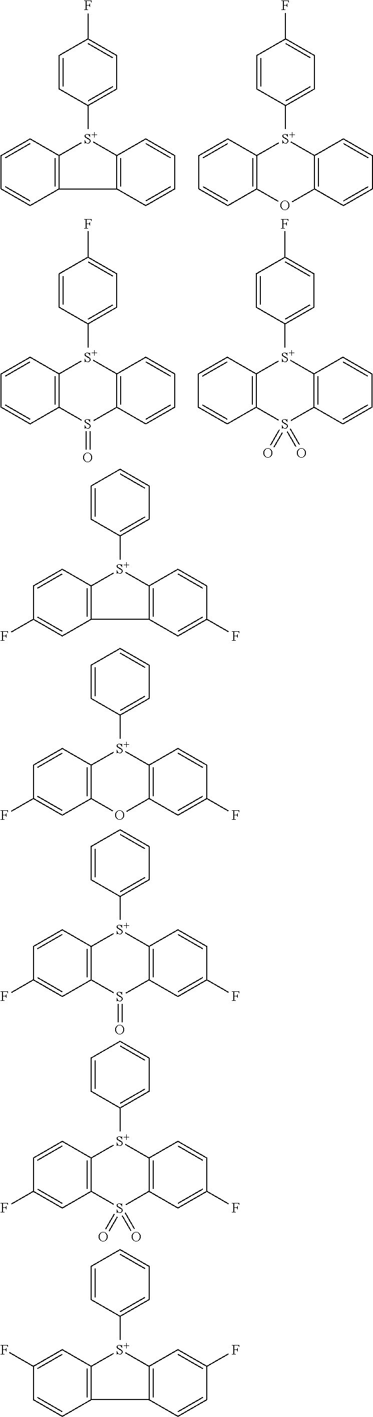

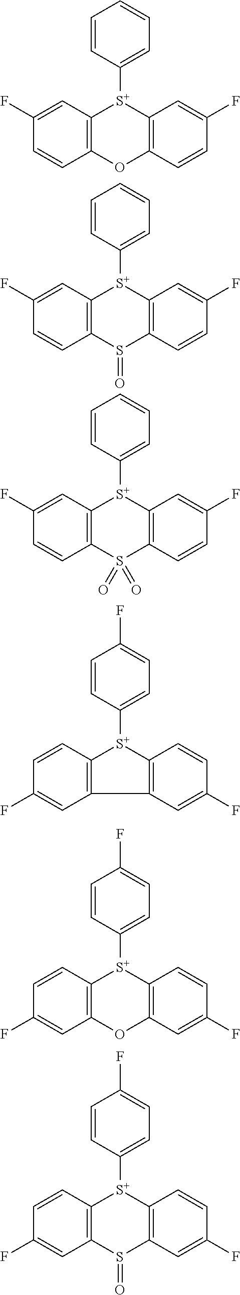 [SMILES: Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21 ; Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21]

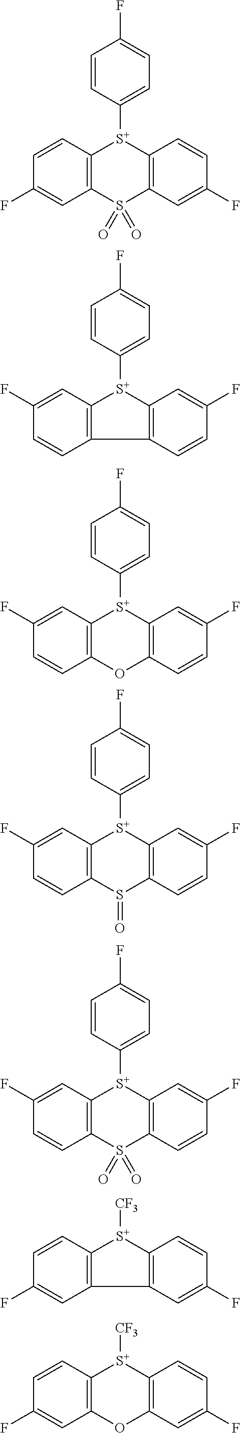

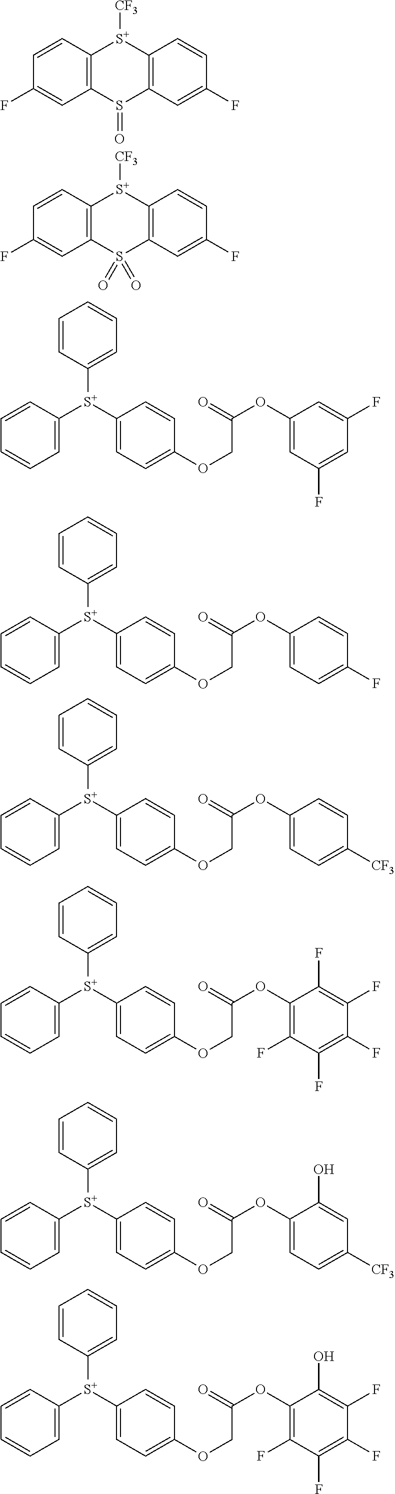

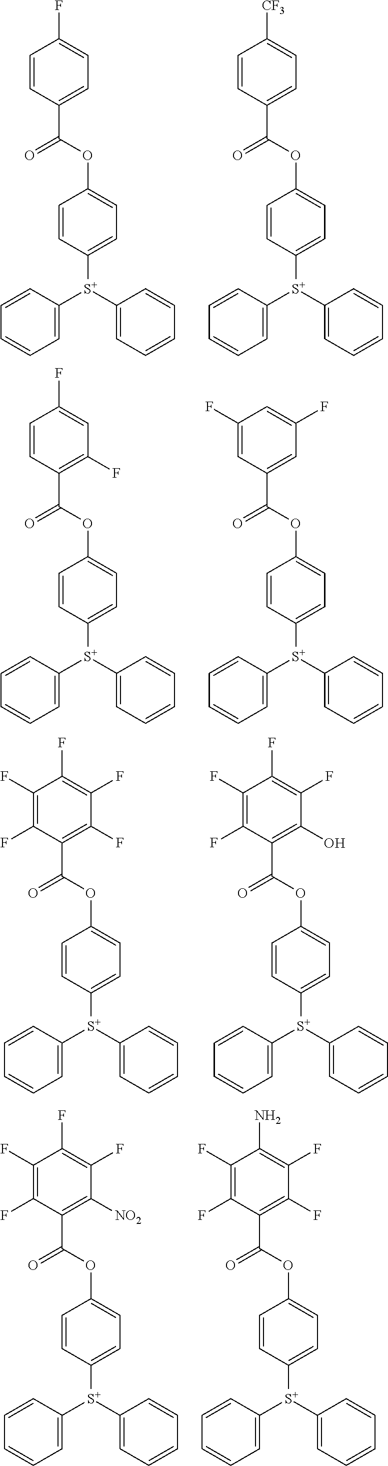

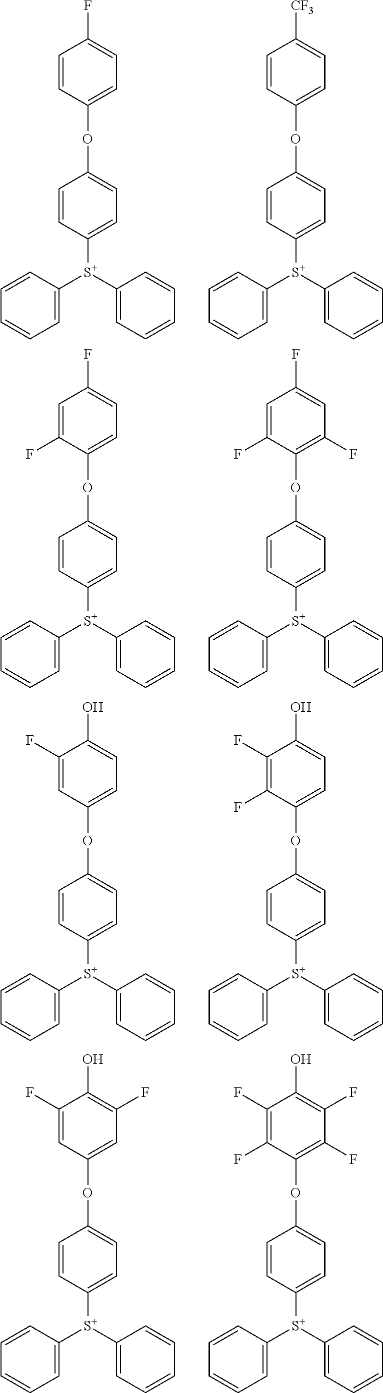

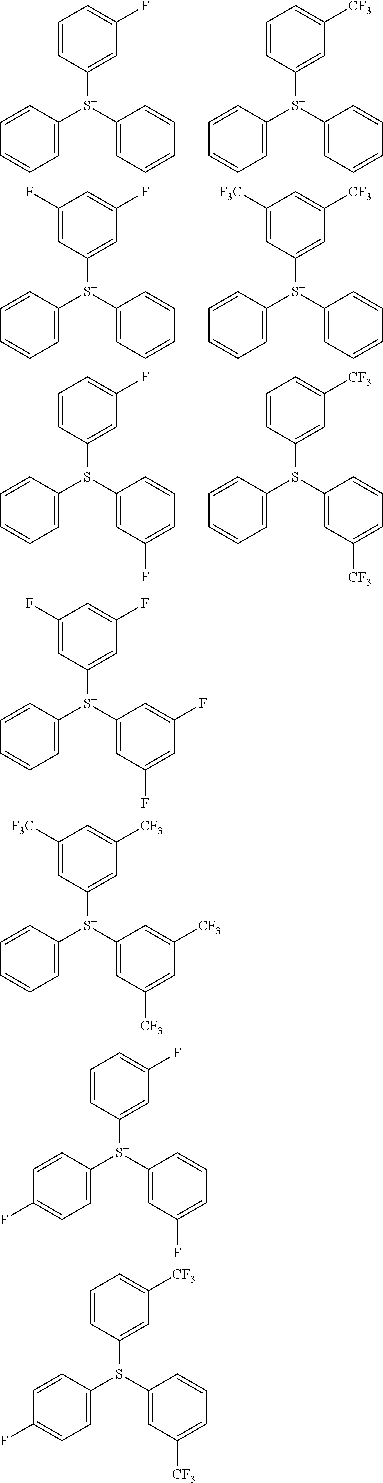

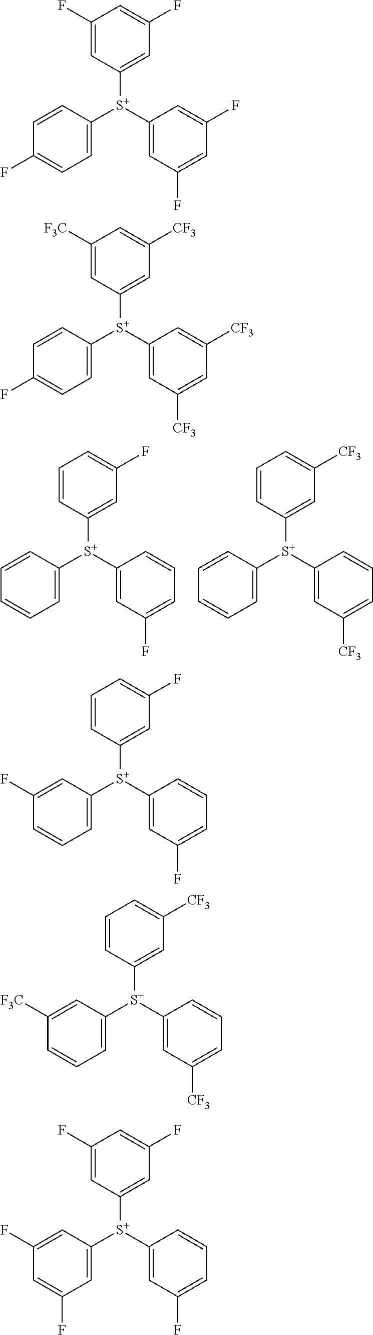

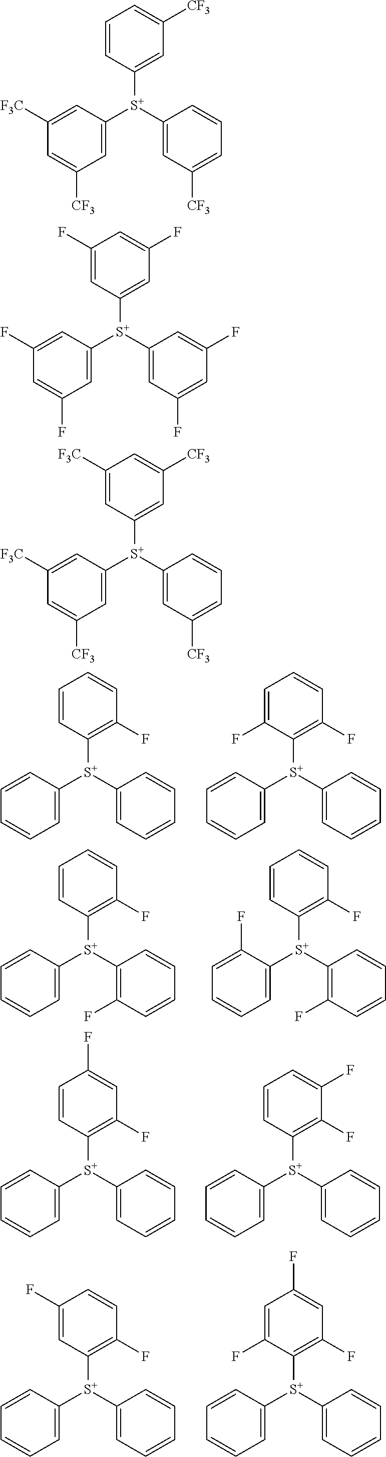

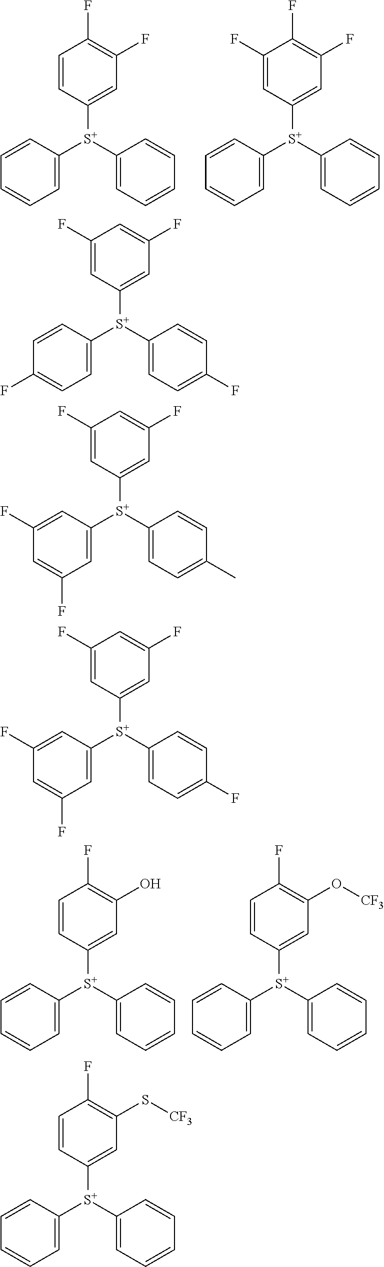

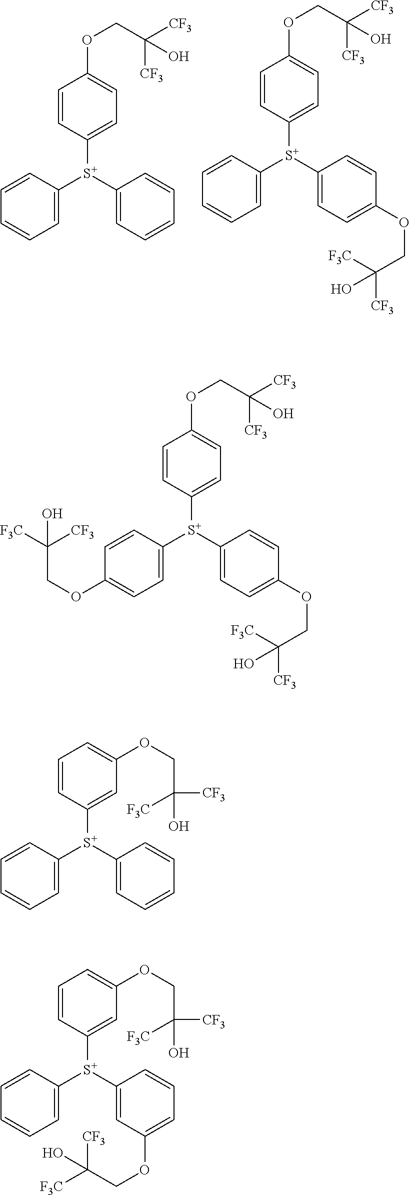 [SMILES: OC(COc1ccc([S+](c2ccccc2)c2ccccc2)cc1)(C(F)(F)F)C(F)(F)F ; OC(COc1ccc([S+](c2ccccc2)c2ccc(OCC(O)(C(F)(F)F)C(F)(F)F)cc2)cc1)(C(F)(F)F)C(F)(F)F ; OC(COc1ccc([S+](c2ccc(OCC(O)(C(F)(F)F)C(F)(F)F)cc2)c2ccc(OCC(O)(C(F)(F)F)C(F)(F)F)cc2)cc1)(C(F)(F)F)C(F)(F)F ; OC(COc1cccc([S+](c2ccccc2)c2ccccc2)c1)(C(F)(F)F)C(F)(F)F ; OC(COc1cccc([S+](c2ccccc2)c2cccc(OCC(O)(C(F)(F)F)C(F)(F)F)c2)c1)(C(F)(F)F)C(F)(F)F]

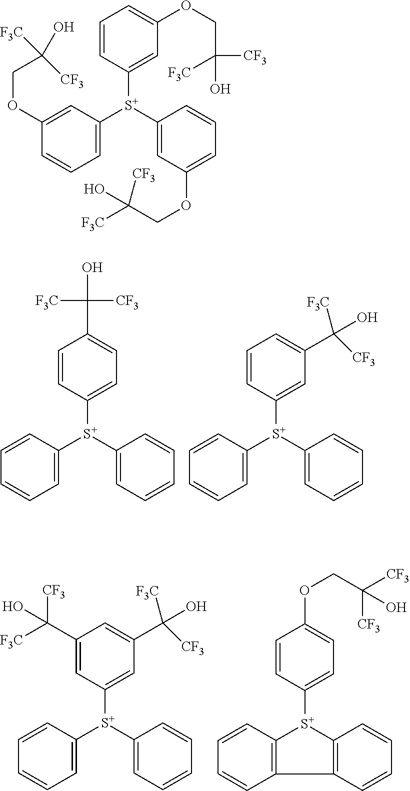 [SMILES: OC(COc1cccc([S+](c2cccc(OCC(O)(C(F)(F)F)C(F)(F)F)c2)c2cccc(OCC(O)(C(F)(F)F)C(F)(F)F)c2)c1)(C(F)(F)F)C(F)(F)F ; OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F ; OC(COc1ccc(-[s+]2c3ccccc3c3ccccc32)cc1)(C(F)(F)F)C(F)(F)F]

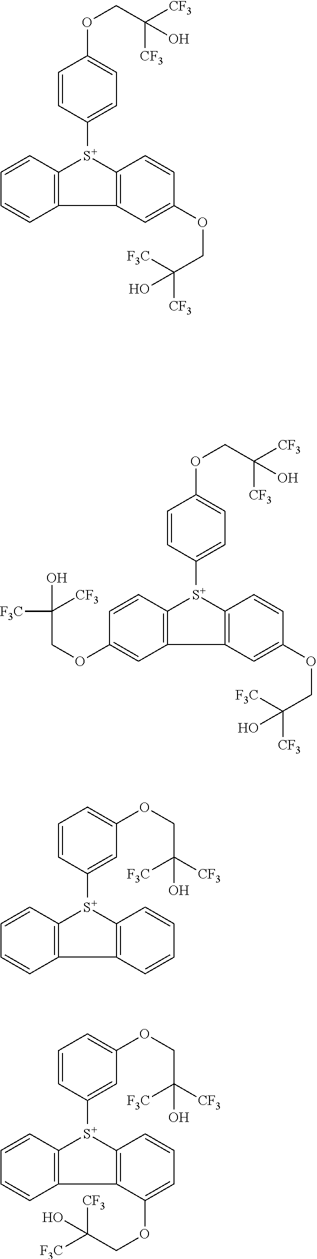 [SMILES: OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F ; OC(COc1cccc(-[s+]2c3ccccc3c3ccccc32)c1)(C(F)(F)F)C(F)(F)F ; OC(COc1cccc(-[s+]2c3ccccc3c3c(OCC(O)(C(F)(F)F)C(F)(F)F)cccc32)c1)(C(F)(F)F)C(F)(F)F]

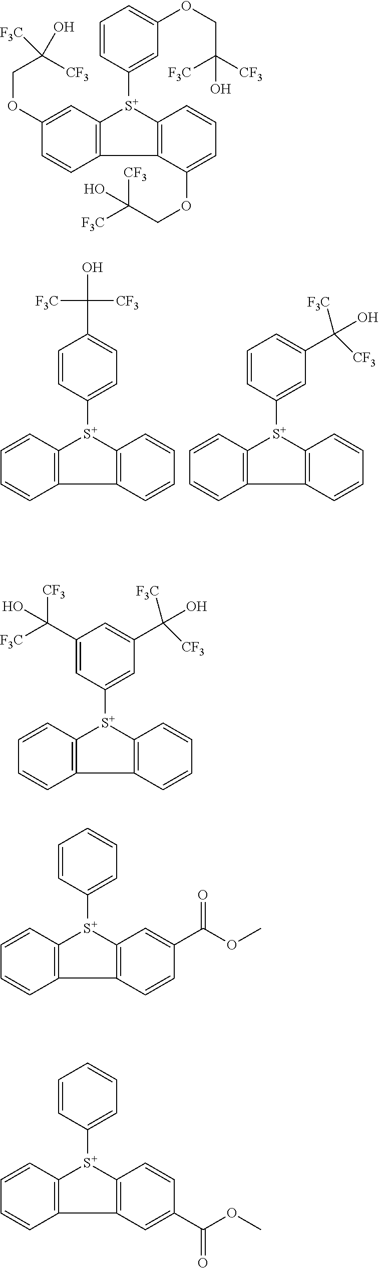 [SMILES: OC(COc1cccc(-[s+]2c3cc(OCC(O)(C(F)(F)F)C(F)(F)F)ccc3c3c(OCC(O)(C(F)(F)F)C(F)(F)F)cccc32)c1)(C(F)(F)F)C(F)(F)F ; OC(c1ccc(-[s+]2c3ccccc3c3ccccc32)cc1)(C(F)(F)F)C(F)(F)F ; OC(c1cccc(-[s+]2c3ccccc3c3ccccc32)c1)(C(F)(F)F)C(F)(F)F ; OC(c1cc(-[s+]2c3ccccc3c3ccccc32)cc(C(O)(C(F)(F)F)C(F)(F)F)c1)(C(F)(F)F)C(F)(F)F ; COC(=O)c1ccc2c3ccccc3[s+](-c3ccccc3)c2c1 ; COC(=O)c1ccc2c(c1)c1ccccc1[s+]2-c1ccccc1]

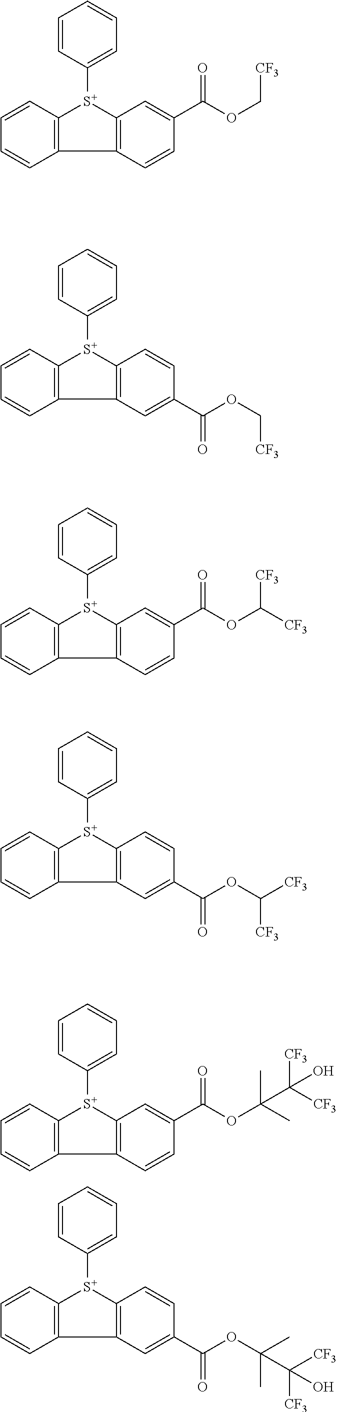 [SMILES: O=C(OCC(F)(F)F)c1ccc2c3ccccc3[s+](-c3ccccc3)c2c1 ; O=C(OCC(F)(F)F)c1ccc2c(c1)c1ccccc1[s+]2-c1ccccc1 ; O=C(OC(C(F)(F)F)C(F)(F)F)c1ccc2c3ccccc3[s+](-c3ccccc3)c2c1 ; O=C(OC(C(F)(F)F)C(F)(F)F)c1ccc2c(c1)c1ccccc1[s+]2-c1ccccc1 ; CC(C)(OC(=O)c1ccc2c3ccccc3[s+](-c3ccccc3)c2c1)C(O)(C(F)(F)F)C(F)(F)F ; CC(C)(OC(=O)c1ccc2c(c1)c1ccccc1[s+]2-c1ccccc1)C(O)(C(F)(F)F)C(F)(F)F]

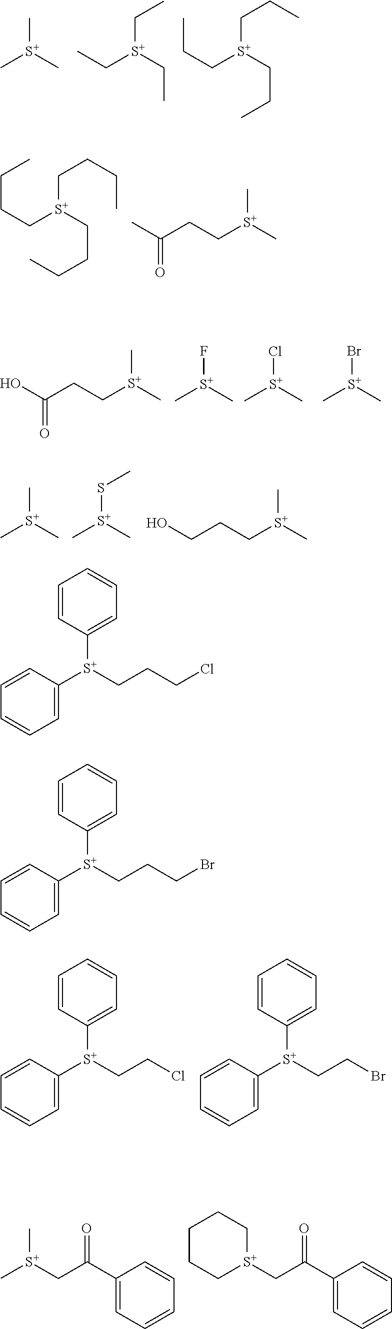

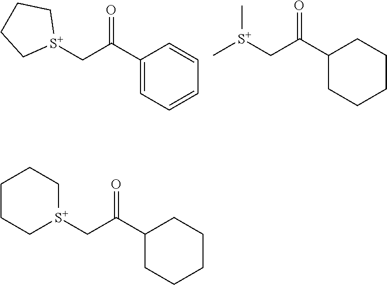

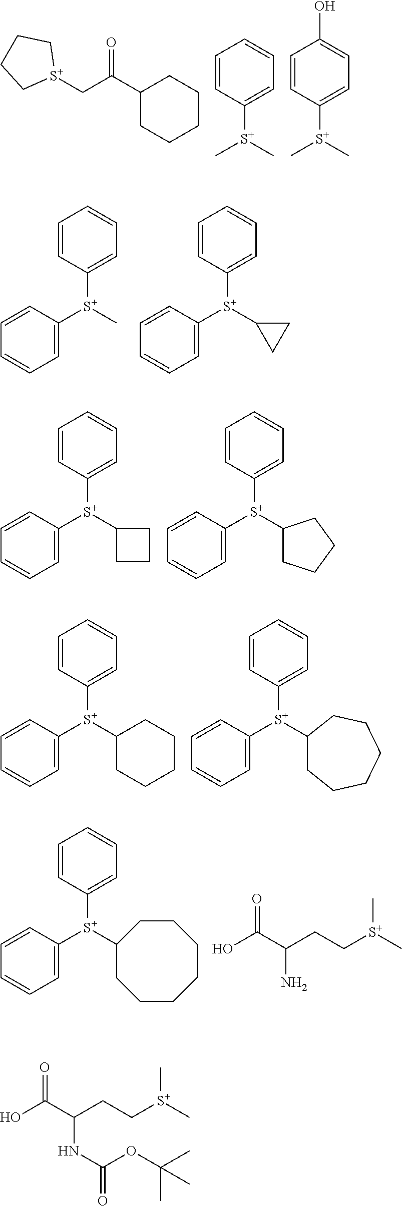

Examples of the iodonium cation represented by formula (Xa-2) are shown below, but not limited thereto.

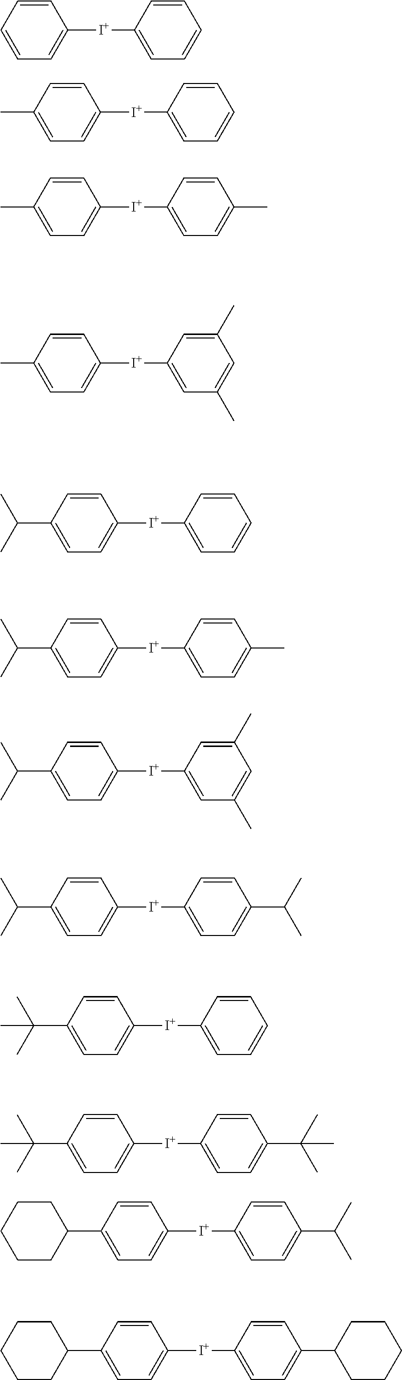

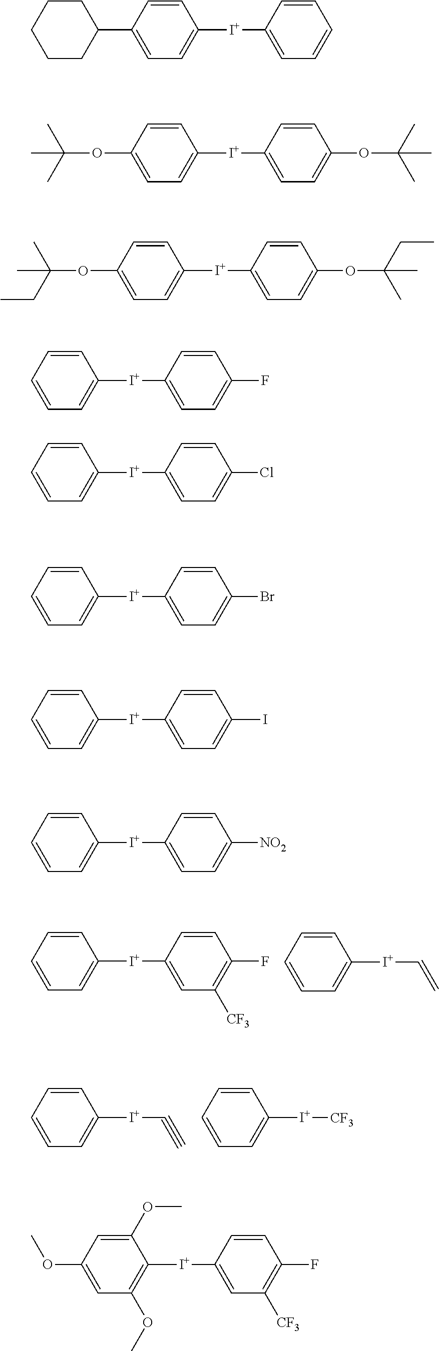

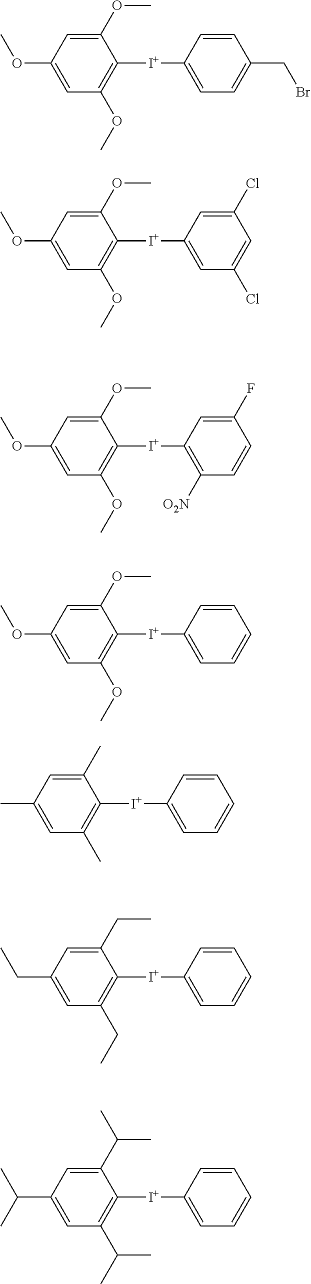

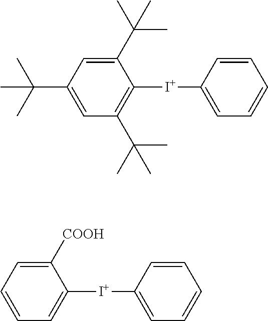 [SMILES: CC(C)(C)c1cc(C(C)(C)C)c([I+]c2ccccc2)c(C(C)(C)C)c1 ; O=C(O)c1ccccc1[I+]c1ccccc1]

Examples of the photoacid generator represented by formula (PAG-a) include arbitrary combinations of anions with cations, both as exemplified above.

In formula (PAG-b), hydrocarbyl groups R¹ and R² may be saturated or unsaturated and straight, branched or cyclic. Examples thereof include C₁-C₂₀ alkyls such as methyl, ethyl, propyl, isopropyl, n-butyl, isobutyl, sec-butyl, tert-butyl, n-pentyl, tert-pentyl, n-hexyl, n-octyl and 2-ethylhexyl; C₃-C₂₀ cyclic saturated hydrocarbyl groups such as cyclopentyl, cyclohexyl, cyclopentylmethyl, cyclopentylethyl, cyclohexyhnethyl, cyclohexylethyl, norbornyl, oxanorbornyl, tricyclo[5.2.1.0^{2,6}] decyl and adamantyl; C₆-C₂₀ aryl groups such as phenyl and naphthyl; and combinations thereof. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a cyano group, a fluorine atom, a chlorine atom, a bromine atom, an iodine atom, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like. Of these, aryl groups in which hydrogen may be substituted are preferred as R¹ and R².

The hydrocarbylene group R³ may be saturated or unsaturated and straight, branched or cyclic. Examples thereof include C₁-C₂₀ alkanediyl groups such as methanediyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1, 12-diyl, tridecane-1,13-diyl, tetradecane-1,14-diyl, pentadecane-1,15-diyl, hexadecane-1,16-diyl and heptadecane-1,17-diyl groups; C₃-C₂₀ cyclic saturated hydrocarbylene groups such as cyclopentanediyl, cyclohexanediyl, norbornanediyl and adamantanediyl groups; and C₆-C₂₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene and tert-butyhnaphthylene groups; and combinations thereof. Some or all of hydrogen atoms of the hydrocarbylene group may be replaced by a group containing a heteroatom such as an oxygen atom, a sulfur atom, a nitrogen atom or a halogen atom, some constituent —CH₂— of the hydrocarbylene group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like. Of these, aryl groups in which hydrogen may be substituted are preferred as R³.

Examples of the divalent linking group L^{A} in formula (PAG-b) include an ether bond, an ester bond, a thioether bond, a sulfinic ester bond, a sulfonic ester bond, a carbonate bond, and a carbamate bond.

Hydrocarbylene groups L^{B} in formula (PAG-b) may be saturated or unsaturated and straight, branched or cyclic. Examples thereof are as exemplified above as a hydrocarbylene group R³. Some or all of hydrogen atoms of the hydrocarbylene group may be replaced by a group containing a heteroatom such as an oxygen atom, a sulfur atom, a nitrogen atom or a halogen atom, some constituent —CH₂— of the hydrocarbylene group may be replaced by a group containing a heteroatom such as an oxygen atom, a sulfur atom or a nitrogen atom, and as a result, the hydrocarbyl group may contain a hydroxy group, a fluorine atom, a chlorine atom, a bromine atom, an iodine atom, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like. Of these, a methanediyl group, or a methanediyl group in which hydrogen is substituted by fluorine or a trifluoromethyl group is preferred as L^{B}.

Examples of the photoacid generator having formula (PAG-b) are shown below, but not limited thereto. Herein, R^{HF} is a hydrogen atom, a fluorine atom, or a trifluoromethyl group.

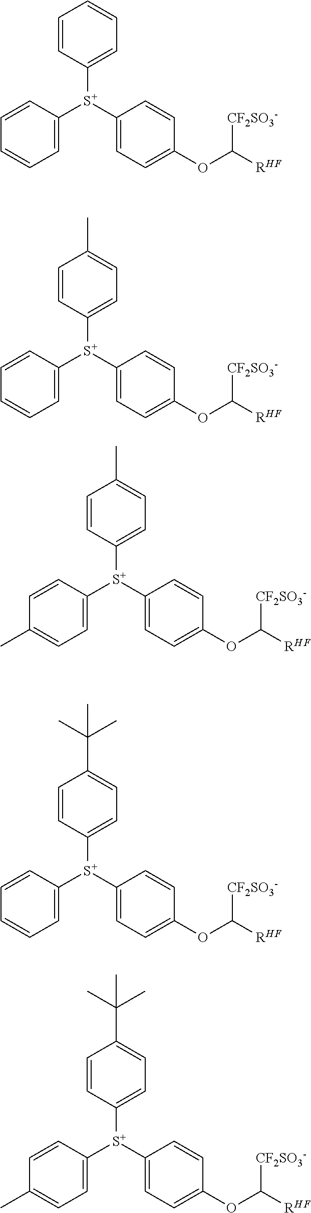

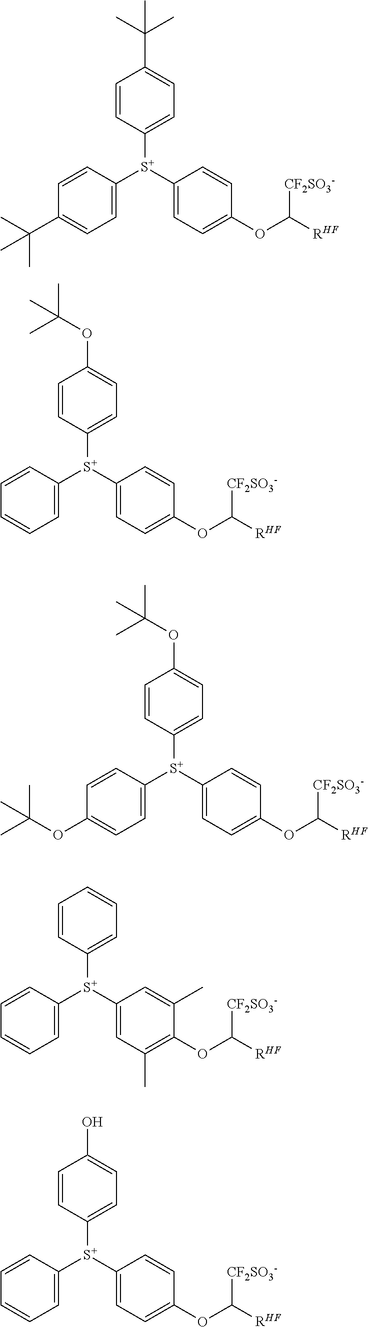

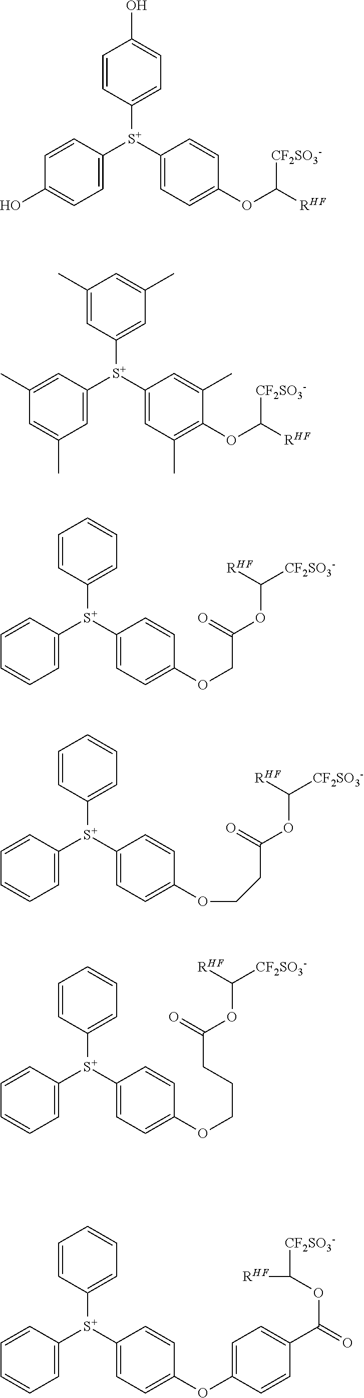

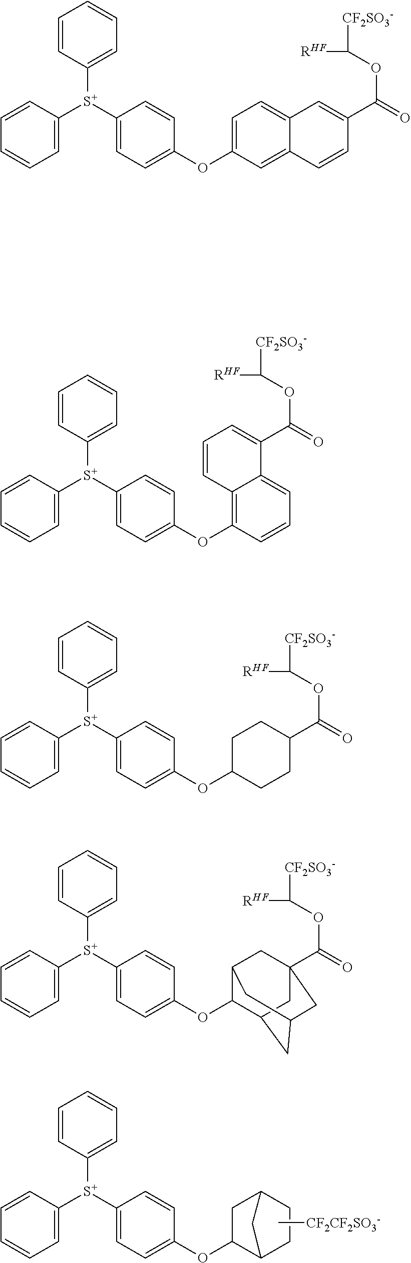

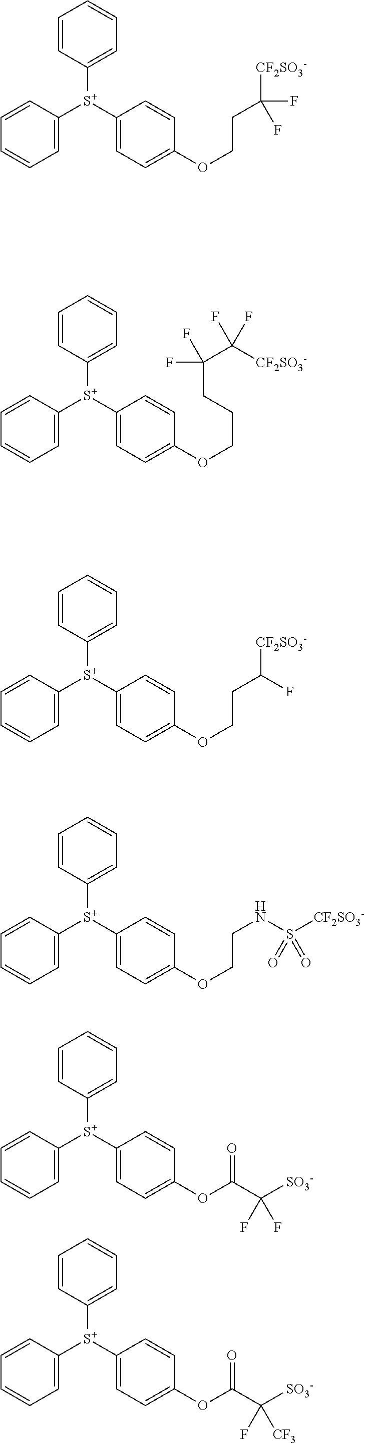

The content of the photoacid generator (B) in the inventive chemically amplified resist composition is preferably 1 to 50 parts by weight, more preferably 5 to 40 parts by weight per 80 parts by weight of the polymer (A). A content of the photoacid generator (B) in the range ensures good resolution and eliminates the risk of leaving foreign matter after development or during separation of resist film. The photoacid generator (B) may be used alone or in admixture.

(C) Organic Solvent

The organic solvent as component (C) is not particularly limited as long as components described above and components described later are soluble therein. Examples of the organic solvent include ketones such as cyclopentanone, cyclohexanone and methyl-2-n-pentyl ketone; alcohols such as 3-methoxybutanol, 3-methyl-3-methoxybutanol, 1-methoxy-2-propanol, 1-ethoxy-2-propanol; keto-alcohols such as DAA, ethers such as PGME, ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as GBL, which may be used alone or in admixture. When a polymer containing an acid labile group of acetal form is used, a high-boiling alcohol solvent may be added for accelerating the deprotection reaction of acetal, for example, diethylene glycol, propylene glycol, glycerol, 1,4-butanediol or 1,3-butanediol.

Of the foregoing organic solvents, 1-ethoxy-2-propanol, PGMEA, cyclohexanone, GBL, DAA and mixtures thereof are preferred because the polymer as component (A) is most soluble therein.

The organic solvent is preferably used in an amount of 200 to 5,000 parts by weight, more preferably 400 to 3,500 parts by weight per 80 parts by weight of the polymer (A). The organic solvent (C) may be used alone or in admixture.

(D) Quencher

The inventive chemically amplified resist composition may further comprise a quencher (acid diffusion controlling agent). In the invention, the quencher refers to a compound capable of trapping the acid, which is generated by the photoacid generator in the chemically amplified resist composition upon light exposure, to prevent the acid from diffusing to the unexposed region and to assist in forming the desired pattern.

Onium salts having the formulae (Q-a) and (Q-b) are useful as the quencher (D).

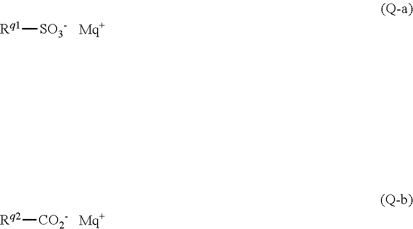

In formula (Q-a), R^{q3} is hydrogen or a C₁-C₄₀ hydrocarbyl group which may contain a heteroatom, exclusive of the hydrocarbyl group in which the hydrogen atom bonded to the carbon atom at α-position of the sulfo group is substituted by fluorine or fluoroalkyl. In formula (Q-b), R^{q2} is a hydrogen atom, or a C₁-C₄₀ hydrocarbyl group which may contain a heteroatom.

The hydrocarbyl group R^{q1} may be saturated or unsaturated and straight, branched or cyclic. Examples thereof include C₁-C₄₀ alkyls such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl and n-decyl groups; C₃-C₄ cyclic saturated hydrocarbyl groups such as cyclopentyl, cyclohexyl, cyclopentylmethyl, cyclopentylethyl, cyclopentylbutyl, cyclohexyhnethyl, cyclohexylethyl, cyclohexylbutyl, norbornyl, tricyclo[5.2.1.0^{2.6}] decyl and adamantyl groups; C₆-C₄₀ aryl groups such as phenyl, naphthyl and anthracenyl groups; C₂₀-C₃₈ hydrocarbyl groups having a steroid backbone, which may contain a heteroatom; and combinations thereof. Some or all of hydrogen atoms of the hydrocarbyl group may be replaced by a group containing a heteroatom such as an oxygen atom, a sulfur atom, a nitrogen atom or a halogen atom, some constituent —CH₂— of the hydrocarbyl group may be replaced by a group containing a heteroatom such as an oxygen atom, a sulfur atom or a nitrogen atom, and as a result, the hydrocarbyl group may contain a hydroxy group, a cyano group, a carbonyl group, an ether bond, an ester bond, a sulfonic ester bond, a carbonate bond, a lactone ring, a sultone ring, carboxylic anhydride (—C(═O)—O—C(═O)—), a haloalkyl group, or the like.

The hydrocarbyl group R^{q2} may be saturated or unsaturated and straight, branched or cyclic. Examples thereof include substituents exemplified above for R^{q1}, fluorinated saturated hydrocarbyl groups such as trifluoromethyl and trifluoroethyl groups, and fluorinated aryl groups such as pentafluorophenyl and 4-trifluoromethylphenyl groups.

Examples of the anion in the onium salt having formula (Q-a) are shown below, but not limited thereto.

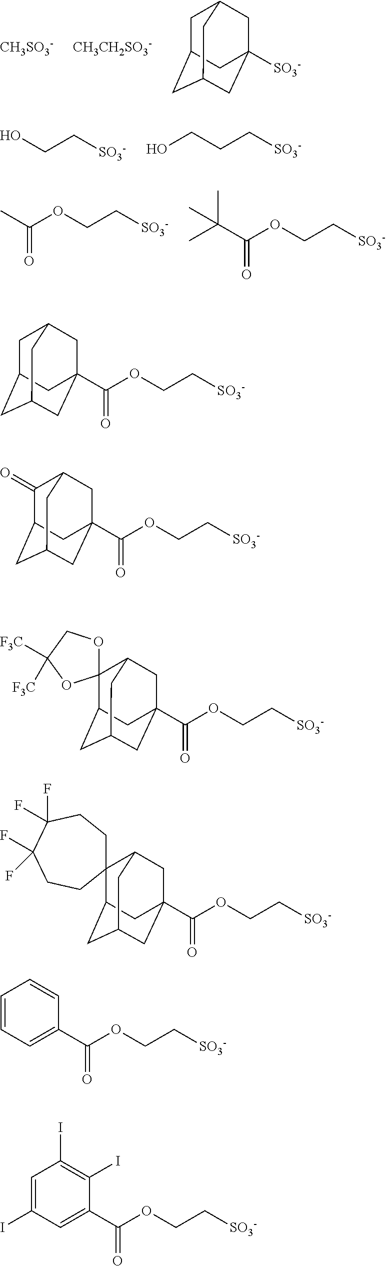

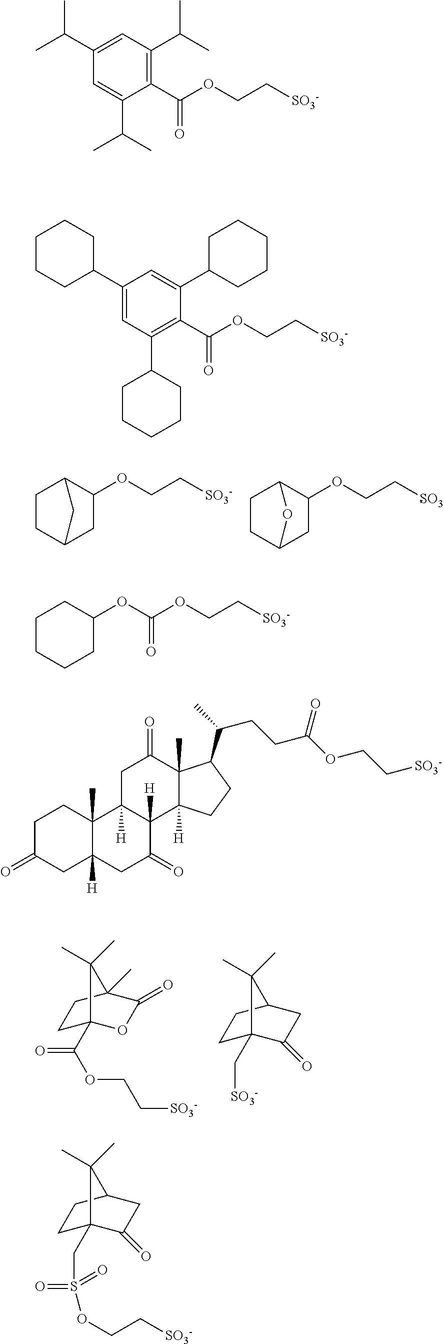

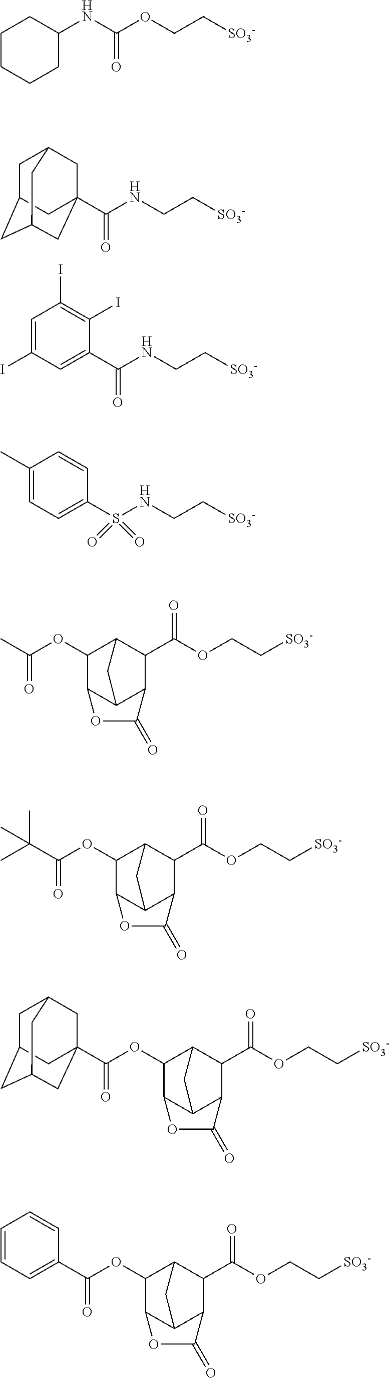

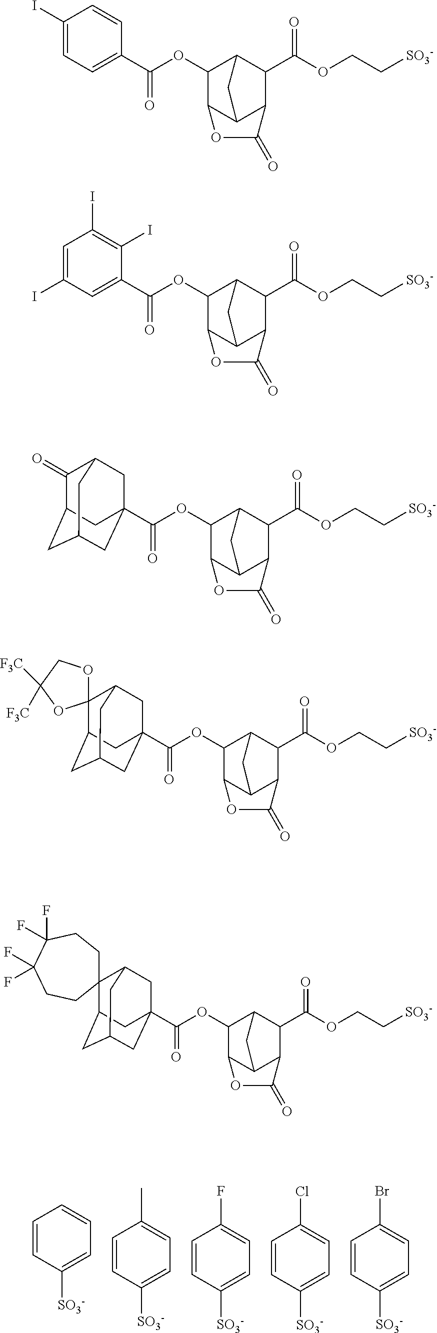

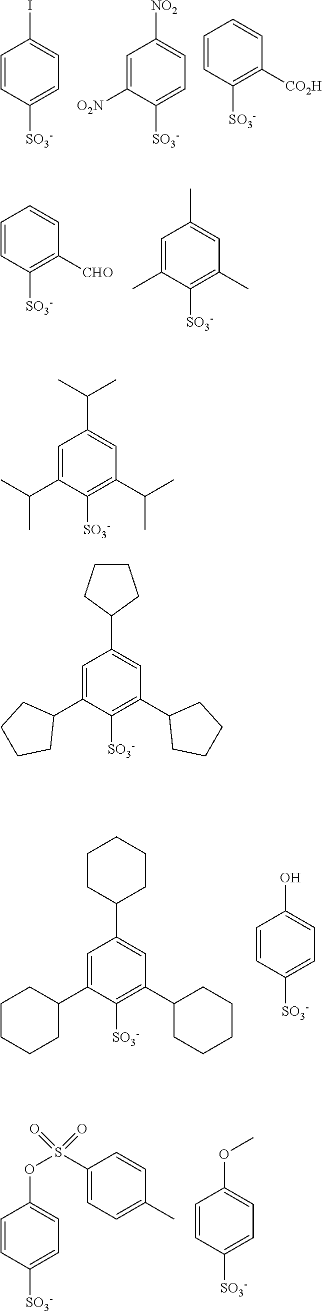

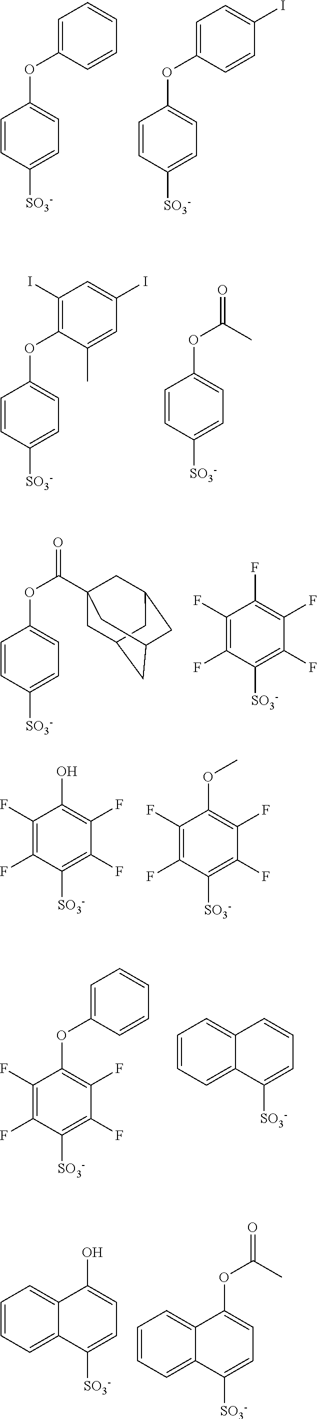

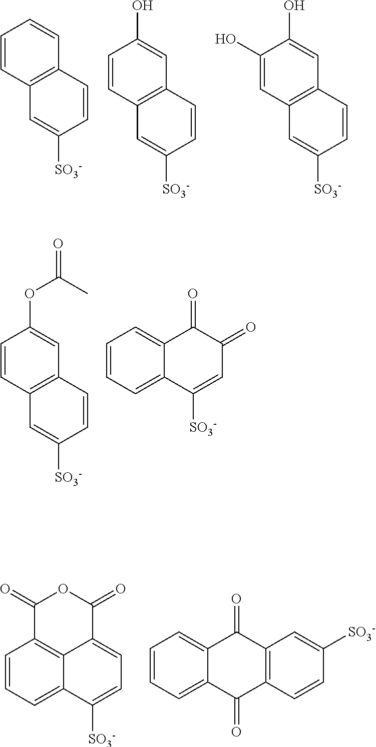

Examples of the anion in the onium salt having formula (Q-b) are shown below, but not limited thereto.

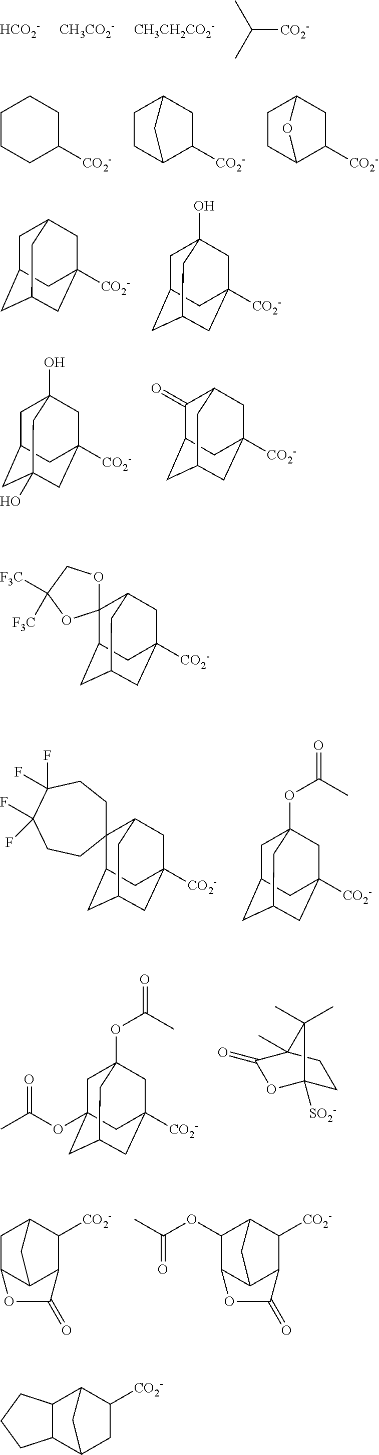

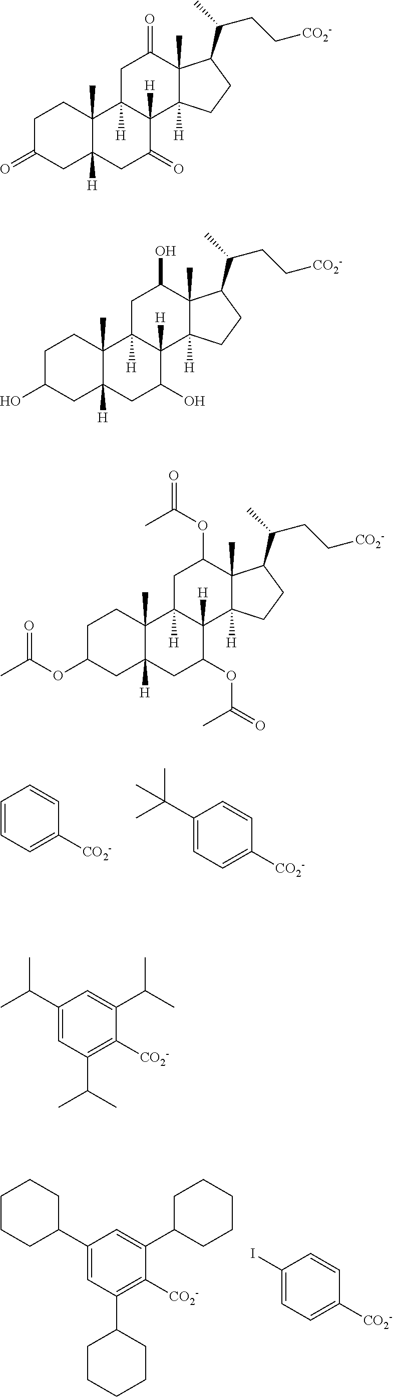

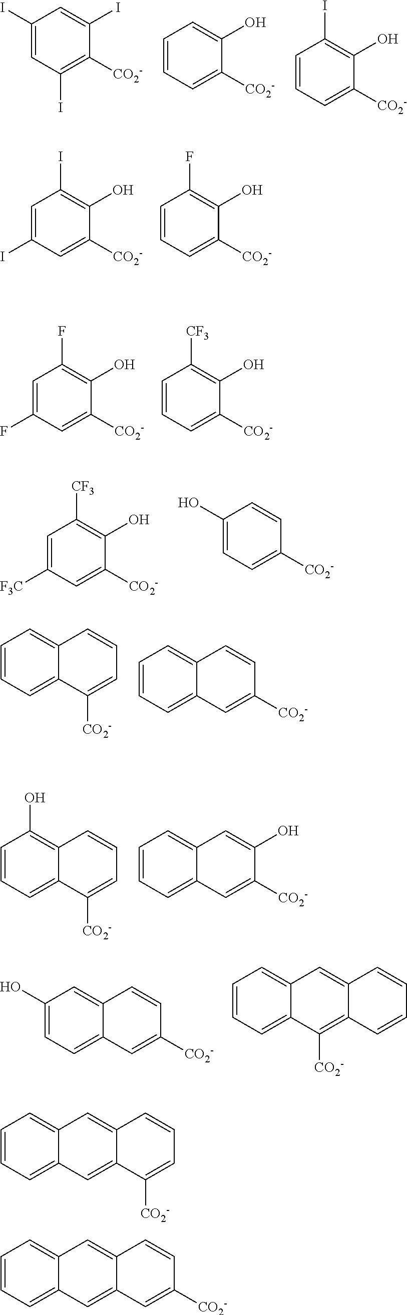

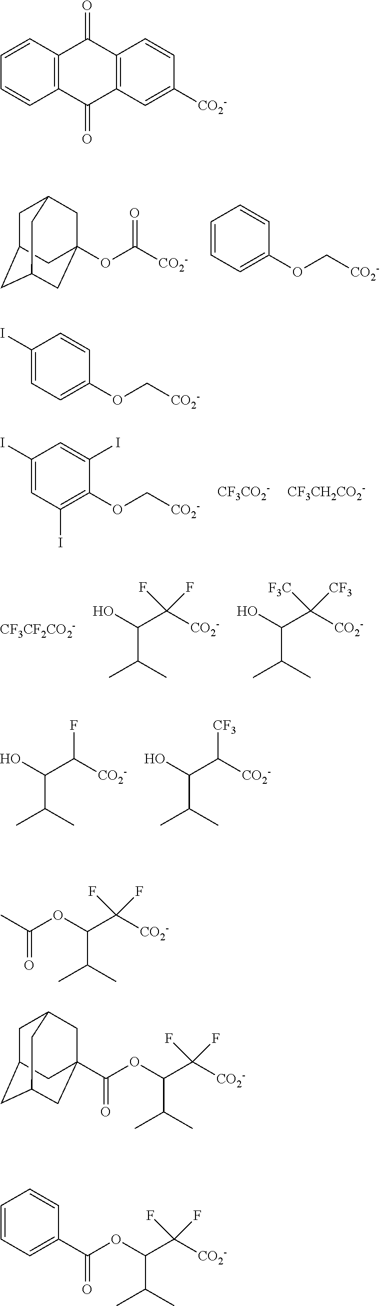

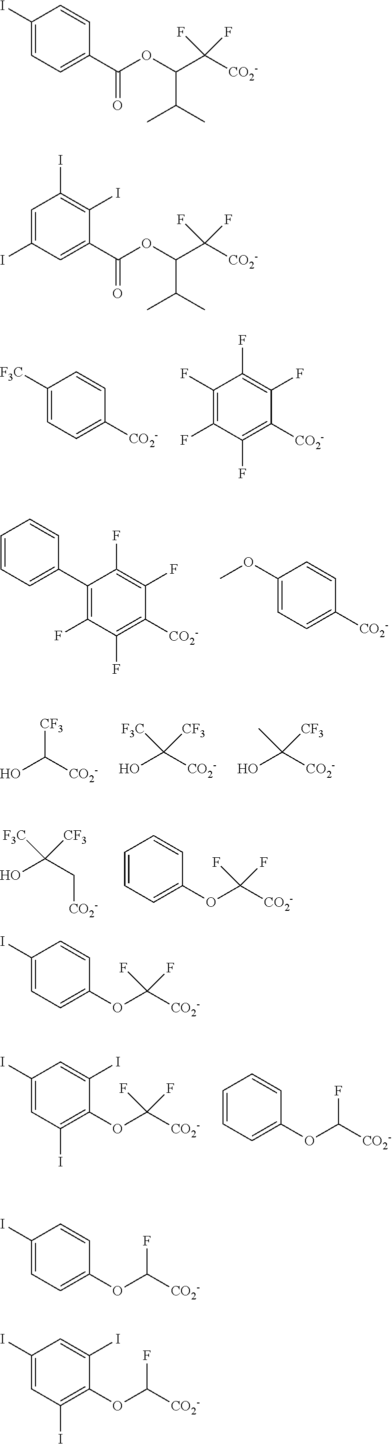

In formulae (Q-a) and (Q-b), Mq⁺ is an onium cation. Preferably, the onium cation is represented by the formula (Mq-1), (Mq-2) or (Mq-3).

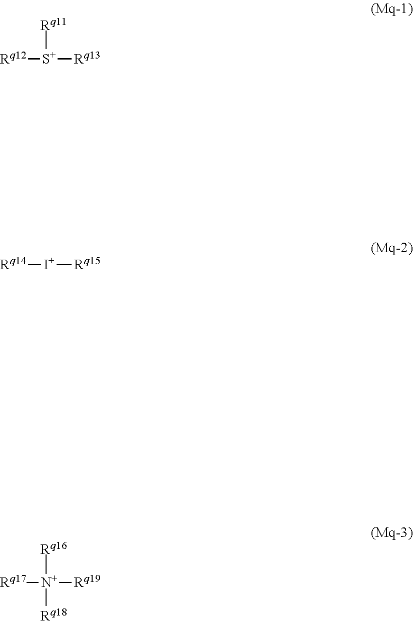

In formulae (Mq-1), (Mq-2) and (Mq-3), R^{q11} to R^{q19} are each independently a C₁-C₄₀ hydrocarbyl group which may contain a heteroatom. R^{q11} and R^{q41} may bond together to form a ring with the sulfur atom to which they are attached, and R^{q16} and R^{q17} may bond together to form a ring with the nitrogen atom to which they are attached. Examples of the hydrocarbyl group are as exemplified above as hydrocarbyl groups R¹¹ to R¹⁵ in formulae (Xa-1) and (Xa-2).

Examples of the sulfonium cation represented by formula (Mq-1) are as exemplified above for the sulfonium cation represented by formula (Xa-1). Examples of the iodonium cation represented by formula (Mq-2) are as exemplified above for the iodonium cation represented by formula (Xa-2). Examples of the ammonium cation represented by formula (Mq-3) are shown below, but not limited thereto.

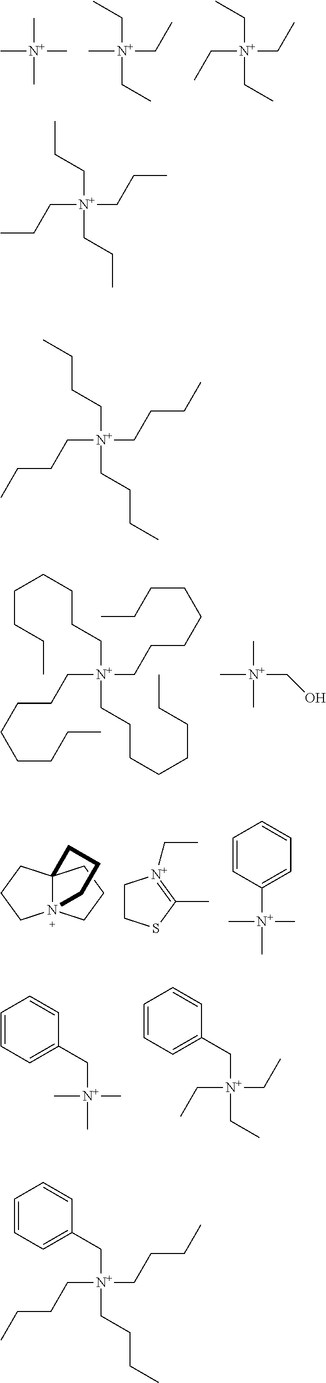

Examples of the onium salt represented by formula (Q-a) or (Q-b) include arbitrary combinations of anions with cations, both as exemplified above. These onium salts may be readily prepared by ion exchange reaction using any well-known organic chemistry technique. For the ion exchange reaction, reference may be made to JP-A 2007-145797, for example.

The onium salt having formula (Q-a) or (Q-b) functions as a quencher in the chemically amplified resist composition. This is because the counter anion of the onium salt is a conjugated base of a weak acid. As used herein, the weak acid indicates an acidity insufficient to deprotect an acid labile group from an acid labile group-containing unit for the base polymer.

The onium salt having formula (Q-a) or (Q-b) functions as a quencher when used in combination with an onium salt type PAG having a conjugated base of a strong acid (typically a sulfonic acid which is fluorinated at α-position) as the counter anion. In a system using a mixture of an onium salt capable of generating a strong acid (e.g., α-position fluorinated sulfonic acid) and an onium salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into an acid having a low catalysis, incurring apparent deactivation of the acid for enabling to control acid diffusion.

JP 6848776 discloses a compound having sulfonium cation and phenoxide anion sites in the same molecule, JP 6583136 and JP-A 2020-200311 disclose a compound having sulfonium cation and carboxylate anion sites in the same molecule, and JP 6274755 discloses a compound having iodonium cation and carboxylate anion sites in the same molecule. These salts may also be used as the quencher (D).

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

When an onium salt type quencher represented by formula (Q-a) or (Q-b) is contained as the quencher (D), the content thereof is preferably 0.1 to 20 parts by weight, more preferably 0.1 to 10 parts by weight per 80 parts by weight of the polymer (A). As long as the content of the onium salt type quencher as component (D) is in the range, a satisfactory resolution is available without a substantial lowering of sensitivity. The onium salt having formula (Q-a) or (Q-b) may be used alone or in admixture.

A nitrogen-containing quencher may also be used as the quencher (D). Suitable nitrogen-containing compounds include primary, secondary and tertiary amine compounds, specifically amine compounds having a hydroxy group, ether bond, ester bond, lactone ring, cyano group or sulfonate bond, as described in JP-A 2008-111103, paragraphs [0146]-[0164], and primary or secondary amine compounds protected with a carbamate group, as described in JP 3790649.

A sulfonic acid sulfonium salt having a nitrogen-containing substituent may also be used as the nitrogen-containing quencher. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and JP-A 2012-46501, for example.

When a nitrogen-containing quencher is contained as the quencher (D), the content thereof is preferably 0.001 to 12 parts by weight, more preferably 0.01 to 8 parts by weight per 80 parts by weight of the polymer (A). The nitrogen-containing quencher may be used alone or in admixture.

(E) Surfactant

The inventive chemically amplified resist composition may further comprise (E) a surfactant. It is typically (E) a surfactant which is insoluble or substantially insoluble in water and alkaline developer, or a surfactant which is insoluble or substantially insoluble in water and soluble in alkaline developer. For the surfactant, reference should be made to those compounds described in JP-A 2010-215608 and JP-A 2011-16746.

While many examples of the surfactant which is insoluble or substantially insoluble in water and alkaline developer are described in the patent documents cited herein, preferred examples are fluorochemical surfactants FC-4430 (3M). Olfine® E1004 (Nissin Chemical Co., Ltd.), Surflonit S-381, KH-20 and KH-30 (AGC Seimi Chemical Co., Ltd.). Partially fluorinated oxetane ring-opened polymers having the formula (surf-1) are also useful.

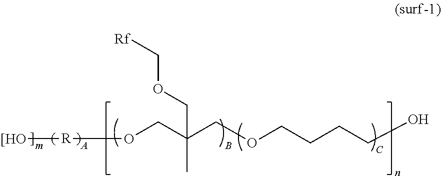

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

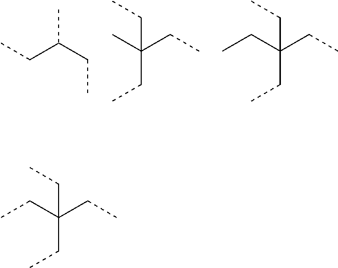

Herein the broken line denotes a valence bond. These formulae are partial structures derived from glycerol, trimethylol ethane, trimethylol propane, and pentaerythritol, respectively.

Of these, 1,4-butylene and 2,2-dimethyl-1,3-propylene are preferred.

Rf is trifluoromethyl or pentafluoroethyl, preferably trifluoromethyl. The subscript m is an integer of 0 to 3, n is an integer of 1 to 4, and the sum of m and n, which represents the valence of R, is an integer of 2 to 4. A is 1. B is an integer of 2 to 25, preferably an integer of 4 to 20. C is an integer of 0 to 10, preferably 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the surface of a resist film for achieving a function of minimizing water penetration or leaching. The surfactant is also effective for preventing water-soluble components from being leached out of the resist film for minimizing any damage to the exposure tool. The surfactant becomes solubilized during alkaline development following exposure and PEB, and thus forms few or no foreign matter which becomes defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one selected from the formulae (SF-a) to (SF-e).

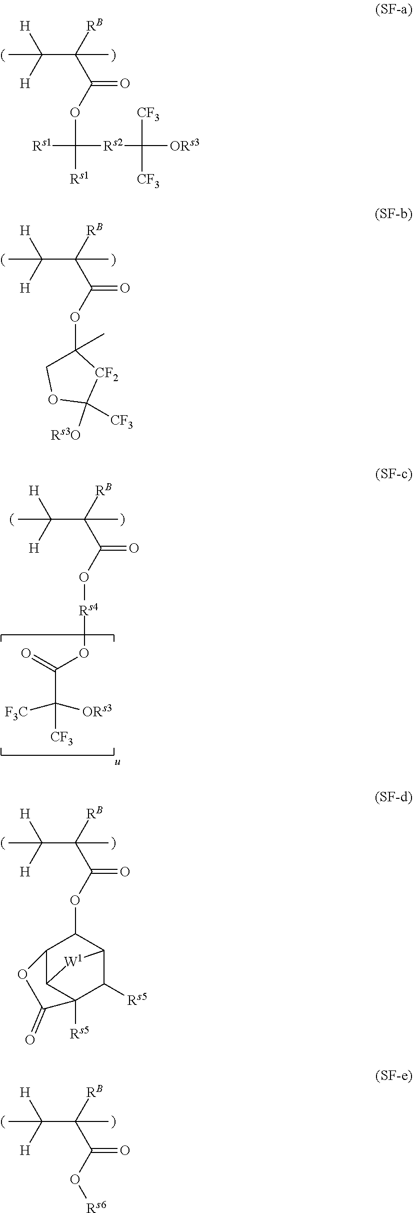

In formulae (SF-a) to (SF-e), R^{B} is hydrogen, fluorine, methyl, or trifluoromethyl. W¹ is —CH₂—, —CH₂CH₂— or —O—, or two separate —H. R^{s1} is each independently a hydrogen atom or a C₁-C₁₀ hydrocarbyl group. R^{s2} is a single bond or a C₁-C₅ straight or branched hydrocarbylene group. R¹ is each independently a hydrogen atom, a C₁-C₁₅ hydrocarbyl or fluorinated hydrocarbyl group, or an acid labile group. When R^{s3} is a hydrocarbyl or fluorinated hydrocarbyl group, an ether bond or carbonyl moiety may intervene in a carbon-carbon bond. R¹ is a C₁-C₂₀ (u+1)-valent hydrocarbon or fluorinated hydrocarbon group, u is an integer of 1 to 3. R¹¹ is each independently hydrogen or a group: —C(═O)—O—R^{sa} wherein R¹¹ is a C₁-C₂₀ fluorinated hydrocarbyl group. R⁶ is a C₁-C₁₅ hydrocarbyl or fluorinated hydrocarbyl group in which an ether bond or carbonyl moiety may intervene in a carbon-carbon bond.

The hydrocarbyl group R^{s1} is preferably saturated while it may be straight, branched or cyclic. Examples thereof include C₁-C₁₀ alkyl groups such as methyl, ethyl, n-propyl, isopropyl, n-butyl, isobutyl, sec-butyl, tert-butyl, n-pentyl, n-hexyl, n-heptyl, n-octyl, n-nonyl and n decyl, and C₃-C₁₀ cyclic saturated hydrocarbyl groups such as cyclopropyl, cyclobutyl, cyclopentyl, cyclohexyl, adamantyl and norbornyl. Inter alia, C₁-C₆ hydrocarbyl groups are preferred.

The hydrocarbylene group R^{s2} is preferably saturated while it may be straight, branched or cyclic. Examples thereof include methylene, ethylene, propylene, butylene and pentylene groups.

The hydrocarbyl group R^{s3} or R^{s6} may be saturated or unsaturated and straight, branched or cyclic. Examples thereof include saturated hydrocarbyl groups and aliphatic unsaturated hydrocarbyl groups such as alkenyl and alkynyl groups, with the saturated hydrocarbyl groups being preferred. Examples of the saturated hydrocarbyl groups include those exemplified for the hydrocarbyl group R^{s1} as well as undecyl, dodecyl, tridecyl, tetradecyl, and pentadecyl groups. Examples of the fluorinated hydrocarbyl group R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group R^{s3} include the groups of formulae (AL-1) to (AL-3), trialkylsilyl groups in which each alkyl group is a C₁-C₆ alkyl group, and C₄-C₂₀ oxoalkyl groups.

The (u+1)-valent hydrocarbon or fluorinated hydrocarbon group R¹¹ may be straight, branched or cyclic, and examples thereof include the foregoing hydrocarbyl or fluorinated hydrocarbyl groups from which “u” number of hydrogen atoms are eliminated.

The fluorinated hydrocarbyl group R^{sa} is preferably saturated while it may be straight, branched or cyclic. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units represented by any of formulae (SF-a) to (SF-e) are shown below, but not limited thereto. Herein R^{B} is as defined above.

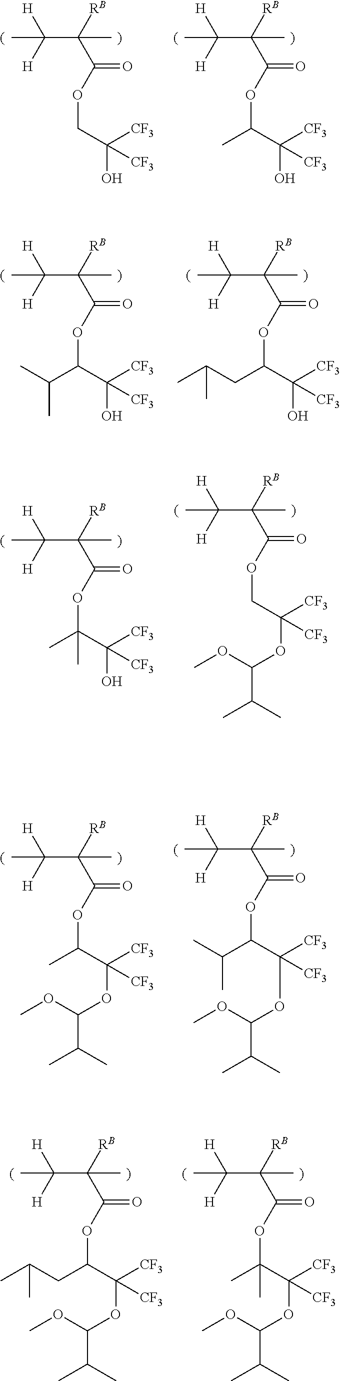

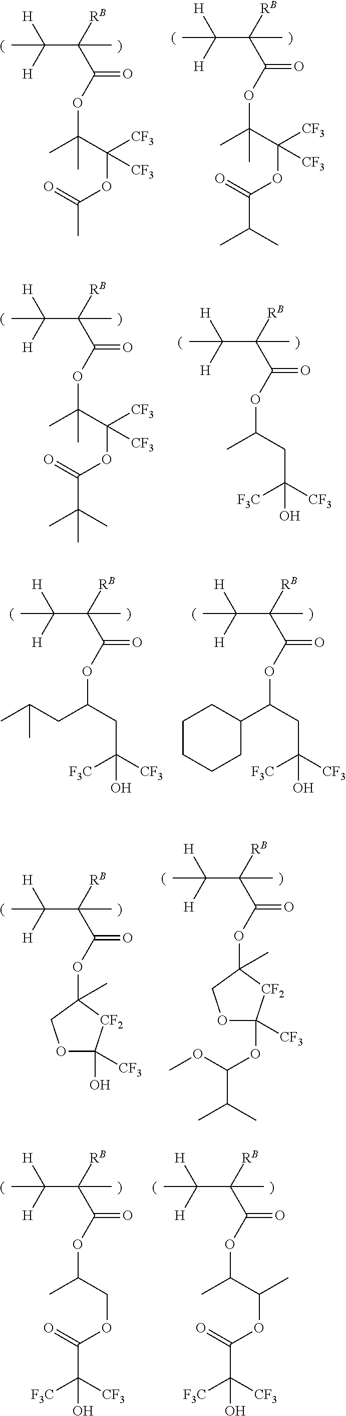

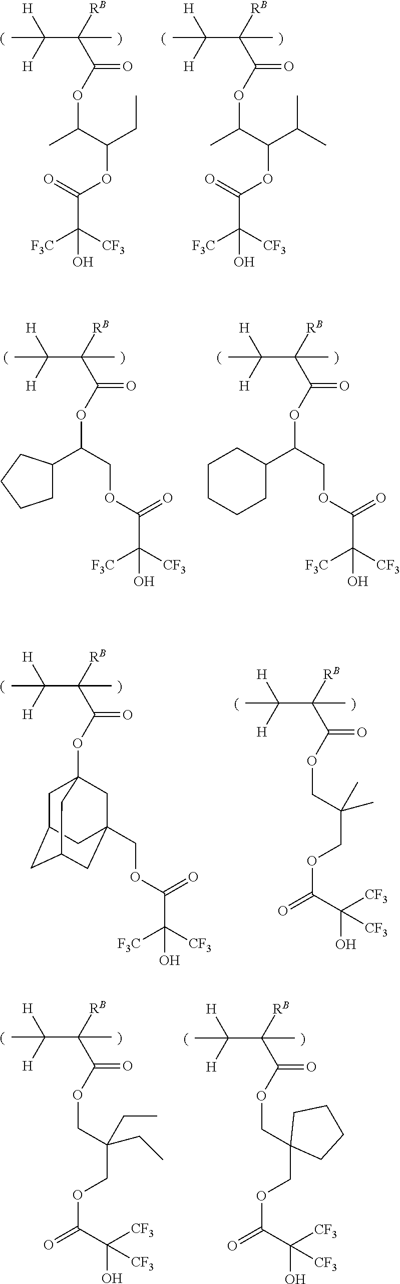

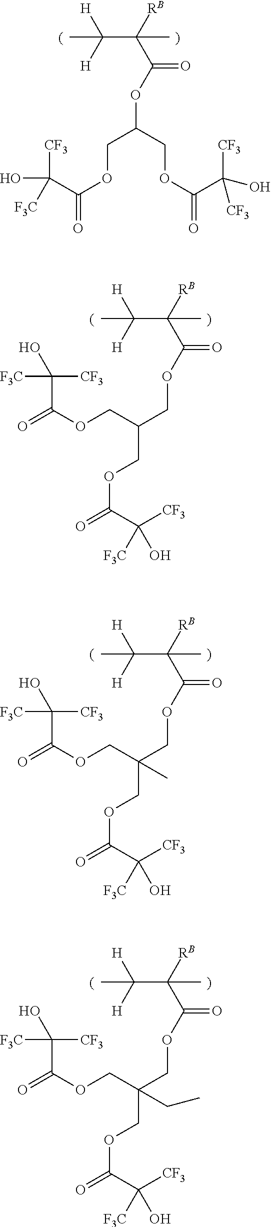

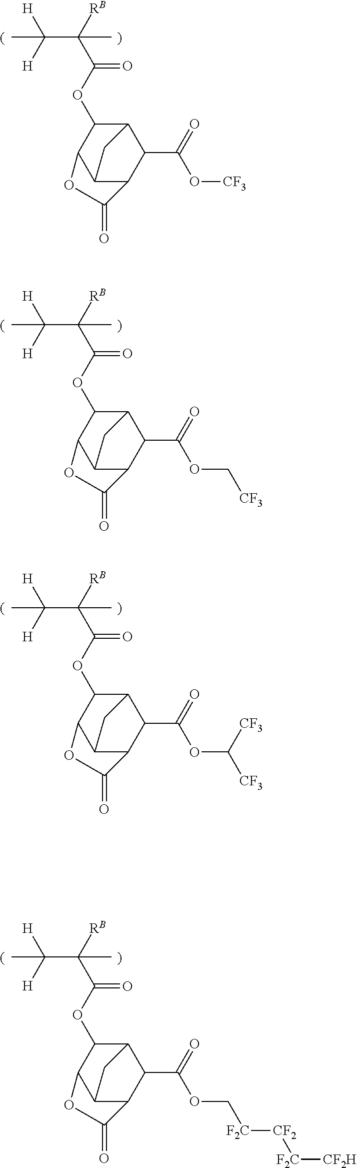

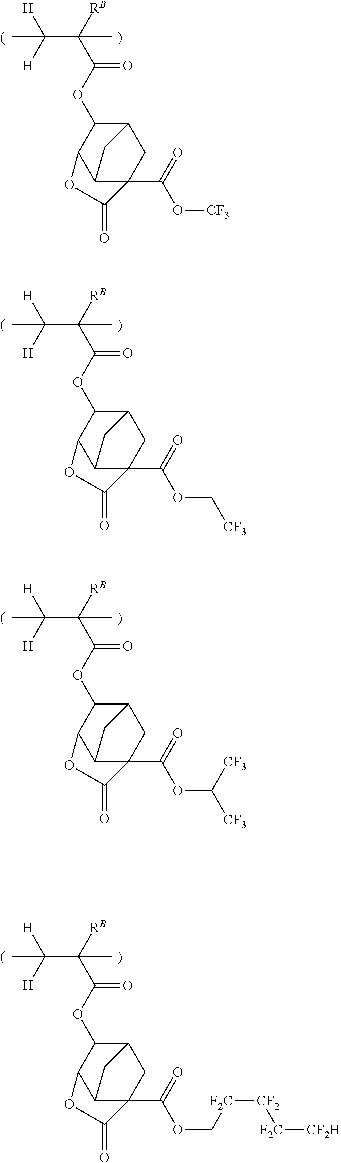

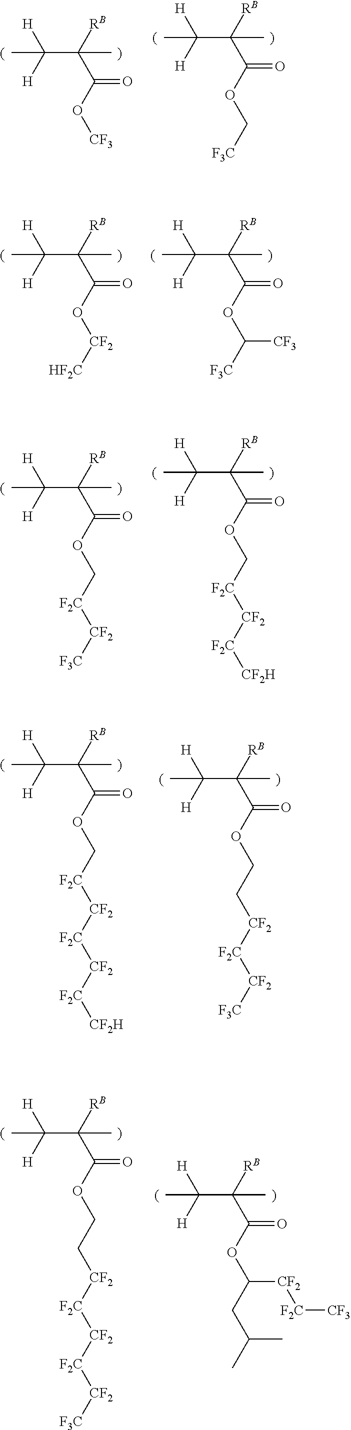

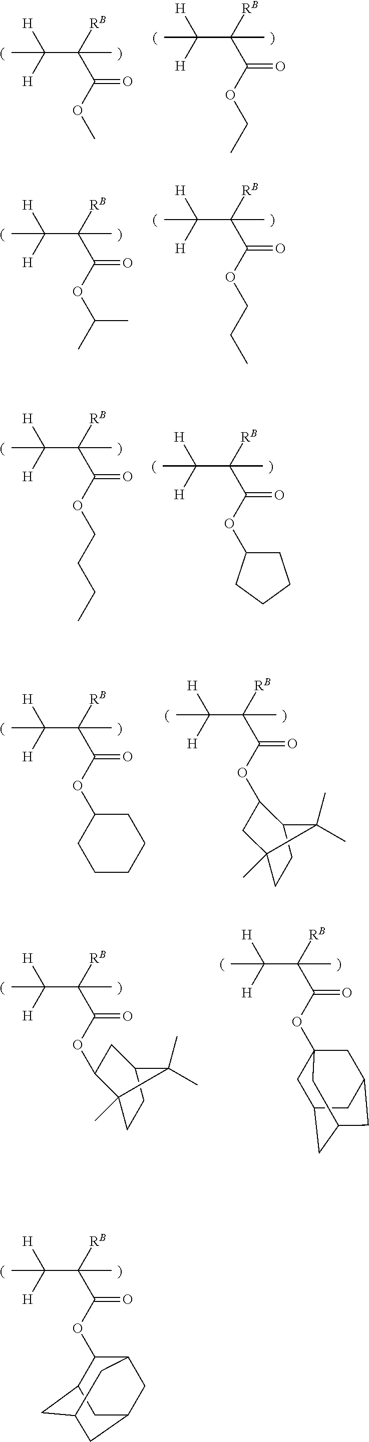

The polymeric surfactant may further contain repeat units other than the repeat limits represented by formulae (SF-a) to (SF-e). Typical other repeat units are those derived from methacrylic acid and α-trifluoromethylacrylic acid derivatives. In the polymeric surfactant, the content of the repeat units having formulae (SF-a) to (SF-e) is preferably at least 20 mol %, more preferably at least 60 mol %, most preferably 100 mol % of the overall repeat units.

Mw of the polymeric surfactant is preferably 1,000 to 500,000, more preferably 3,000 to 100,000. Mw/Mn is preferably 1.0 to 2.0, more preferably 1.0 to 1.6.

The polymeric surfactant may be synthesized, for example, by dissolving an unsaturated bond-containing monomer or monomers, from which repeat units having formulae (SF-a) to (SF-e) and optional other repeat units are derived, in an organic solvent, adding a radical initiator, and heating for polymerization. Suitable organic solvents used herein include toluene, benzene, THF, diethyl ether, and dioxane. Examples of the polymerization initiator used herein include AIBN, 2,2′-azobis(2,4-dimethylvaleronitrile), dimethyl 2,2-azobis(2-methylpropionate), benzoyl peroxide, and lauroyl peroxide. The reaction temperature is preferably 50 to 100° C. The reaction time is preferably 4 to 24 hours. The acid labile group that has been incorporated in the monomer may be kept as such, or the polymerization may be followed by protection or partial protection.

During the synthesis of the polymeric surfactant, any of well-known chain transfer agents such as dodecylmercaptan and 2-mercaptoethanol may be used for the purpose of adjusting molecular weight. An appropriate amount of the chain transfer agent is 0.01 to 10 mol % based on the total moles of monomers to be polymerized.

When the chemically amplified resist composition contains the surfactant (E), the amount of the surfactant (E) used is 0.1 to 50 parts by weight, more preferably 0.5 to 10 parts by weight per 80 parts by weight of the polymer (A). As long as the amount of the surfactant (E) is at least 0.1 parts by weight, the receding contact angle of resist film surface with water is fully improved. As long as the amount of the surfactant (E) is up to 50 parts by weight, the dissolution rate of resist film surface in developer is so low that the resulting small-size pattern may maintain a sufficient height. The surfactant (E) may be used alone or in admixture.

(F) Other Components

The inventive chemically amplified resist composition may further comprise (F) another component, for example, a compound which is decomposed with an acid to generate another acid (i.e., acid amplifier compound), an organic acid derivative, a fluorinated alcohol, and a compound having a Mw of up to 3,000 which changes its solubility in developer under the action of an acid (i.e., dissolution inhibitor). The acid amplifier compound is described in JP-A 2009-269953 and JP-A 2010-215608. The acid amplifier compound is preferably used in an amount of 0 to 5 parts, more preferably 0 to 3 parts by weight per 80 parts by weight of the polymer (A). An extra amount of the acid amplifier compound can make the acid diffusion control difficult and cause degradations to resolution and pattern profile. With respect to the organic acid derivative, fluorinated alcohol and dissolution inhibitor, reference should be made to JP-A 2009-269953 and JP-A 2010-215608.

Process

Another embodiment of the invention is a pattern forming process using the chemically amplified resist composition defined above. The process comprises the steps of applying the chemically amplified resist composition to a substrate to form a resist film thereon, exposing the resist film to KrF excimer laser, ArF excimer laser, EB or EUV, and developing the exposed resist film in a developer.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The resist composition is applied by a suitable coating technique such as spin coating. The coating is prebaked on a hot plate preferably at a temperature of 60 to 150° C. for 1 to 10 minutes, more preferably at 80 to 140° C. for 1 to 5 minutes. The resulting resist film preferably has a thickness of 0.05 to 2 μm.

On use of KrF excimer laser, ArF excimer laser or EUV, the resist film is exposed through a mask having a desired pattern, preferably in a dose of 1 to 200 mJ/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0 between the resist film and the projection lens may be employed if desired. The liquid is typically water, and in this case, a protective film which is insoluble in water may be formed on the resist film.

While the water-insoluble protective film serves to prevent any components from being leached out of the resist film and to improve water sliding on the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate at 60 to 150° C. for 1 to 5 minutes, preferably at 80 to 140° C. for 1 to 3 minutes.

The resist film is then developed with a developer in the form of an aqueous alkaline, for example, 0.1 to 5 wt %, preferably 2 to 3 wt % aqueous solution of tetramethylammonium hydroxide (TMAH) for 0.1 to 3 minutes, preferably 0.5 to 2 minutes by conventional techniques such as dip, puddle and spray techniques. In this way, a desired resist pattern is formed on the substrate.

Any desired step may be added to the pattern forming process. For example, after the resist film is formed, a step of rinsing with pure water (post-soaking) may be introduced to extract the acid generator or the like from the film surface or wash away particles. After exposure, a step of rinsing (post-soaking) may be introduced to remove any water remaining on the film after exposure.

Also, a double patterning process may be used for pattern formation. The double patterning process includes a trench process of processing an underlay to a 1:3 trench pattern by a first step of exposure and etching, shifting the position, and forming a 1:3 trench pattern by a second step of exposure, for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the inventive pattern forming process, negative tone development may also be used. That is, an organic solvent may be used instead of the aqueous alkaline solution as the developer for dissolving away the unexposed region of the resist film.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvents may be used alone or in admixture.

### EXAMPLES

Synthesis Examples, Examples and Comparative Examples are given below by way of illustration and not by way of limitation. The apparatuses used are as follows.
IR: NICOLET 6700 by Thermo Fisher Scientific Inc.
¹H-NMR: ECA-500 by JEOL Ltd.

### [1] Synthesis of Monomers

### Synthesis Example 1-1 Synthesis of Monomer A-1

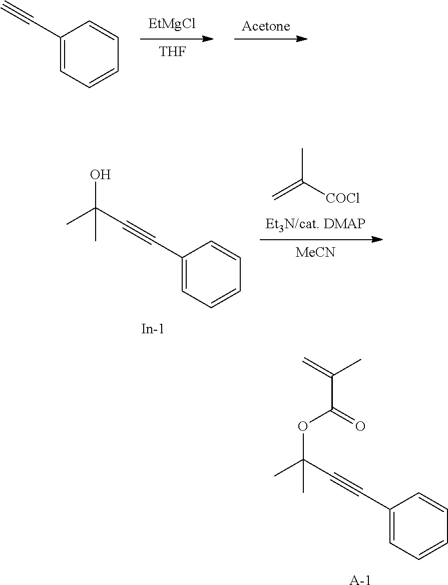

### (1) Synthesis of Intermediate In-1

In a nitrogen atmosphere, a reaction vessel was charged with a Grignard reagent prepared using 250 g of a solution of 2.0 mol/L ethylmagnesium chloride in THF, 51 g of ethynylbenzene and 50 mL of THF. While the internal temperature of the reaction vessel was kept below 50° C., a solution of 38 g of acetone and 40 mL of THE was added dropwise. The solution was stirred for 2 hours at an internal temperature of 50° C. The reaction solution was ice cooled, after which a mixture of 50 g of ammonium chloride and 300 g of 3.0 wt % hydrochloric acid aqueous solution was added dropwise to quench the reaction. 300 mL of toluene was added to the solution, followed by ordinary aqueous workup, solvent stripping, vacuum distillation. There was obtained 76 g of Intermediate In-1 as colorless oily matter (yield 91%).

### (2) Synthesis of Monomer A-1

In nitrogen atmosphere, a reaction vessel was charged with a solution of 114 g of Intermediate In-1, 152 g of triethylamine, 12.2 g of dimethylaminopyridine and 400 mL of acetonitrile, and 136 g of chloride methacrylate was added dropwise at an internal temperature below 20° C. The solution was aged for 3 hours at an internal temperature of 45° C. The reaction solution was ice cooled, after which 200 mL of saturated sodium hydrogencarbonate solution was added dropwise to quench the reaction. This was followed by extraction with 500 mL of hexane, ordinary aqueous workup, solvent stripping, and vacuum distillation. There was obtained 144 g of Monomer A-1 as colorless transparent oily matter (yield 79%).

Monomer A-1 was analyzed by IR and ¹H-NMR spectroscopy, with the data shown below.

IR (D-ATR): ν=3057, 2987, 2928, 1723, 1638, 1599, 1491, 1468, 1444, 1401, 1381, 1363, 1327, 1293, 1175, 1123, 1070, 1007, 965, 941, 884, 858, 815, 757, 692, 652, 569, 549, 509 cm⁻¹.

¹H-NMR (600 MHz in DMSO-d₆): δ=7.37 (5H, in), 6.01 (1H, s), 5.68 (1H, s), 1.87 (3H, s), 1.74 (6H, m) ppm.

### Synthesis Example 1-2 Synthesis of Monomer A-2

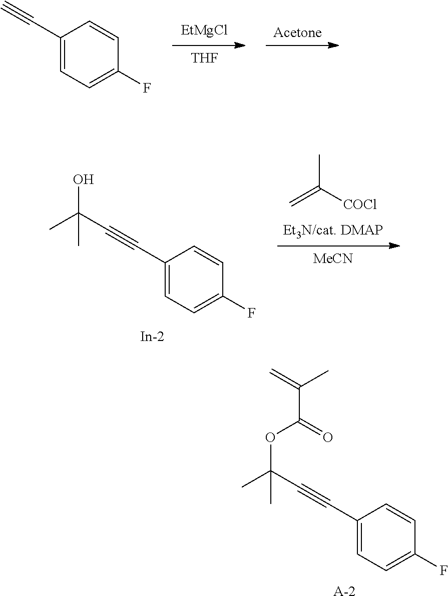

Synthesis was performed by the same procedure as Synthesis Example 1-1 aside from using 4-fluorophenylacetylene instead of ethynylbenzene. There was obtained Monomer A-2 as colorless transparent oily matter (2-step yield 78%).

Monomer A-2 was analyzed by IR and ¹H-NMR spectroscopy, with the data shown below.

IR(D-ATR): ν=2988, 2928, 2230, 1893, 1723, 1638, 1601, 1507, 1469, 1452, 1435, 1404, 1381, 1364, 1327, 1295, 1223, 1175, 1157, 1125, 1093, 1008, 966, 941, 886, 858, 837, 814, 780, 651, 626, 568, 548, 528, 483, 452 cm⁻¹.

¹H-NMR (600 MHz in DMSO-d6): δ=7.44 (2H, dd), 7.20 (2H, dd), 6.00 (1H, s), 5.67 (1H, s), 1.86 (3H, s), 1.73 (6H, m) ppm.

### Synthesis Example 1-3 Synthesis of Monomer A-3

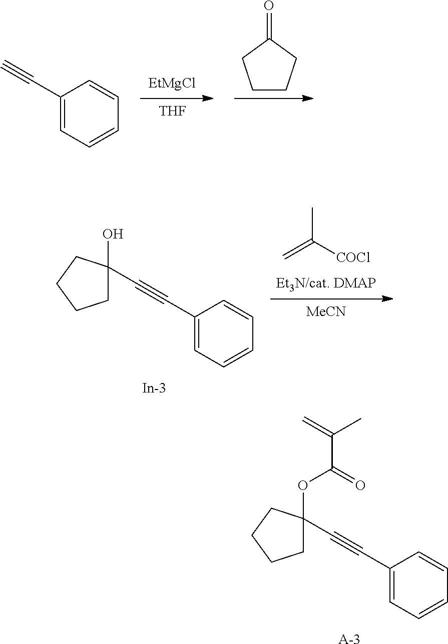

Synthesis was performed by the same procedure as Synthesis Example 1-1 aside from using cyclopentanone instead of acetone. There was obtained Monomer A-3 as colorless transparent oily matter (yield 77%).

Monomer A-3 was analyzed by IR and ¹H-NMR spectroscopy, with the data shown below.

IR (D-ATR): ν=3056, 2959, 2875, 2232, 1723, 1637, 1599, 1573, 1491, 1444, 1401, 1377, 1327, 1299, 1151, 1070, 1008, 969, 944, 862, 815, 757, 692, 651, 535 cm⁻¹.

¹H-NMR (600 MHz in DMSO-d6): δ=7.37 (5H, m), 6.02 (1H, s), 5.68 (1H, s), 2.27 (2H, m), 2.17 (2H, m), 1.87 (3H, s), 1.75 (4H, m) ppm.

### Synthesis Examples 1-4 to 1-7 Synthesis of Monomers A-4 to A-7

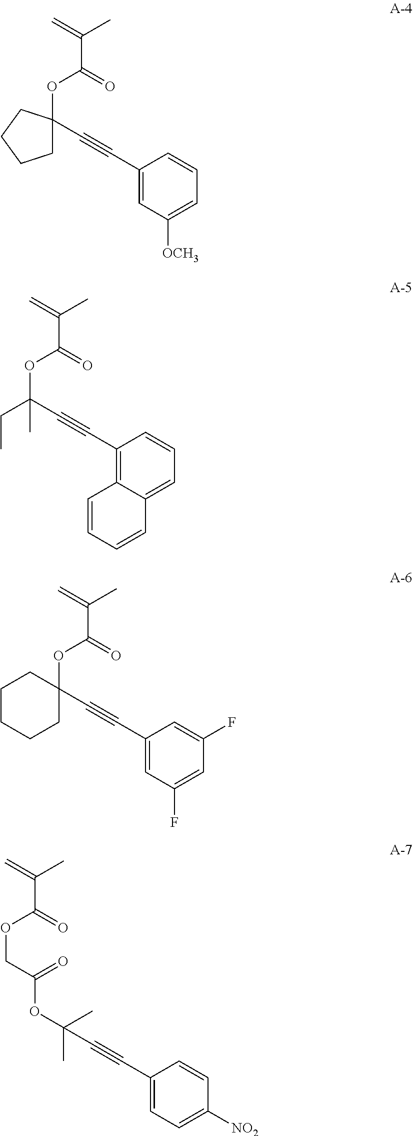

Monomers A-4 to A-7 were similarly synthesized using the corresponding reactants and organic chemistry techniques.

### Comparative Synthesis Examples 1-1 to 1-4 Comparative Monomers cA-1 to cA-4

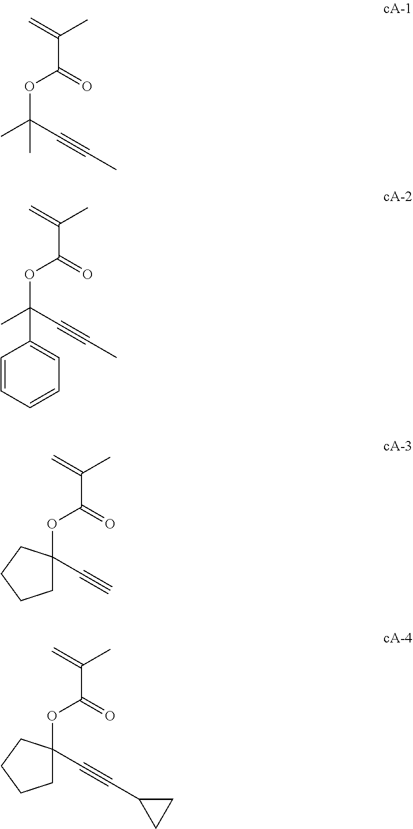

Comparative Monomers cA-1 to cA-4 were similarly synthesized using the corresponding reactants and organic chemistry techniques.

### [2] Synthesis of Polymers

Monomers A-1 to A-7, Comparative Monomers cA-1 to cA-4, and the monomers shown below were used in the synthesis of polymers.

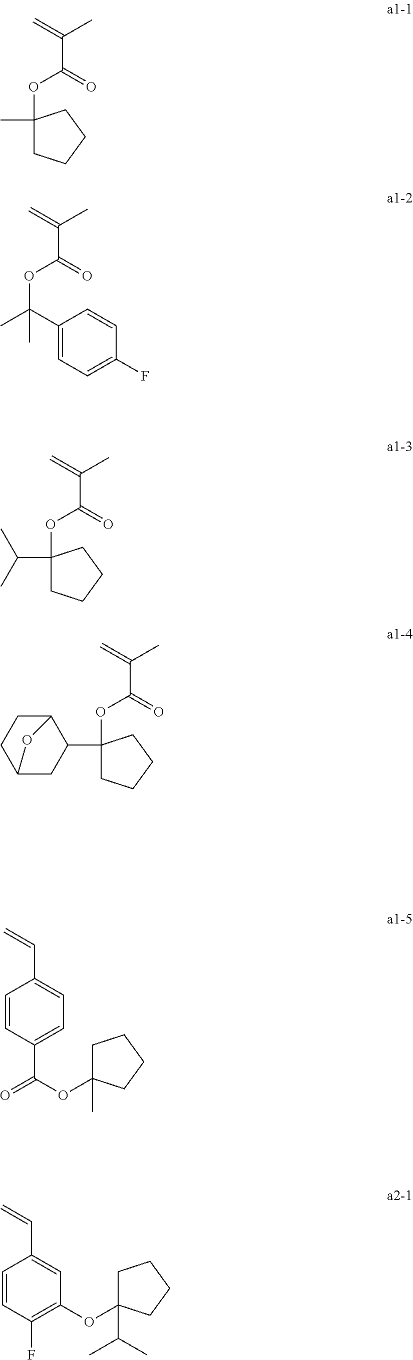 [SMILES: C=C(C)C(=O)OC1(C)CCCC1 ; C=C(C)C(=O)OC(C)(C)c1ccc(F)cc1 ; C=C(C)C(=O)OC1(C(C)C)CCCC1 ; C=C(C)C(=O)OC1(C2CC3CCC2O3)CCCC1 ; C=Cc1ccc(C(=O)OC2(C)CCCC2)cc1 ; C=Cc1ccc(F)c(OC2(C(C)C)CCCC2)c1]

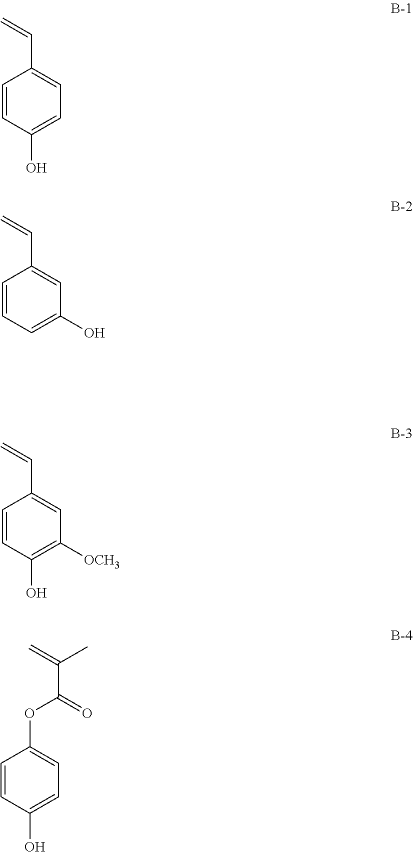

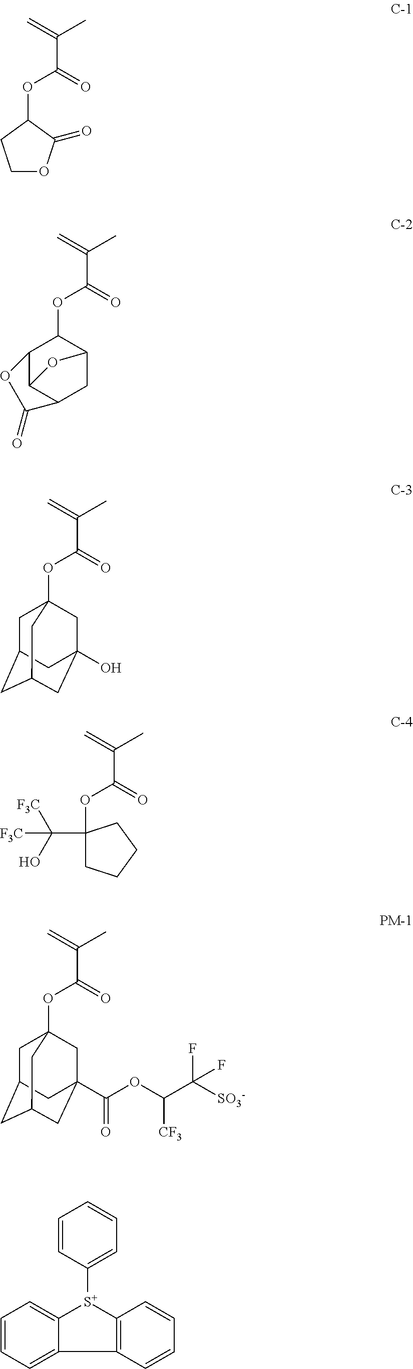

### Synthesis Example 2-1 Synthesis of Polymer P-1

In a funnel under nitrogen atmosphere, 32.8 g of Monomer A-1, 17.1 g of Monomer B-1, 3.3 g of V-601 (manufactured by Fujifilm Wako Pure Chemical Corp.), and 52 g of PGMEA were combined to form a monomer/initiator solution. A flask in nitrogen atmosphere was charged with 23 g of PGMEA, which was heated at 80° C. with stirring. With stirring, the monomer/initiator solution was added dropwise to the flask over 4 hours. After the completion of dropwise addition, the polymerization solution was continuously stirred for 2 hours while maintaining the temperature of 80° C., and then cooled to room temperature. The polymerization solution was cooled to room temperature, whereupon it was added dropwise to 800 g of hexane with vigorous stirring. The precipitate was collected by filtration, washed twice with 300 g of hexane, and vacuum dried at 50° C. for 20 hours, obtaining Polymer P-1 in white powder form (amount 47.9 g, yield 96%). Polymer P-1 had a Mw of 5,400 and a Mw/Mn of 1.67. It is noted that Mw is as measured by GPC versus polystyrene standards using THF solvent.

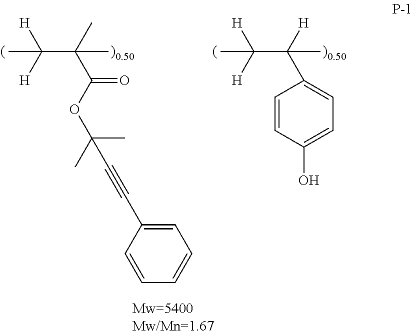 [SMILES: CCC(C)(C)C(=O)OC(C)(C)C#Cc1ccccc1 ; CCC(C)c1ccc(O)cc1]

### Synthesis Examples 2-2 to 2-25 and Comparative Synthesis Examples 2-1 to 2-25 Synthesis of Polymers P-2 to P-25 and Polymers CP-1 to CP-25

Polymers as shown in Tables 1 and 2 were synthesized by the same procedure as in Synthesis Example 2-1 aside from changing the type and amount of monomers. It is noted that Mw is as measured by GPC versus polystyrene standards using THF or DMF solvent.

TABLE 1

| | | Ratio | | Ratio | | Ratio | | Ratio | | Ratio | | |
|---|---|---|---|---|---|---|---|---|---|---|---|---|
| Polymer | Unit A | (mol %) | Unit a | (mol %) | Unit B | (mol %) | Unit C | (mol %) | Unit P | (mol %) | Mw | Mw/Mn |
| P-1 | A-1 | 50 | — | — | B-1 | 50 | — | — | — | — | 5,400 | 1.67 |
| P-2 | A-2 | 50 | — | — | B-1 | 50 | — | — | — | — | 5,600 | 1.63 |
| P-3 | A-3 | 50 | — | — | B-1 | 50 | — | — | — | — | 5,500 | 1.68 |
| P-4 | A-4 | 50 | — | — | B-1 | 50 | — | — | — | — | 5,700 | 1.71 |
| P-5 | A-5 | 50 | — | — | B-1 | 50 | — | — | — | — | 5,400 | 1.73 |
| P-6 | A-6 | 50 | — | — | B-1 | 50 | — | — | — | — | 5,600 | 1.66 |
| P-7 | A-7 | 50 | — | — | B-1 | 50 | — | — | — | — | 5,500 | 1.69 |
| P-8 | A-1 | 20 | a1-1 | 40 | B-1 | 40 | — | — | — | — | 5,800 | 1.66 |
| P-9 | A-2 | 20 | a1-2 | 40 | B-1 | 40 | — | — | — | — | 6,200 | 1.72 |
| P-10 | A-3 | 30 | a1-3 | 30 | B-2 | 40 | — | — | — | — | 6,400 | 1.73 |
| P-11 | A-4 | 40 | a1-4 | 15 | B-3 | 30 | C-1 | 15 | — | — | 6,700 | 1.66 |
| P-12 | A-5 | 30 | a1-5 | 25 | B-4 | 25 | C-2 | 20 | — | — | 6,400 | 1.74 |
| P-13 | A-6 | 35 | a2-1 | 15 | B-2 | 40 | C-3 | 10 | — | — | 6,500 | 1.69 |
| P-14 | A-7 | 40 | a1-2 | 15 | B-3 | 35 | C-4 | 10 | — | — | 7,200 | 1.70 |
| P-15 | A-1 | 30 | a1-3 | 25 | B-2 | 35 | C-3 | 10 | — | — | 6,800 | 1.73 |
| P-16 | A-2 | 40 | — | — | B-1 | 30 | C-2 | 20 | — | — | 7,200 | 1.71 |
| | | | | | | | C-3 | 10 | | | | |
| P-17 | A-4 | 40 | — | — | B-2 | 30 | C-1 | 20 | — | — | 7,800 | 1.81 |
| | | | | | | | C-3 | 10 | | | | |
| P-18 | A-5 | 45 | a2-1 | 10 | B-3 | 35 | C-2 | 10 | — | — | 7,300 | 1.71 |
| P-19 | A-6 | 30 | a1-2 | 25 | B-4 | 30 | C-1 | 15 | — | — | 6,900 | 1.68 |
| P-20 | A-2 | 35 | a1-5 | 15 | B-2 | 40 | C-1 | 10 | — | — | 6,900 | 1.71 |
| P-21 | A-3 | 45 | — | — | B-2 | 55 | — | — | — | — | 5,900 | 1.69 |
| P-22 | A-5 | 45 | — | — | B-4 | 55 | — | — | — | — | 6,600 | 1.72 |
| P-23 | A-2 | 35 | a1-5 | 15 | B-2 | 40 | C-1 | 10 | — | — | 6,900 | 1.71 |
| P-24 | A-3 | 25 | a1-1 | 25 | B-2 | 35 | C-2 | 15 | — | — | 7,300 | 1.72 |
| P-25 | A-1 | 40 | a1-3 | 10 | B-1 | 25 | C-3 | 25 | — | — | 7,400 | 1.67 |

TABLE 2

| | | Ratio | | Ratio | | Ratio | | Ratio | | Ratio | | |
|---|---|---|---|---|---|---|---|---|---|---|---|---|
| Polymer | Unit A | (mol %) | Unit a | (mol %) | Unit B | (mol %) | Unit C | (mol %) | Unit P | (mol %) | Mw | Mw/Mn |
| CP-1 | cA-1 | 50 | — | — | B-1 | 50 | — | — | — | — | 5,500 | 1.67 |
| CP-2 | cA-2 | 50 | — | — | B-1 | 50 | — | — | — | — | 5,500 | 1.59 |
| CP-3 | cA-3 | 50 | — | — | B-1 | 50 | — | — | — | — | 6,400 | 1.80 |
| CP-4 | cA-4 | 50 | — | — | B-1 | 50 | — | — | — | — | 5,900 | 1.57 |
| CP-5 | cA-1 | 40 | — | — | B-1 | 50 | C-4 | 10 | — | — | 6,500 | 1.51 |
| CP-6 | cA-2 | 40 | — | — | B-1 | 50 | C-3 | 10 | — | — | 5,900 | 1.51 |
| CP-7 | cA-1 | 40 | — | — | B-1 | 30 | C-2 | 20 | — | — | 7,200 | 1.71 |
| | | | | | | | C-3 | 10 | | | | |
| CP-8 | cA-1 | 45 | — | — | B-2 | 55 | — | — | — | — | 5,900 | 1.69 |
| CP-9 | cA-4 | 40 | — | — | B-1 | 50 | C-4 | 10 | — | — | 7,000 | 1.73 |
| CP-10 | cA-4 | 40 | — | — | B-1 | 50 | C-3 | 10 | — | — | 6,400 | 1.58 |
| CP-11 | cA-3 | 40 | — | — | B-1 | 30 | C-2 | 20 | — | — | 7,800 | 1.81 |
| | | | | | | | C-3 | 10 | | | | |
| CP-12 | cA-4 | 45 | — | — | B-2 | 55 | — | — | — | — | 5,800 | 1.63 |
| CP-13 | cA-2 | 40 | — | — | B-3 | 30 | C-1 | 20 | — | — | 7,100 | 1.69 |
| | | | | | | | C-3 | 10 | | | | |
| CP-14 | cA-4 | 35 | a1-2 | 15 | B-2 | 50 | — | — | — | — | 6,200 | 1.65 |
| CP-15 | cA-2 | 35 | a1-4 | 15 | B-4 | 40 | C-3 | 10 | — | — | 6,700 | 1.67 |
| CP-16 | cA-4 | 35 | a1-5 | 15 | B-2 | 40 | C-1 | 10 | — | — | 6,900 | 1.71 |
| CP-17 | cA-1 | 55 | — | — | B-2 | 30 | — | — | PM-1 | 15 | 9,700 | 1.81 |
| CP-18 | cA-2 | 55 | — | — | B-2 | 30 | — | — | PM-1 | 15 | 9,700 | 1.81 |
| CP-19 | cA-3 | 55 | — | — | B-2 | 30 | — | — | PM-1 | 15 | 10,500 | 1.88 |
| CP-20 | cA-4 | 55 | — | — | B-2 | 30 | — | — | PM-1 | 15 | 9,800 | 1.82 |
| CP-21 | A-1 | 55 | — | — | B-2 | 30 | — | — | PM-1 | 15 | 10,200 | 1.84 |
| CP-22 | A-3 | 40 | a1-1 | 15 | B-1 | 30 | — | — | PM-1 | 15 | 10,700 | 1.85 |
| CP-23 | A-2 | 30 | a1-2 | 25 | B-3 | 35 | — | — | PM-1 | 10 | 10,400 | 1.84 |
| CP-24 | A-4 | 25 | a1-3 | 25 | B-4 | 20 | C-2 | 20 | PM-1 | 10 | 10,900 | 1.81 |
| CP-25 | A-5 | 30 | a1-4 | 25 | B-2 | 20 | C-4 | 10 | PM-1 | 15 | 10,400 | 1.84 |

### [3] Preparation of Chemically Amplified Resist Composition

### Examples 1-1 to 1-25 and Comparative Examples 1-1 to 1-25

A chemically amplified resist composition was prepared by dissolving a component selected from the inventive polymers (P-1 to P-25), a component selected from comparative polymers (CP-1 to CP-25), a component selected from photoacid generators (PAG-1 and PAG-4), a component selected from quenchers (SQ-1 to SQ-3 and AQ-1) and an alkali-soluble surfactant (SF-1) in a solvent containing 100 ppm of surfactant FC-4430 (3M Company) in accordance with the formulation shown in Tables 3 and 4 below, and filtering the solution through a Teflon® filter with a pore size of0.2 μm.

The components in Tables 3 and 4 are identified below.

Solvent:
PGMEA (propylene glycol monomethyl ether acetate)
DAA (diacetone alcohol)

Photoacid generator: PAG-1 to PAG-4

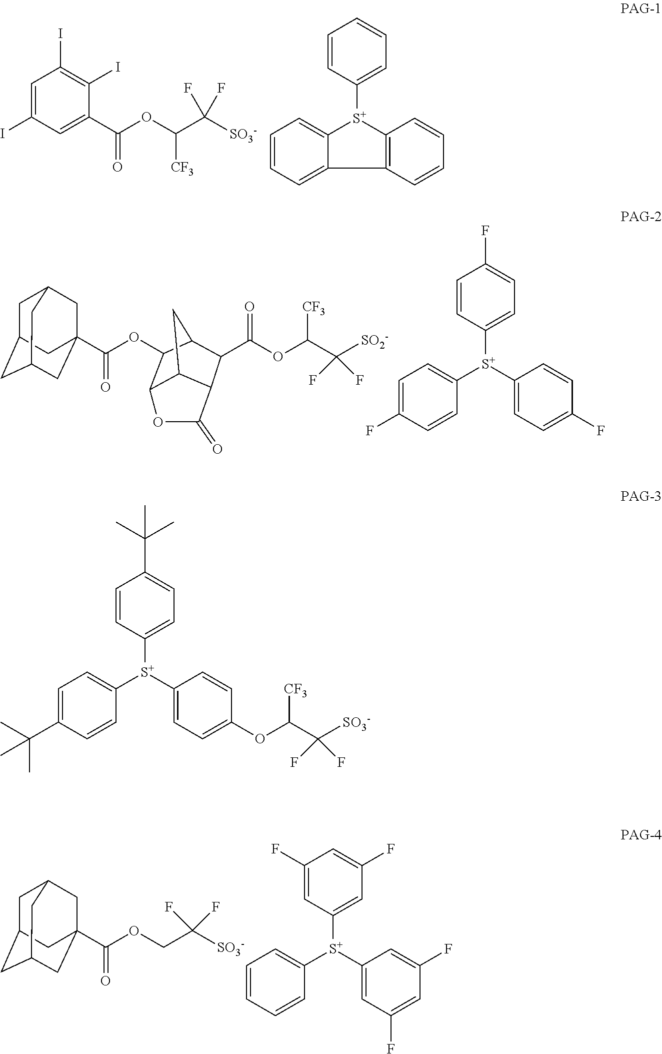

Quencher: SQ-1 to SQ-3, AQ-1

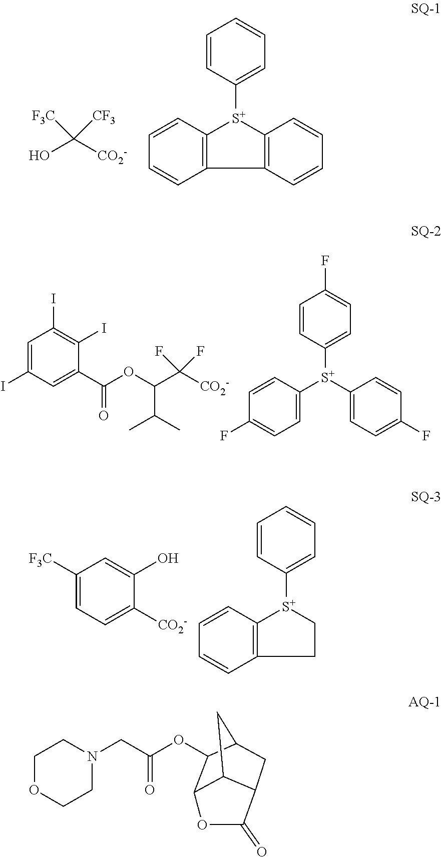

Alkali-soluble surfactant SF-1: Poly(2,2,3,3,4,4,4-heptafluoro-1-isobutyl methacrylate-1-butyl methacrylate/9-(2,2,2-trifluoro-1-trifluoromethylethyloxycarbonyl)-4-oxatricyclo[4.2.1.0^{3,7}]nonan-5-on-2-yl methacrylate)

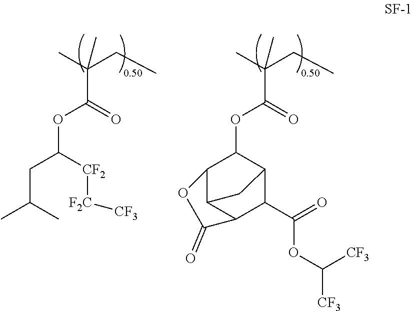

Mw=7,700, Mw/Mn=1.82

TABLE 3

| | | Resist | Polymer | Photoacid generator | Quencher | Solvent 1 | Solvent 2 |
|---|---|---|---|---|---|---|---|
| | | composition | (pbw) | (pbw) | (pbw) | (pbw) | (pbw) |
| Example | 1-1 | R-1 | P-1 | PAG-1 | SQ-1 | PGMEA | DAA |
| | | | (80) | (30) | (6.8) | (2200) | (900) |
| | 1-2 | R-2 | P-2 | PAG-1 | SQ-1 | PGMEA | DAA |
| | | | (80) | (30) | (6.6) | (2200) | (900) |
| | 1-3 | R-3 | P-3 | PAG-1 | SQ-1 | PGMEA | DAA |
| | | | (80) | (30) | (6.8) | (2200) | (900) |
| | 1-4 | R-4 | P-4 | PAG-4 | SQ-1 | PGMEA | DAA |
| | | | (80) | (32) | (7.0) | (2200) | (900) |
| | 1-5 | R-5 | P-5 | PAG-1 | SQ-1 | PGMEA | DAA |
| | | | (80) | (30) | (6.8) | (2200) | (900) |
| | 1-6 | R-6 | P-6 | PAG-1 | SQ-1 | PGMEA | DAA |
| | | | (80) | (30) | (6.6) | (2200) | (900) |
| | 1-7 | R-7 | P-7 | PAG-1 | SQ-1 | PGMEA | DAA |
| | | | (80) | (32) | (6.8) | (2200) | (900) |
| | 1-8 | R-8 | P-8 | PAG-2 | SQ-3 | PGMEA | DAA |
| | | | (80) | (28) | (6.8) | (2200) | (900) |
| | 1-9 | R-9 | P-9 | PAG-3 | SQ-2 | PGMEA | DAA |
| | | | (80) | (30) | (7.0) | (2200) | (900) |
| | 1-10 | R-10 | P-10 | PAG-2 | SQ-3 | PGMEA | DAA |
| | | | (80) | (28) | (7.2) | (2200) | (900) |
| | 1-11 | R-11 | P-11 | PAG-4 | SQ-2 | PGMEA | DAA |
| | | | (80) | (30) | (6.8) | (2200) | (900) |
| | 1-12 | R-12 | P-12 | PAG-4 | SQ-3 | PGMEA | DAA |
| | | | (80) | (30) | (6.8) | (2200) | (900) |
| | 1-13 | R-13 | P-13 | PAG-3 | SQ-1 | PGMEA | DAA |
| | | | (80) | (28) | (3.4) | (2200) | (900) |
| | | | | | AQ-1 | | |
| | | | | | (3.4) | | |
| | 1-14 | R-14 | P-14 | PAG-2 | SQ-3 | PGMEA | DAA |
| | | | (80) | (28) | (6.8) | (2200) | (900) |
| | 1-15 | R-15 | P-15 | PAG-3 | SQ-2 | PGMEA | DAA |
| | | | (80) | (32) | (6.8) | (2200) | (900) |
| | 1-16 | R-16 | P-16 | PAG-4 | SQ-3 | PGMEA | DAA |
| | | | (80) | (30) | (6.8) | (2200) | (900) |
| | 1-17 | R-17 | P-17 | PAG-2 | SQ-2 | PGMEA | DAA |
| | | | (80) | (28) | (6.8) | (2200) | (900) |
| | 1-18 | R-18 | P-18 | PAG-3 | SQ-3 | PGMEA | DAA |
| | | | (80) | (30) | (7.4) | (2200) | (900) |
| | 1-19 | R-19 | P-19 | PAG-2 | SQ-2 | PGMEA | DAA |
| | | | (80) | (28) | (6.8) | (2200) | (900) |
| | 1-20 | R-20 | P-20 | PAG-4 | SQ-2 | PGMEA | DAA |
| | | | (80) | (30) | (6.6) | (2200) | (900) |
| | 1-21 | R-21 | P-21 | PAG-3 | SQ-2 | PGMEA | DAA |
| | | | (80) | (30) | (7.0) | (2200) | (900) |
| | 1-22 | R-22 | P-22 | PAG-1 | SQ-3 | PGMEA | DAA |
| | | | (80) | (30) | (6.8) | (2200) | (900) |
| | 1-23 | R-23 | P-23 | PAG-4 | SQ-2 | PGMEA | DAA |
| | | | (80) | (30) | (3.4) | (2200) | (900) |
| | | | | | AQ-1 | | |
| | | | | | (3.4) | | |
| | 1-24 | R-24 | P-24 | PAG-1 | SQ-2 | PGMEA | DAA |
| | | | (80) | (32) | (6.8) | (2200) | (900) |
| | 1-25 | R-25 | P-25 | PAG-3 | SQ-3 | PGMEA | DAA |
| | | | (80) | (30) | (7.2) | (2200) | (900) |

TABLE 4

| | | Resist | Polymer | Photoacid generator | Quencher | Solvent 1 | Solvent 2 |
|---|---|---|---|---|---|---|---|
| | | composition | (pbw) | (pbw) | (pbw) | (pbw) | (pbw) |
| Comparative | 1-1 | CR-1 | CP-1 | PAG-1 | SQ-1 | PGMEA | DAA |
| Example | | | (80) | (30) | (6.8) | (2200) | (900) |
| | 1-2 | CR-2 | CP-2 | PAG-1 | SQ-1 | PGMEA | DAA |
| | | | (80) | (32) | (6.6) | (2200) | (900) |
| | 1-3 | CR-3 | CP-3 | PAG-1 | SQ-1 | PGMEA | DAA |
| | | | (80) | (30) | (6.8) | (2200) | (900) |
| | 1-4 | CR-4 | CP-4 | PAG-4 | SQ-2 | PGMEA | DAA |
| | | | (80) | (30) | (6.8) | (2200) | (900) |
| | 1-5 | CR-5 | CP-5 | PAG-2 | SQ-1 | PGMEA | DAA |
| | | | (80) | (28) | (6.8) | (2200) | (900) |
| | 1-6 | CR-6 | CP-6 | PAG-4 | SQ-2 | PGMEA | DAA |
| | | | (80) | (28) | (6.8) | (2200) | (900) |
| | 1-7 | CR-7 | CP-7 | PAG-2 | SQ-1 | PGMEA | DAA |
| | | | (80) | (28) | (6.8) | (2200) | (900) |
| | 1-8 | CR-8 | CP-8 | PAG-4 | SQ-1 | PGMEA | DAA |
| | | | (80) | (30) | (3.4) | (2200) | (900) |
| | | | | | AQ-1 | | |
| | | | | | (3.4) | | |
| | 1-9 | CR-9 | CP-9 | PAG-3 | SQ-2 | PGMEA | DAA |
| | | | (80) | (28) | (7.0) | (2200) | (900) |
| | 1-10 | CR-10 | CP-10 | PAG-2 | SQ-3 | PGMEA | DAA |
| | | | (80) | (28) | (7.2) | (2200) | (900) |
| | 1-11 | CR-11 | CP-11 | PAG-4 | SQ-2 | PGMEA | DAA |
| | | | (80) | (32) | (6.8) | (2200) | (900) |
| | 1-12 | CR-12 | CP-12 | PAG-2 | SQ-3 | PGMEA | DAA |
| | | | (80) | (28) | (6.8) | (2200) | (900) |
| | 1-13 | CR-13 | CP-13 | PAG-3 | SQ-1 | PGMEA | DAA |
| | | | (80) | (28) | (3.4) | (2200) | (900) |
| | | | | | AQ-1 | | |
| | | | | | (3.4) | | |
| | 1-14 | CR-14 | CP-14 | PAG-2 | SQ-2 | PGMEA | DAA |
| | | | (80) | (28) | (6.8) | (2200) | (900) |
| | 1-15 | CR-15 | CP-15 | PAG-3 | SQ-2 | PGMEA | DAA |
| | | | (80) | (32) | (6.8) | (2200) | (900) |
| | 1-16 | CR-16 | CP-16 | PAG-4 | SQ-3 | PGMEA | DAA |
| | | | (80) | (30) | (6.8) | (2200) | (900) |
| | 1-17 | CR-17 | CP-17 | — | SQ-1 | PGMEA | DAA |
| | | | (80) | | (6.8) | (2200) | (900) |
| | 1-18 | CR-18 | CP-18 | — | SQ-3 | PGMEA | DAA |
| | | | (80) | | (7.4) | (2200) | (900) |
| | 1-19 | CR-19 | CP-19 | — | SQ-2 | PGMEA | DAA |
| | | | (80) | | (6.8) | (2200) | (900) |
| | 1-20 | CR-20 | CP-20 | — | SQ-3 | PGMEA | DAA |
| | | | (80) | | (7.2) | (2200) | (900) |
| | 1-21 | CR-21 | CP-21 | PAG-1 | SQ-2 | PGMEA | DAA |
| | | | (80) | (30) | (7.0) | (2200) | (900) |
| | 1-22 | CR-22 | CP-22 | — | SQ-3 | PGMEA | DAA |
| | | | (80) | | (6.8) | (2200) | (900) |
| | 1-23 | CR-23 | CP-23 | PAG-4 | SQ-2 | PGMEA | DAA |
| | | | (80) | (18) | (3.4) | (2200) | (900) |
| | | | | | AQ-1 | | |
| | | | | | (3.4) | | |
| | 1-24 | CR-24 | CP-24 | — | SQ-3 | PGMEA | DAA |
| | | | (80) | | (7.2) | (2200) | (900) |
| | 1-25 | CR-25 | CP-25 | — | SQ-2 | PGMEA | DAA |
| | | | (80) | | (7.0) | (2200) | (900) |

### [4] EUV Lithography Test (1)

### Examples 2-1 to 2-25 and Comparative Examples 2-1 to 2-25

Each of the chemically amplified resist compositions (R-1 to R-25, CR-1 to CR-25) shown in Tables 3 and 4 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100° C. for 60 seconds to form a resist film of 50 nm thick. Using an EUV scanner NXE3300 (ASML, NA 0.33, a 0.9/0.6, dipole illumination), the resist film was exposed to EUV through a mask bearing a LS pattern having a size of 18 nm and a pitch of 36 nm (on-wafer size) while varying the dose and focus (dose pitch: 1 mJ/cm², focus pitch: 0.020 μm). After exposure, the resist film was baked (PEB) at the temperature shown in Tables 5 to 6 for 60 seconds and puddle developed in a 2.38 wt % TMAH aqueous solution for 30 seconds, rinsed with a rinse fluid containing surfactant, and spin dried to form a positive pattern.

The LS pattern as developed was observed under CD-SEM (CG6300, Hitachi High-Technologies Corp.) whereupon sensitivity, exposure latitude (EL), LWR, depth of focus (DOF), and collapse limit were evaluated by the following methods. The results are shown in Tables 5 and 6.

Evaluation of Sensitivity

The optimum dose Eop (mJ/cm²) which provided a LS pattern with a line width of 18 nm and a pitch of 36 nm was determined as an index of sensitivity. A smaller value indicates a higher sensitivity.

Evaluation of EL

The exposure dose which provided a LS pattern with a space width of 18 nm±10% (i.e., 16.2 to 19.8 nm) was determined. EL (%) is calculated from the exposure doses according to the following equation:

EL (%)=(|E₁−E₂|/Eop)×100
wherein E₁ is an optimum exposure dose which provides a LS pattern with a line width of 16.2 nm and a pitch of 36 nm.

E₂ is an optimum exposure dose which provides a LS pattern with a line width of 19.8 nm and a pitch of 36 nm, and

Eop is an optimum exposure dose which provides a LS pattern with a line width of 18 nm and a pitch of 36 nm. A larger value indicates better performance. A larger value indicates better performance.

Evaluation of LWR

For the LS pattern formed by exposure at the optimum dose Eop, the line width was measured at 10 longitudinally spaced apart points, from which a 3-fold value (3σ) of standard deviation (σ) was determined and reported as LWR A smaller value of 3σ indicates a pattern having small roughness and uniform line width.

Evaluation of DOF

As an index of DOF, a range of focus which provided a LS pattern with a size of 18 nm±10% (i.e., 16.2 to 19.8 mu) was determined. A greater value indicates a wider DOF.

Evaluation of Collapse Limit of Line Pattern

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

TABLE 5

| | | Resist | PEB temp. | Eop | EL | LWR | DOF | Collapse limit |
|---|---|---|---|---|---|---|---|---|
| | | composition | (° C.) | (mJ/cm²) | (%) | (nm) | (nm) | (nm) |
| Example | 2-1 | R-1 | 95 | 39 | 19 | 2.6 | 120 | 10.7 |
| | 2-2 | R-2 | 90 | 38 | 17 | 2.8 | 110 | 10.9 |
| | 2-3 | R-3 | 95 | 40 | 19 | 2.7 | 120 | 11.1 |
| | 2-4 | R-4 | 95 | 39 | 18 | 2.8 | 120 | 11.3 |
| | 2-5 | R-5 | 90 | 39 | 19 | 2.9 | 120 | 11.4 |
| | 2-6 | R-6 | 90 | 39 | 18 | 2.8 | 110 | 10.9 |
| | 2-7 | R-7 | 90 | 40 | 18 | 2.7 | 120 | 11.4 |
| | 2-8 | R-8 | 100 | 39 | 17 | 3 | 100 | 11.5 |
| | 2-9 | R-9 | 95 | 41 | 19 | 2.8 | 120 | 11.2 |
| | 2-10 | R-10 | 90 | 38 | 18 | 2.8 | 110 | 11.5 |
| | 2-11 | R-11 | 95 | 39 | 19 | 3 | 110 | 10.9 |
| | 2-12 | R-12 | 90 | 39 | 19 | 2.8 | 120 | 11.2 |
| | 2-13 | R-13 | 90 | 38 | 18 | 2.9 | 100 | 11.4 |
| | 2-14 | R-14 | 95 | 40 | 18 | 2.7 | 110 | 11.5 |
| | 2-15 | R-15 | 90 | 39 | 17 | 2.9 | 120 | 11.2 |
| | 2-16 | R-16 | 100 | 38 | 19 | 3 | 100 | 10.8 |
| | 2-17 | R-17 | 90 | 39 | 18 | 2.8 | 110 | 11.4 |
| | 2-18 | R-18 | 95 | 38 | 18 | 2.8 | 110 | 11.9 |
| | 2-19 | R-19 | 100 | 39 | 19 | 2.9 | 100 | 11.4 |
| | 2-20 | R-20 | 100 | 41 | 17 | 2.7 | 120 | 11.2 |
| | 2-21 | R-21 | 95 | 40 | 19 | 2.8 | 110 | 10.7 |
| | 2-22 | R-22 | 90 | 39 | 18 | 2.7 | 100 | 11.4 |
| | 2-23 | R-23 | 95 | 38 | 17 | 2.9 | 120 | 11.7 |
| | 2-24 | R-24 | 90 | 40 | 18 | 2.9 | 110 | 11.5 |
| | 2-25 | R-25 | 95 | 39 | 19 | 2.8 | 120 | 11.7 |

TABLE 6

| | | Resist | PEB temp. | Eop | EL | LWR | DOF | Collapse limit |
|---|---|---|---|---|---|---|---|---|
| | | composition | (° C.) | (mJ/cm²) | (%) | (nm) | (nm) | (nm) |
| Comparative | 2-1 | CR-1 | 95 | 44 | 14 | 3.5 | 90 | 14.5 |
| Example | 2-2 | CR-2 | 95 | 43 | 15 | 3.3 | 80 | 13.4 |
| | 2-3 | CR-3 | 90 | 45 | 14 | 3.4 | 70 | 15.5 |
| | 2-4 | CR-4 | 90 | 42 | 14 | 3.4 | 90 | 14.1 |
| | 2-5 | CR-5 | 90 | 43 | 15 | 3.5 | 70 | 13.9 |
| | 2-6 | CR-6 | 90 | 45 | 14 | 3.6 | 70 | 14.5 |
| | 2-7 | CR-7 | 95 | 43 | 16 | 3.4 | 80 | 14.2 |
| | 2-8 | CR-8 | 90 | 43 | 14 | 3.6 | 90 | 13.6 |
| | 2-9 | CR-9 | 100 | 42 | 13 | 3.6 | 70 | 12.9 |
| | 2-10 | CR-10 | 95 | 45 | 15 | 3.4 | 90 | 14.3 |
| | 2-11 | CR-11 | 95 | 44 | 14 | 3.5 | 100 | 15.1 |
| | 2-12 | CR-12 | 100 | 42 | 14 | 3.4 | 80 | 14.2 |
| | 2-13 | CR-13 | 95 | 45 | 15 | 3.6 | 70 | 13.8 |
| | 2-14 | CR-14 | 95 | 43 | 13 | 3.5 | 80 | 13.5 |
| | 2-15 | CR-15 | 100 | 42 | 14 | 3.5 | 80 | 14.2 |
| | 2-16 | CR-16 | 95 | 44 | 15 | 3.5 | 90 | 13.7 |
| | 2-17 | CR-17 | 90 | 40 | 16 | 3.4 | 100 | 13.4 |
| | 2-18 | CR-18 | 95 | 39 | 14 | 3.4 | 100 | 13.6 |
| | 2-19 | CR-19 | 95 | 38 | 15 | 3.5 | 90 | 14.1 |
| | 2-20 | CR-20 | 90 | 39 | 14 | 3.4 | 80 | 13.9 |
| | 2-21 | CR-21 | 100 | 37 | 14 | 3.5 | 90 | 13.7 |
| | 2-22 | CR-22 | 95 | 39 | 15 | 3.4 | 90 | 14.1 |
| | 2-23 | CR-23 | 100 | 38 | 16 | 3.3 | 80 | 14.3 |
| | 2-24 | CR-24 | 95 | 39 | 15 | 3.4 | 90 | 14.4 |
| | 2-25 | CR-25 | 90 | 38 | 14 | 3.2 | 100 | 13.8 |

It is demonstrated in Tables 5 to 6 that chemically amplified resist compositions containing a photoacid generator within the scope of the invention exhibit a high sensitivity and improved EL, LWR and DOF. The resist composition is also confirmed to have a low collapse resistance value, and resistance to pattern collapse in fine pattern formation.

### [5] EUV Lithography Test (2)

### Examples 3-1 to 3-25 and Comparative Examples 3-1 to 3-25

Each of the chemically amplified resist compositions (R-1 to R-25, CR-1 to CR-25) shown in Tables 3 and 4 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 50 nm thick. Using an EUV scanner NXE3400 (ASML, NA 0.33, a 0.9/0.6, quadrupole illumination), the resist film was exposed to EUV through a mask bearing a hole pattern having a pitch of 46 nm (on-wafer size) and +20% bias. The resist film was baked (PEB) on a hotplate at the temperature shown in Tables 7 and 8 for 60 seconds and developed in a 2.38 wt % TMAH aqueous solution for 30 seconds to form a hole pattern with a size of 23 nm.

The hole pattern was observed under CD-SEM (CG6300, Hitachi High-Technologies Corp.). The exposure dose that provides a hole pattern having a size of 23 nm is reported as sensitivity. The size of 50 holes was measured, from which a 3-fold value (3a) of standard deviation (a) was computed and reported as size variation or CDU. The results are shown in Tables 7 and 8.

TABLE 7

| | | Resist | PEB temp. | Eop | CDU |
|---|---|---|---|---|---|
| | | composition | (° C.) | (mJ/cm²) | (nm) |
| Example | 3-1 | R-1 | 90 | 25 | 2.4 |
| | 3-2 | R-2 | 90 | 26 | 2.3 |
| | 3-3 | R-3 | 95 | 26 | 2.5 |
| | 3-4 | R-4 | 90 | 25 | 2.5 |
| | 3-5 | R-5 | 90 | 27 | 2.4 |
| | 3-6 | R-6 | 85 | 26 | 2.6 |
| | 3-7 | R-7 | 85 | 26 | 2.5 |
| | 3-8 | R-8 | 85 | 26 | 2.5 |
| | 3-9 | R-9 | 90 | 27 | 2.5 |
| | 3-10 | R-10 | 95 | 26 | 2.6 |
| | 3-11 | R-11 | 85 | 27 | 2.6 |
| | 3-12 | R-12 | 90 | 25 | 2.7 |
| | 3-13 | R-13 | 85 | 27 | 2.8 |
| | 3-14 | R-14 | 85 | 26 | 2.4 |
| | 3-15 | R-15 | 90 | 25 | 2.7 |
| | 3-16 | R-16 | 85 | 26 | 2.6 |
| | 3-17 | R-17 | 85 | 26 | 2.5 |
| | 3-18 | R-18 | 85 | 27 | 2.8 |
| | 3-19 | R-19 | 90 | 26 | 2.5 |
| | 3-20 | R-20 | 95 | 27 | 2.7 |
| | 3-21 | R-21 | 95 | 25 | 2.5 |
| | 3-22 | R-22 | 90 | 25 | 2.5 |
| | 3-23 | R-23 | 90 | 25 | 2.7 |
| | 3-24 | R-24 | 85 | 26 | 2.4 |
| | 3-25 | R-25 | 90 | 25 | 2.5 |

TABLE 8

| | | Resist | PEB temp. | Eop | CDU |
|---|---|---|---|---|---|
| | | composition | (° C.) | (mJ/cm²) | (nm) |
| Comparative | 3-1 | CR-1 | 90 | 30 | 3.1 |
| Example | 3-2 | CR-2 | 95 | 31 | 3.2 |
| | 3-3 | CR-3 | 85 | 32 | 3.4 |
| | 3-4 | CR-4 | 90 | 31 | 3.1 |
| | 3-5 | CR-5 | 90 | 30 | 3.4 |
| | 3-6 | CR-6 | 85 | 29 | 3.1 |
| | 3-7 | CR-7 | 95 | 30 | 3.2 |
| | 3-8 | CR-8 | 90 | 29 | 3.2 |
| | 3-9 | CR-9 | 95 | 30 | 3.4 |
| | 3-10 | CR-10 | 90 | 31 | 3.3 |
| | 3-11 | CR-11 | 90 | 32 | 3.5 |
| | 3-12 | CR-12 | 85 | 30 | 3.3 |
| | 3-13 | CR-13 | 85 | 29 | 3.2 |
| | 3-14 | CR-14 | 90 | 28 | 3.1 |
| | 3-15 | CR-15 | 85 | 32 | 3.0 |
| | 3-16 | CR-16 | 90 | 33 | 3.1 |
| | 3-17 | CR-17 | 85 | 28 | 2.9 |
| | 3-18 | CR-18 | 90 | 27 | 3.1 |
| | 3-19 | CR-19 | 85 | 29 | 3.0 |
| | 3-20 | CR-20 | 85 | 28 | 3.0 |
| | 3-21 | CR-21 | 90 | 28 | 2.9 |
| | 3-22 | CR-22 | 95 | 29 | 3.1 |
| | 3-23 | CR-23 | 85 | 28 | 3.0 |
| | 3-24 | CR-24 | 90 | 28 | 2.9 |
| | 3-25 | CR-25 | 95 | 27 | 2.9 |

It is demonstrated in Tables 7 and 8 that chemically amplified resist compositions within the scope of the invention exhibit a high sensitivity and improved CDU.

This demonstrates that chemically amplified resist compositions are suitable as materials for EUV lithography.

### [6] Evaluation of Dry Etch Resistance

### Examples 4-1 to 4-25 and Comparative Examples 4-1 to 4-25

2 g of each of the polymers shown in Tables 1 and 2 (P-1 to P-25 and CP-1 to CP-25) was dissolved in 10 g of cyclohexanone. The solution was filtered through a filter with a pore size of 0.2 μm, and spin-coated on a Si substrate to form a 300-nm film thereon, and the film was tested under the following conditions.

Etching Test with CHF₃/CF₄-Based Gas:

A polymer film thickness difference before and after etching was determined using a dry etching apparatus TE-8500 P manufactured by Tokyo Electron Limited.

The etching conditions are as shown below.
Chamber pressure: 40.0 Pa
RF power: 1,000 W
Gap: 9 mm
CHF₃ gas flow rate: 30 mL/min
CF₄ gas flow rate: 30 mL/min
Ar gas flow rate: 100 mL/min
Time: 60 sec

In this evaluation, a smaller film thickness difference, i.e., a smaller amount of decrease, indicates higher etching resistance.

The results of dry etch resistance evaluation are shown in Tables 9 and 10.

TABLE 9

| | | | Etching rate with |
|---|---|---|---|
| | | Polymer | CHF₃/CF₄-based gas (nm/min) |
| Example | 4-1 | P-1 | 95 |
| | 4-2 | P-2 | 97 |
| | 4-3 | P-3 | 96 |
| | 4-4 | P-4 | 98 |
| | 4-5 | P-5 | 99 |
| | 4-6 | P-6 | 96 |
| | 4-7 | P-7 | 97 |
| | 4-8 | P-8 | 98 |
| | 4-9 | P-9 | 96 |
| | 4-10 | P-10 | 98 |
| | 4-11 | P-11 | 97 |
| | 4-12 | P-12 | 99 |
| | 4-13 | P-13 | 97 |
| | 4-14 | P-14 | 96 |
| | 4-15 | P-15 | 96 |
| | 4-16 | P-16 | 99 |
| | 4-17 | P-17 | 98 |
| | 4-18 | P-18 | 97 |
| | 4-19 | P-19 | 98 |
| | 4-20 | P-20 | 97 |
| | 4-21 | P-21 | 96 |
| | 4-22 | P-22 | 97 |
| | 4-23 | P-23 | 98 |
| | 4-24 | P-24 | 99 |
| | 4-25 | P-25 | 99 |

TABLE 10

| | | | Etching rate with |
|---|---|---|---|
| | | Polymer | CHF₃/CF₄-based gas (nm/min) |
| Comparative | 4-1 | CP-1 | 123 |
| Example | 4-2 | CP-2 | 122 |
| | 4-3 | CP-3 | 117 |
| | 4-4 | CP-4 | 116 |
| | 4-5 | CP-5 | 108 |
| | 4-6 | CP-6 | 107 |
| | 4-7 | CP-7 | 109 |
| | 4-8 | CP-8 | 106 |
| | 4-9 | CP-9 | 108 |
| | 4-10 | CP-10 | 108 |
| | 4-11 | CP-11 | 110 |
| | 4-12 | CP-12 | 108 |
| | 4-13 | CP-13 | 110 |
| | 4-14 | CP-14 | 112 |
| | 4-15 | CP-15 | 109 |
| | 4-16 | CP-16 | 108 |
| | 4-17 | CP-17 | 116 |
| | 4-18 | CP-18 | 112 |
| | 4-19 | CP-19 | 111 |
| | 4-20 | CP-20 | 108 |
| | 4-21 | CP-21 | 112 |
| | 4-21 | CP-22 | 114 |
| | 4-23 | CP-23 | 108 |
| | 4-24 | CP-24 | 112 |
| | 4-25 | CP-25 | 113 |

From the results shown in Tables 9 and 10, it is confirmed that polymers used in the present invention have excellent dry etch resistance to a CHF₃/CF₄-based gas.

Japanese Patent Application No. 2022-167620 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A chemically amplified resist composition comprising:
(A) a polymer adapted to increase its solubility in an aqueous alkaline under the action of an acid, the polymer comprising repeat units having the formula (A1), and repeat units having the formula (B1), and lacking repeat units adapted to generate an acid upon exposure; and
(B) a photoacid generator having the formula (PAG-a) or (PAG-b) which generates an acid under the action of KrF excimer laser, ArF excimer laser, electron beams or extreme ultraviolet radiation: 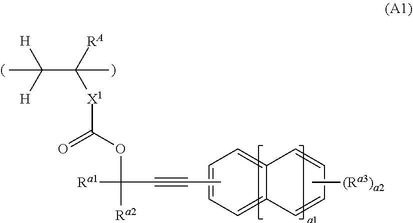
wherein a1 is 0 or 1, a2 is an integer of 0 to 3,
R^{A} is hydrogen, fluorine, methyl, or trifluoromethyl,
X¹ is a single bond, a phenylene group, a naphthylene group or *—C(═O)—O—X¹¹—, X¹¹ is a C₁-C₁₀ saturated hydrocarbylene group which may contain a hydroxy moiety, ether bond, ester bond, sulfide bond, sulfonamide bond, lactone ring or sultone ring, or a phenylene or naphthylene group, the asterisk (*) designates a point of attachment to the carbon atom in the backbone,
R^{a1} and R^{a2} are each independently hydrogen, or a C₁-C₂₀ hydrocarbyl group which may contain a heteroatom, excluding that R^{a1} and R^{a2} are hydrogen at the same time, R^{a1} and R^{a2} may bond together to form a ring with the carbon atom to which they are attached,
R^{a3} is a C₁-C₂₀ hydrocarbyl group which may contain a halogen atom or a heteroatom, and a plurality of R^{a3} moieties may bond together to form a ring with the carbon atom to which they are attached when a2≥2; 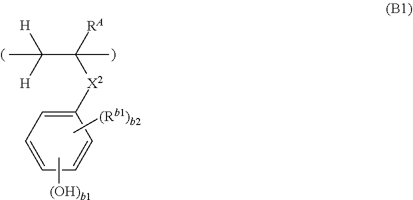
wherein b1 is an integer of 1 to 4, b2 is an integer of 0 to 3, the sum of b1+b2 is from 1 to 5,
R^{A} is hydrogen, fluorine, methyl or trifluoromethyl,
X² is a single bond or *—C(═O)—O—, the asterisk (*) designates a point of attachment to the carbon atom in the backbone,
R^{b1} is a halogen atom, a cyano group, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, and a plurality of R^{b1} moieties may bond together to form a ring with the carbon atom to which they are attached when b2≥2; 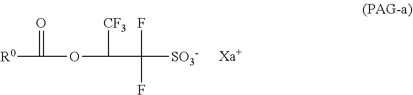
wherein R⁰ is hydrogen or a C₁-C₅₀ hydrocarbyl group, some or all of the hydrogen atoms of the hydrocarbyl group may be substituted by halogen atoms, and some constituent —CH₂— of the hydrocarbyl group may be substituted by —O— or —C(═O)—,
Xa⁺ is an organic cation; 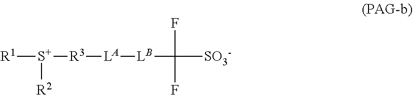
wherein R¹ and R² are each independently a C₁-C₂₀ hydrocarbyl group which may contain a heteroatom, R¹ and R² may bond together to form a ring with the sulfur atom to which they are attached,
R³ is a C₁-C₂₀ hydrocarbylene group which may contain a heteroatom,
L^{A} is a divalent linking group, and
L^{B} is a single bond, or a C₁-C₂₀ hydrocarbylene group which may contain a heteroatom.

2. The chemically amplified resist composition according to claim 1, wherein Xa⁺ is an onium cation having the formula (Xa-1) or (Xa-2): 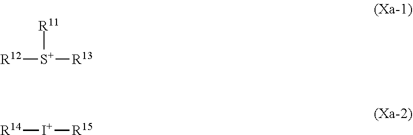
wherein R¹¹ to R¹⁵ are each independently a C₁-C₃₀ hydrocarbyl group which may contain a heteroatom, and R¹¹ and R¹² may bond together to form a ring with the sulfur atom to which they are attached.

3. The chemically amplified resist composition according to claim 1, wherein the polymer further comprises repeat units having the formula (a1) or (a2): 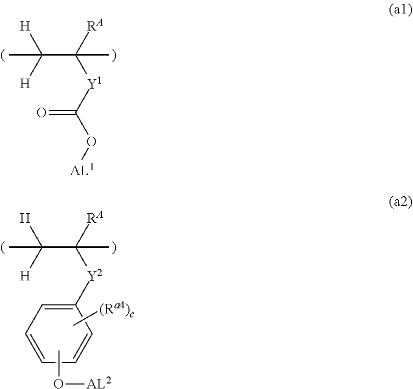
wherein R^{A} is hydrogen, fluorine, methyl group, or trifluoromethyl,
Y¹ is a single bond, a phenylene group, a naphthylene group or *—C(═O)—O—Y¹¹—, Y¹¹ is a C₁-C₁₀ saturated hydrocarbylene group which may contain a hydroxy moiety, ether bond, ester bond or lactone ring, or a phenylene or naphthylene group,
Y² is a single bond or *—C(═O)—O—,
the asterisk (*) designates a point of attachment to the carbon atom in the backbone,
AL¹ and AL² are each independently an acid labile group having no triple bond,
R^{a4} is a halogen atom, a cyano group, a C₁-C₂ hydrocarbyl group which may contain a heteroatom, a C₁-C₂ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R moieties may bond together to form a ring with the carbon atom to which they are attached when c≥2, and c is an integer of 0 to 4.

4. The chemically amplified resist composition according to claim 1, wherein the polymer further comprises repeat units having the formula (C₁): 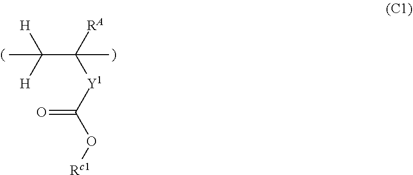
wherein R^{A} is hydrogen, fluorine, methyl group, or trifluoromethyl,
Z¹ is a single bond, a phenylene group, a naphthylene group or *—C(═O)—O—Z¹¹—, Z¹¹ is a C₁-C₁₀ saturated hydrocarbylene group which may contain a hydroxy moiety, ether bond, ester bond or lactone ring, or a phenylene or naphthylene group, the asterisk (*) designates a point of attachment to the carbon atom in the backbone, and
R^{c1} is hydrogen, or a C₁-C₂₀ group containing at least one structure selected from a hydroxy moiety other than a phenolic hydroxy moiety, a cyano moiety, a carbonyl moiety, a carboxy moiety, an ether bond, an ester bond, a sulfonic ester bond, a sulfonic amide bond, a carbonate bond, a lactone ring, a sultone ring, a sulfur atom and carboxylic anhydride (—C(═O)—O—C(═O)—).

5. The chemically amplified resist composition according to claim 1, further comprising an organic solvent.

6. The chemically amplified resist composition according to claim 1, further comprising a quencher.

7. The chemically amplified resist composition according to claim 1, further comprising a surfactant.

8. A process for forming a pattern comprising the steps of applying the chemically amplified resist composition defined in claim 1 to a substrate to form a resist film thereon, exposing the resist film to KrF excimer laser, ArF excimer laser, electron beams or EUV having a wavelength of 3 to 15 nm, and developing the exposed resist film in a developer.
